(19) United States
(12) Patent Application Publication
(10) Pub. No.: US 2015/0155165 A1
(43) Pub. Date: Jun. 4, 2015

(54) METHOD OF PRODUCING COMPOSITE WAFER AND COMPOSITE WAFER

(71) Applicants: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); HITACHI KOKUSAI ELECTRIC INC., Tokyo (JP)

(72) Inventors: Masahiko HATA, Phoenix, AZ (US); Takenori OSADA, Tsukuba-shi (JP); Taketsugu YAMAMOTO, Tsukuba-shi (JP); Takeshi AOKI, Niihama-shi (JP); Tetsuji YASUDA, Tsukuba-shi (JP); Tatsuro MAEDA, Tsukuba-shi (JP); Eiko MIEDA, Tsukuba-shi (JP); Hideki TAKAGI, Tsukuba-shi (JP); Yuichi KURASHIMA, Tsukuba-shi (JP); Yasuo KUNII, Tokyo (JP); Toshiyuki KIKUCHI, Toyama-shi (JP); Arito OGAWA, Toyama-shi (JP)

(73) Assignees: SUMITOMO CHEMICAL COMPANY, LIMITED, Tokyo (JP); NATIONAL INSTITUTE OF ADVANCED INDUSTRIAL SCIENCE AND TECHNOLOGY, Tokyo (JP); HITACHI KOKUSAI ELECTRIC INC., Tokyo (JP)

(21) Appl. No.: 14/568,159

(22) Filed: Dec. 12, 2014

Related U.S. Application Data
(63) Continuation-in-part of application No. PCT/JP2013/003755, filed on Jun. 14, 2013.

(30) Foreign Application Priority Data
Jun. 15, 2012 (JP) 2012-136443
Jun. 15, 2012 (JP) 2012-136446
Jun. 15, 2012 (JP) 2012-136447
Mar. 27, 2013 (JP) 2013-067698

(51) Int. Cl. H01L 21/02; H01L 29/16; H01L 29/20; H01L 21/306

(52) U.S. Cl. CPC H01L 21/02373; H01L 21/02546; H01L 21/30604; H01L 21/02387; H01L 29/16; H01L 29/20

(57) ABSTRACT

A method of producing a composite wafer including a semiconductor crystal layer, includes forming a sacrificial layer and the semiconductor crystal layer above a semiconductor crystal layer forming wafer in the stated order, etching the semiconductor crystal layer to partially expose the sacrificial layer and dividing the semiconductor crystal layer into a plurality of divided pieces, bonding the semiconductor crystal layer forming wafer and a transfer target wafer made of an inorganic material in such a manner that a first surface of the semiconductor crystal layer forming wafer faces and comes into contact with a second surface of the transfer target wafer, and etching the sacrificial layer to separate the transfer target wafer and the semiconductor crystal layer forming wafer from each other with the semiconductor crystal layer being left on the transfer target wafer.

The contents of the following patent applications are incorporated herein by reference:
No. 2012-136443 filed in Japan on Jun. 15, 2012,
No. 2012-136446 filed in Japan on Jun. 15, 2012,
No. 2012-136447 filed in Japan on Jun. 15, 2012,
No. 2013-067698 filed in Japan on Mar. 27, 2012, and
No. PCT/JP2013-003755 filed on Jun. 14, 2013.

### BACKGROUND

1. Technical Field

The present invention relates to a method of producing a composite wafer and a composite wafer.

2. Related Art

Group III-V compound semiconductors such as GaAs and InGaAs have high electron mobility. On the other hand, Group IV semiconductors such as Ge and SiGe have high hole mobility. Therefore, a highly advanced complementary metal-oxide-semiconductor field effect transistor (CMOSFET) can be realized if the Group III-V compound semiconductors are used to form an N-channel metal-oxide-semiconductor field effect transistor (MOSFET) (hereinafter, may be simply referred to as nMOSFET) and the Group IV semiconductors are used to form a P-channel MOSFET (hereinafter, may be simply referred to as “pMOSFET”). Non-Patent Document 1 discloses a CMOSFET structure in which an N-channel MOSFET having a channel made of a Group III-V compound semiconductor and a P-channel MOSFET having a channel made of Ge are formed on a single wafer.

To form heterogeneous materials of a Group III-V compound semiconductor layer and a Group IV semiconductor crystal layer on a single wafer (for example, a silicon wafer), which is a transfer target, a technique is known to transfer onto the single wafer a semiconductor crystal layer that has been formed on a crystal growth wafer. For example, Non-Patent Document 2 discloses a technique according to which an AlAs layer is formed as a sacrificial layer on a GaAs wafer and a Ge layer is formed on the sacrificial layer (AlAs layer) and transferred onto a silicon wafer.

Patent Document 1 describes a technique to solve the problem related to a time-consuming process of etching the sacrificial layer and discloses a method of producing a semiconductor device. The production method includes bonding, onto a first plane of a second wafer, the upper plane of a semiconductor thin film that is formed on a first wafer with a removal layer therebetween, and separating the semiconductor thin film from the first wafer. According to the method, an etching solution path that includes a through hole extending through the second wafer is provided in a dicing region in the second wafer. An etching solution is supplied through the etching solution path to dissolve the removal layer, so that the semiconductor thin film is separated from the first wafer. Prior Art Documents
Patent Document 1: Japanese Patent Application Publication No. 2004-363213
Non-Patent Document 1: S. Takagi, et al., SSE, vol. 51, pp. 526-536, 2007
Non-Patent Document 2: Y. Bai and E. A. Fitzgerald ECS Transactions, 33 (6) 927-932 (2010)

To form on a single wafer an N-channel metal-insulator-semiconductor field effect transistor (MISFET) (hereinafter, may be simply referred to as “nMISFET”) having a channel made of a Group III-V compound semiconductor and a P-channel MISFET (hereinafter, may be simply referred to as “pMISFET”) having a channel made of a Group IV semiconductor, it is necessary to develop a technique of forming the Group III-V compound semiconductor for the n-MISFET and the Group IV semiconductor for the p-MISFET on the single wafer. Furthermore, taking into consideration that the single wafer is produced as a large scale integration (LSI), it is preferable to form a Group III-V compound semiconductor crystal layer for the nMISFET and a Group IV semiconductor crystal layer for the pMISFET on a silicon wafer, which makes it possible to make use of existing production apparatuses and methods.

The technique disclosed in Non-Patent Document 2 is capable of removing the AlAs layer, which is the sacrificial layer, by etching and separating from the GaAs wafer, which is the crystal growth wafer, the Ge layer, which is the semiconductor crystal layer to be transferred. However, the sacrificial layer is sandwiched between the crystal growth wafer and the Ge layer and thus removed by lateral etching performed in the gap between the crystal growth wafer and the Ge layer. Therefore, if the sacrificial layer is thin, the etching solution is not sufficiently supplied and it may take long time to remove the sacrificial layer. This problem may be solved by the technique disclosed in Patent Document 1, which describes that the etching solution path including a through hole is provided in the second wafer to supply the etching solution through the etching solution path. However, if such a through hole is provided in the second wafer, which is the transfer target wafer, the number of production steps increases and the production cost also increases. In addition, the region in which the through hole is provided cannot be used to form a device and device integration is disadvantageously affected.

An objective of the present invention is to provide a technique of increasing the etching rate of the sacrificial layer when the semiconductor crystal layer formed on the crystal growth wafer is transferred to the transfer target wafer.

The inventors of the present invention repeatedly performed experiments of forming a sacrificial layer and a semiconductor crystal layer on a semiconductor crystal layer forming wafer, bonding the semiconductor crystal layer forming wafer to a transfer target wafer and transferring the semiconductor crystal layer onto the transfer target wafer by dissolving the sacrificial layer by etching and found that distinguishable transfer defects may had been seen in the semiconductor crystal layer that had been transferred onto the transfer target wafer. The transfer defects include holes or concave portions that are created in the vicinity of the center of the pattern of the transferred semiconductor crystal layer and may cause failures when the semiconductor crystal layer is used as the active layer of an electronic device. In addition, irrespective of whether there are the above-described transfer defects, it is desirable to transfer the entire semiconductor crystal layer onto the transfer target wafer excellently. Furthermore, considering that the semiconductor crystal layer that has been transferred onto the transfer target wafer may be used as the active layer of an electronic device, it is desirable to maintain superior quality, for example, superior crystallinity for the transferred semiconductor crystal layer.

Another objective of the present invention is to provide a technique of transferring a semiconductor crystal layer that enables the semiconductor crystal layer to be transferred excellently onto a transfer target wafer while the occurrence of the above-described transfer defects can be reduced. Furthermore, it is aimed to provide a technique of transferring a semiconductor crystal layer that can maintain high quality, for example, crystallinity, for the transferred semiconductor crystal layer.

### SUMMARY

For a solution to the above-mentioned problems, according to the first aspect related to the present invention, provided is one exemplary method of producing a composite wafer including a semiconductor crystal layer. The method includes forming a sacrificial layer and the semiconductor crystal layer above a semiconductor crystal layer forming wafer in the order of the sacrificial layer and the semiconductor crystal layer, etching the semiconductor crystal layer so as to partially expose the sacrificial layer and dividing the semiconductor crystal layer into a plurality of divided pieces, bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, where the first surface is a surface of a layer formed on the semiconductor crystal layer forming wafer, and the second surface is a surface of the transfer target wafer or a surface of a layer formed on the transfer target wafer, and etching the sacrificial layer to separate the transfer target wafer and the semiconductor crystal layer forming wafer from each other with the semiconductor crystal layer being left on the transfer target wafer.

According to the second aspect related to the present invention, provided is one exemplary method of producing a composite wafer including a semiconductor crystal layer. The method includes forming a sacrificial layer made of AlₓGa₁₋ₓAs (0.9≦x≦1) above a semiconductor crystal layer forming wafer to a thickness of no less than 5 nm and no more than 100 nm and further forming the semiconductor crystal layer, etching the semiconductor crystal layer so as to partially expose the sacrificial layer and dividing the semiconductor crystal layer into a plurality of divided pieces, bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, where the first surface is a surface of a layer formed on the semiconductor crystal layer forming wafer, and the second surface is a surface of the transfer target wafer or a surface of a layer formed on the transfer target wafer, and removing the sacrificial layer by means of etching that uses an HCl aqueous solution as an etchant to separate the transfer target wafer and the semiconductor crystal layer forming wafer from each other with the semiconductor crystal layer being left on the transfer target wafer.

According to the third aspect related to the present invention, provided is one exemplary method of producing a composite wafer including a semiconductor crystal layer. The method includes forming a sacrificial layer made of AlₓGa₁₋ₓAs (0.9≦x≦1) above a semiconductor crystal layer forming wafer and further forming the semiconductor crystal layer, etching the semiconductor crystal layer so as to partially expose the sacrificial layer and dividing the semiconductor crystal layer into a plurality of divided pieces, bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, where the first surface is a surface of a layer formed on the semiconductor crystal layer forming wafer, and the second surface is a surface of the transfer target wafer or a surface of a layer formed on the transfer target wafer, and removing the sacrificial layer by means of etching that uses an HCl aqueous solution as an etchant to separate the transfer target wafer and the semiconductor crystal layer forming wafer from each other with the semiconductor crystal layer being left on the transfer target wafer. Here, the HCl aqueous solution has a concentration of no less than 5 mass % and no more than 25 mass %.

According to the fourth aspect related to the present invention, provided is one exemplary method of producing a composite wafer including a semiconductor crystal layer. The method includes forming a sacrificial layer and the semiconductor crystal layer above a semiconductor crystal layer forming wafer in the order of the sacrificial layer and the semiconductor crystal layer, etching the semiconductor crystal layer so as to partially expose the sacrificial layer and dividing the semiconductor crystal layer into a plurality of divided pieces, bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, where the first surface is a surface of a layer formed on the semiconductor crystal layer forming wafer, and the second surface is a surface of the transfer target wafer or a surface of a layer formed on the transfer target wafer, and etching the sacrificial layer to separate the transfer target wafer and the semiconductor crystal layer forming wafer from each other with the semiconductor crystal layer being left on the transfer target wafer. Here, one or more of the plurality of divided pieces have such a planar shape that, when the divided pieces are assumed to shrink and disappear at equal rates from each point on edges that define the external shape of the planar shape of the divided pieces in a normal direction at the point, a shape observed immediately before the disappearance due to the shrinkage is not a single point but a single line, a plurality of lines or a plurality of points. The planar shape of the divided pieces may be a planar shape defined by two parallel line segments and two lines connecting the ends of the two parallel line segments, and the lines connecting the ends can be, for example, straight, curved or polygonal lines. The planar shape of the divided pieces can be, for example, rectangular. Note that, when a tangent t can be drawn at a point P on a line c, the straight line that passes through the point P and orthogonal to the tangent t is referred to as a normal to the line c on the P.

In the first to fourth aspects, the method may further include after the bonding, attaching the semiconductor crystal layer forming wafer and the transfer target wafer to each other under a pressure within a range of 0.01 MPa to 1 GPa.

According to the fifth aspect related to the present invention, provided is one exemplary method of producing a composite wafer including a semiconductor crystal layer. The method includes forming a sacrificial layer and the semiconductor crystal layer above a semiconductor crystal layer forming wafer in the order of the sacrificial layer and the semiconductor crystal layer, etching the semiconductor crystal layer so as to partially expose the sacrificial layer and dividing the semiconductor crystal layer into a plurality of divided pieces, arranging the semiconductor crystal layer forming wafer and a transfer target wafer made of an inorganic material in such a manner that a first surface of the semiconductor crystal layer forming wafer faces a second surface of the transfer target wafer and attaching the semiconductor crystal layer forming wafer and the transfer target wafer to each other in such a manner that the first surface comes into contact with the second surface under a pressure within a range of 0.01 MPa to 1 GPa, where the first surface is a surface of a layer formed on the semiconductor crystal layer forming wafer, and the second surface is a surface of the transfer target wafer or a surface of a layer formed on the transfer target wafer, and etching the sacrificial layer to separate the transfer target wafer and the semiconductor crystal layer forming wafer from each other with the semiconductor crystal layer being left on the transfer target wafer.

In the first to fifth aspects, the method may further include after the formation of the sacrificial layer and the semiconductor crystal layer, and before the division of the semiconductor crystal layer into the plurality of divided pieces, forming an adhesive layer made of an inorganic material above the semiconductor crystal layer. In this case, during the division of the semiconductor crystal layer into the plurality of divided pieces, the adhesive layer and the semiconductor crystal layer are etched so as to partially expose the sacrificial layer and the adhesive layer and the semiconductor crystal layer are divided into the plurality of pieces. The method may further include after the division and before the bonding of the semiconductor crystal layer forming wafer and the transfer target wafer, performing adhesiveness enhancement treatment to enhance adhesiveness at the bonding interface between the first surface and the second surface on one or more surfaces selected from the first surface and the second surface.

The etching of the sacrificial layer for the separation of the transfer target wafer and the semiconductor crystal layer forming wafer may be performed by immersing partially or entirely the semiconductor crystal layer forming wafer and the transfer target wafer in an etching solution. Alternatively, the bonding or the attachment under the pressure of the transfer target wafer and the semiconductor crystal layer forming wafer may form a space between the surface of the transfer target wafer and an internal wall of a groove formed between adjacent ones of the divided pieces, and the etching of the sacrificial layer for the separation of the transfer target wafer and the semiconductor crystal layer forming wafer from each other may be started by dropping an etching solution onto one end of the space. In this case, after the inside of the space is filled with the etching solution, the transfer target wafer and the semiconductor crystal layer forming wafer may be entirely immerse into the etching solution to allow the etching to proceed. Alternatively, the etching solution may be continuously supplied to the end of the space to allow the etching to proceed. In this case, during the etching, the inside of the space may be partially or entirely dried one or more times.

Other aspects of the present invention may include one exemplary composite wafer comprising a transfer target wafer and a semiconductor crystal layer that is formed on the transfer target wafer by a transfer technique. The semiconductor crystal layer has a plurality of divided pieces, and one or more of the plurality of divided pieces have such a planar shape that, when the divided pieces are assumed to shrink and disappear at equal rates from each point on edges that define the external shape of the planar shape of the divided pieces in a normal direction at the point, a shape observed immediately before the disappearance due to the shrinkage is not a single point but a single line, a plurality of lines or a plurality of points. The planar shape of the divided pieces can be, for example, rectangular.

Other aspects of the present invention may include one exemplary composite wafer comprising a transfer target wafer and a semiconductor crystal layer that is formed on the transfer target wafer by a transfer technique. Here, the semiconductor crystal layer has a plurality of divided pieces, and one or more of the plurality of divided pieces have compressive or tensile strain. The planar shape of the divided pieces can be, for example, rectangular.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a cross-sectional view illustrating steps of a method of producing a composite wafer relating to a first embodiment in the performed order.

FIG. 2 is a cross-sectional view illustrating steps of the method of producing a composite wafer relating to the first embodiment in the performed order.

FIGS. 3A to 3C are plan views illustrating exemplary planar shapes of a divided piece 108.

FIGS. 4A to 4E are plan views illustrating exemplary planar shapes of the divided piece 108.

FIG. 5 is a cross-sectional view illustrating the steps of the method of producing a composite wafer relating to the first embodiment in the performed order.

FIG. 6 is a cross-sectional view illustrating the steps of the method of producing a composite wafer relating to the first embodiment in the performed order.

FIG. 7 is a cross-sectional view illustrating the steps of the method of producing a composite wafer relating to the first embodiment in the performed order.

FIG. 8 is a cross-sectional view illustrating the steps of the method of producing a composite wafer relating to the first embodiment in the performed order.

FIG. 9 is a cross-sectional view illustrating the steps of the method of producing a composite wafer relating to the first embodiment in the performed order.

FIG. 10 is a cross-sectional view illustrating the steps of the method of producing a composite wafer relating to the first embodiment in the performed order.

FIG. 11 is a cross-sectional view illustrating steps of a method of producing a composite wafer relating to a second embodiment in the performed order.

FIG. 12 is a cross-sectional view illustrating the steps of the method of producing a composite wafer relating to the second embodiment in the performed order.

FIG. 13 is a cross-sectional view illustrating the steps of the method of producing a composite wafer relating to the second embodiment in the performed order.

FIG. 14 is a cross-sectional view illustrating the steps of the method of producing a composite wafer relating to the second embodiment in the performed order.

FIG. 15 is a cross-sectional view illustrating steps of a method of producing a composite wafer relating to a third embodiment in the performed order.

FIG. 16 is a cross-sectional view illustrating the steps of the method of producing a composite wafer relating to the third embodiment in the performed order.

FIG. 17 is a cross-sectional view illustrating the steps of the method of producing a composite wafer relating to the third embodiment in the performed order.

FIG. 18 is a cross-sectional view illustrating the steps of the method of producing a composite wafer relating to the third embodiment in the performed order.

FIG. 19 is a cross-sectional view illustrating the steps of the method of producing a composite wafer relating to the third embodiment in the performed order.

FIG. 20 is a cross-sectional view illustrating steps of a method of producing a composite wafer relating to a fourth embodiment in the performed order.

FIG. 21 is a cross-sectional view illustrating the steps of the method of producing a composite wafer relating to the fourth embodiment in the performed order.

FIG. 22 is a cross-sectional view illustrating the steps of the method of producing a composite wafer relating to the fourth embodiment in the performed order.

FIG. 23 is a cross-sectional view illustrating the steps of the method of producing a composite wafer relating to the fourth embodiment in the performed order.

FIG. 24 is a cross-sectional view illustrating the steps of the method of producing a composite wafer relating to the fourth embodiment in the performed order.

FIG. 25 is a cross-sectional view illustrating steps of a method of producing a composite wafer relating to a fifth embodiment in the performed order.

FIG. 26 is a cross-sectional view illustrating the steps of the method of producing a composite wafer relating to the fifth embodiment in the performed order.

FIG. 27 is a cross-sectional view illustrating the steps of the method of producing a composite wafer relating to the fifth embodiment in the performed order.

FIG. 28 is a cross-sectional view illustrating steps of a method of producing a composite wafer relating to a sixth embodiment in the performed order.

FIG. 29 is a cross-sectional view illustrating the steps of the method of producing a composite wafer relating to the sixth embodiment in the performed order.

FIG. 30 is a plan view illustrating steps of a method of producing a composite wafer relating to a seventh embodiment in the performed order.

FIG. 31 is a plan view illustrating the steps of the method of producing a composite wafer relating to the seventh embodiment in the performed order.

FIG. 32 is a plan view illustrating the steps of the method of producing a composite wafer relating to the seventh embodiment in the performed order.

FIG. 33 is a cross-sectional view illustrating the steps of the method of producing a composite wafer relating to the seventh embodiment in the performed order.

FIG. 34 is a cross-sectional view illustrating the steps of the method of producing a composite wafer relating to the seventh embodiment in the performed order.

FIG. 35 is a cross-sectional view illustrating the steps of the method of producing a composite wafer relating to the seventh embodiment in the performed order.

FIG. 36 is a cross-sectional view illustrating the steps of the method of producing a composite wafer relating to the seventh embodiment in the performed order.

FIG. 37 is a cross-sectional view illustrating the steps of the method of producing a composite wafer relating to the seventh embodiment in the performed order.

FIG. 38 is a cross-sectional view illustrating the steps of the method of producing a composite wafer relating to the seventh embodiment in the performed order.

FIG. 39 is a plan view illustrating the steps of the method of producing a composite wafer relating to the seventh embodiment in the performed order.

FIG. 40 is a plan view illustrating a modification example of the method of producing a composite wafer relating to the seventh embodiment.

FIG. 41 is a plan view illustrating a modification example of the method of producing a composite wafer relating to the seventh embodiment.

FIG. 42 is a plan view illustrating a modification example of the method of producing a composite wafer relating to the seventh embodiment.

FIG. 43 shows the PL spectral intensity of a transfer GaAs layer.

FIG. 44 shows the PL spectral intensity peak wavelength distribution and half-value width distribution among a plurality of points in the transfer GaAs layer.

FIG. 45 shows the surface of the transfer GaAs layer, which is observed using AFM.

FIG. 46 shows the Raman spectral intensity of a transfer Ge layer.

FIG. 47 is a plan view illustrating the planar views of the divided piece 108 and a groove 110 of an eleventh exemplary embodiment.

FIG. 48 is a plan view illustrating the planar views of the divided piece 108 and the groove 110 of a twelfth exemplary embodiment.

### DESCRIPTION OF EXEMPLARY EMBODIMENTS

### First Embodiment

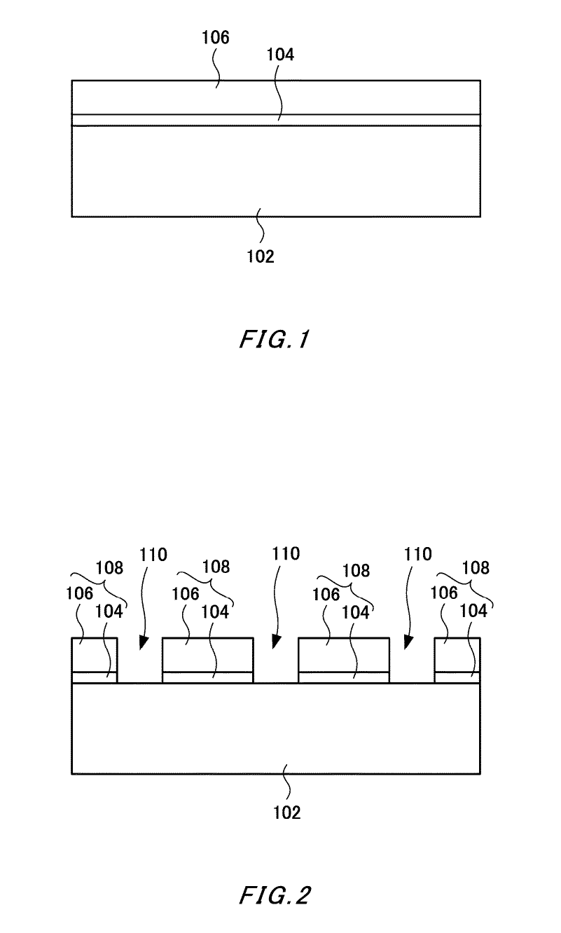

FIGS. 1 to 10 are cross-sectional or plan views illustrating steps of a method of producing a composite wafer relating to a first embodiment in the performed order. The production method relating to the first embodiment first forms a sacrificial layer 104 and a semiconductor crystal layer 106 on a semiconductor crystal layer forming wafer 102 in the order of the sacrificial layer 104 and the semiconductor crystal layer 106 as shown in FIG. 1.

The semiconductor crystal layer forming wafer 102 is a wafer used to form a high-quality semiconductor crystal layer 106. A preferable material of the semiconductor crystal layer forming wafer 102 depends on the material of the semiconductor crystal layer 106, the method of forming the semiconductor crystal layer 106, and the like. Generally speaking, the semiconductor crystal layer forming wafer 102 is desirably made of a material that lattice-matches or pseudo-lattice-matches the semiconductor crystal layer 106 to be formed. For example, when a GaAs layer or Ge layer is formed by epitaxial growth as the semiconductor crystal layer 106, the semiconductor crystal layer forming wafer 102 is preferably a GaAs single-crystal wafer, and can be selected among InP, sapphire, Ge and SiC single-crystal wafers. When the semiconductor crystal layer forming wafer 102 is a GaAs single-crystal layer, the plane on which the semiconductor crystal layer 106 is formed is the (100) plane or (111) plane.

The sacrificial layer 104 is a layer that is used to separate the semiconductor crystal layer forming wafer 102 from the semiconductor crystal layer 106. Since the sacrificial layer 194 is removed by etching, the semiconductor crystal layer 106 is separated from the semiconductor crystal layer forming wafer 102. When the sacrificial layer 104 is etched, it is necessary to prevent at least a portion of the semiconductor crystal layer forming wafer 102 and the semiconductor crystal layer 106 from being etched away and to keep such a portion. Therefore, the etching rate of the sacrificial layer 104 needs to be higher than the etching rate of the semiconductor crystal layer forming wafer 102 and the semiconductor crystal layer 106, preferably several times or more. When a GaAs single-crystal wafer is selected as the semiconductor crystal layer forming wafer 102 and a GaAs layer is selected as the semiconductor crystal layer 106, the sacrificial layer 104 is preferably a layer made of AlₓGa₁₋ₓAs (0.9≦x≦1), particularly an AlAs layer. The sacrificial layer 104 may be selected among an InAlAs layer, an InGaP layer, an InAlP layer, an InGaAlP layer, and an AlSb layer. As the thickness of the sacrificial layer 104 increases, the crystallinity of the semiconductor crystal layer 106 tends to degrade. Therefore, the sacrificial layer 104 is preferably as thin as possible as long as the sacrificial layer 104 can serve as a sacrificial layer. The thickness of the sacrificial layer 104 can be selected within the range of 0.1 nm to 10 μm.

When the sacrificial layer 104 is made of AlₓGa₁₋ₓAs (0.9≦x≦1), the sacrificial layer 104 can be removed by etching using an HCl aqueous solution as an etchant. In this case, the thickness of the sacrificial layer 104 is preferably no less than 5 nm and no more than 100 nm.

If the sacrificial layer 104 is formed thick, the etching solution is supplied swiftly in the step of removing the sacrificial layer 104 by etching (described later), and it is expected to shorten the period of time required to complete the removal of the sacrificial layer 104. However, when the sacrificial layer 104 has a large thickness, the reaction of dissolving the sacrificial layer 104 by the etchant generates a large amount of gaseous materials, which may undermine the etching. For example, when the sacrificial layer 104 is made of AlₓGa₁₋ₓAs (0.9≦x≦1) and the etchant is a HCl aqueous solution, an increased amount of gases such as arsine is generated and the etching may be disturbed. Furthermore, when the sacrificial layer 104 has a large thickness, the crystallinity of the semiconductor crystal layer 106 formed on the sacrificial layer 104 may resultantly degrade. However, when the sacrificial layer 104 is made of AlₓGa₁₋ₓAs (0.9≦x≦1) and the etchant is a HCl aqueous solution, the period of time required to complete the removal of the sacrificial layer 104 can be shortened and the amount of the generated gas can be reduced to such a level that practicality does not cause problems if the thickness of the sacrificial layer 104 is no less than 5 nm and no more than 100 nm.

The sacrificial layer 104 can be formed by epitaxial growth, chemical vapor deposition (CVD), sputtering or atomic layer deposition (ALD). The epitaxial growth can include metal organic chemical vapor deposition (MOCVD) or molecular beam epitaxy (MBL). When the sacrificial layer 104 is formed by MOCVD, the source gas can be trimethylgallium (TMGa), trimethylaluminum (TMA), trimethylindium (TMIn), arsine (AsH₃), phosphine (PH₃) or the like. The carrier gas can be hydrogen, for example. Alternatively, a compound that is obtained by replacing some of the hydrogen atom groups of the above-described source gas with chlorine atoms or hydrocarbon groups can be used. The temperature at which the reaction takes place can be selected appropriately within the range of 300° C. to 900° C., preferably within the range of 400° C. to 800° C. The thickness of the sacrificial layer 104 can be controlled by appropriately determining the amount of the source gas to be supplied and the duration of the reaction.

The semiconductor crystal layer 106 is a transfer layer that is to be transferred onto a transfer target wafer (described later). The semiconductor crystal layer 106 is used as, for example, an active layer of a semiconductor device. The semiconductor crystal layer 106 can have high-quality crystallinity by being formed on the semiconductor crystal layer forming wafer 102 by epitaxial growth or the like. Furthermore, since the semiconductor crystal layer 106 is formed by being transferred onto the transfer target wafer, the semiconductor crystal layer 106 having high quality can be formed on any transfer target wafer without the need of considering whether the semiconductor crystal layer 106 lattice matches the transfer target wafer.

The semiconductor crystal layer 106 can be a crystal layer made of a Group III-V compound semiconductor, a crystal layer made of a Group IV semiconductor, a crystal layer made of a Group II-VI compound semiconductor, or a laminate obtained by stacking these crystal layers. The Group III-V compound semiconductor is AlᵤGaᵥIn₁₋ᵤ₋ᵥNₘPₙAs_{q}Sb_{1-m-n-q} (0≦u≦1, 0≦v≦1, 0≦m≦1, 0≦n≦1, 0≦q≦1). For example, the Group III-V compound semiconductor is GaAs, In_{y}Ga_{1-y}As (0<y<1), InP or GaSb. The Group IV semiconductor is Ge or GeₓSi₁₋ₓ (0<x<1). The Group II-VI compound semiconductor is ZnO, ZnSe, ZnTe, CdS, CdSe, CdTe or the like. When the Group IV semiconductor is GeₓSi₁₋ₓ, the Ge ratio x is preferably equal to or higher than 0.9. When the Ge ratio x is equal to or higher than 0.9, the Group IV semiconductor can have similar semiconductor characteristics to Ge. If the semiconductor crystal layer 106 is one of the above-described crystal layers and laminate, the semiconductor crystal layer 106 can be used to form an active layer of a field effect transistor with high mobility, in particular, of a complementary field effect transistor having high mobility.

The thickness of the semiconductor crystal layer 106 can be appropriately selected within the range of 0.1 nm to 500 μm. The thickness of the semiconductor crystal layer 106 is preferably no less than 0.1 nm and less than 1 μm. When the thickness of the semiconductor crystal layer 106 is less than 1 μm, preferably less than 200 nm, more preferably less than 20 nm, the semiconductor crystal layer 106 can be used to form a composite wafer that is suitably used to produce a highly advanced transistor such as ultrathin-body MISFET.

The semiconductor crystal layer 106 can be formed by epitaxial growth or ALD. The epitaxial growth can include MOCVD and MBE. When the semiconductor crystal layer 106 is made of a Group III-V compound semiconductor and formed by MOCVD, the source gas can be trimethylgallium (TMGa), trimethylaluminum (TMA), trimethylindium (TMIn), arsine (AsH₃), PH₃ (phosphine) or the like. When the semiconductor crystal layer 106 is made of a Group IV compound semiconductor and formed by CVD, the source gas can be germane (GeH₄), silane (SiH₄), disilane (Si₂H₆) or the like. The carrier gas can be hydrogen. Alternatively, a compound that is obtained by replacing some of the hydrogen atom groups of the above-described source gas with chlorine atoms or hydrocarbon groups can be used. The temperature at which the reaction takes place can be selected appropriately within the range of 300° C. to 900° C., preferably within the range of 400° C. to 800° C. The thickness of the semiconductor crystal layer 106 can be controlled by appropriately determining the amount of the source gas to be supplied and the duration of the reaction.

Subsequently, as shown in FIG. 2, the semiconductor crystal layer 106 is subjected to etching so as to partly expose the sacrificial layer 104. As a result, the semiconductor crystal layer 106 is divided into a plurality of divided pieces 108. This etching forms grooves 110 between adjacent ones of the divided pieces 108. Here, the expression “so as to partly expose the sacrificial layer 104” means the following cases where the sacrificial layer 104 is substantially exposed in the etched regions in which the grooves 110 are formed. Firstly, the sacrificial layer 104 is completely etched away at the bottoms of the grooves 110 and the semiconductor crystal layer forming wafer 102 is exposed at the bottoms of the grooves 110, so that the vertical cross-sections of the sacrificial layer 104 are exposed as part of the lateral planes of the grooves 110. Secondly, the grooves 110 are engraved in the semiconductor crystal layer forming wafer 102, so that the vertical cross-sections of the sacrificial layer 104 are exposed as part of the lateral planes of the grooves 110. Thirdly, the etching is performed halfway through the sacrificial layer 104 in the regions in which the grooves 110 are formed so that the sacrificial layer 104 is exposed at the bottoms of the grooves 110. Fourthly, the semiconductor crystal layer 106 remains on part of the bottoms of the grooves 110 so that the sacrificial layer 104 is partially exposed at the bottoms of the grooves 110. Fifthly, the semiconductor crystal layer 106 is very thinly left all over the bottoms of the grooves 110 but the thickness of the remaining semiconductor crystal layer 106 is thin enough to allow the etching solution to penetrate through the semiconductor crystal layer 106 and the sacrificial layer 104 is substantially exposed.

The etching performed to form the grooves 110 can be either dry or wet etching. In the case of dry etching, the etching gas can be a halogen gas such as SF₆, CH₄₋ₓFₓ (x=an integer from 1 to 4). In the case of wet etching, the etching solution can be HCl, HF, phosphoric acid, citric acid, hydrogen peroxide solution, ammonia, and an aqueous solution of sodium hydroxide. A mask for the etching may be made of an organic or inorganic matter that provides an appropriate etching selectivity ratio. By patterning the mask, any pattern for the grooves 110 can be formed. For the etching performed to form the grooves 110, the semiconductor crystal layer forming wafer 102 can be used as an etching stopper, but it is desirable to stop the etching when the etching reaches the surface or middle of the sacrificial layer 104 considering that the semiconductor crystal layer forming wafer 102 is recycled. When the semiconductor crystal layer 106 is thin, for example, when the thickness of the semiconductor crystal layer 106 is 2 μm or less, it may be desirable to engrave the grooves 110 down into the semiconductor crystal layer forming wafer 102.

As a result of the presence of the grooves 110, the etching solution is supplied through the grooves 110 while the etching is performed on the sacrificial layer 104. If a large number of grooves 110 are formed, the distance in the sacrificial layer 104 which the etching solution needs to travel (in other words, the distance from the grooves 110 to the most distant portion of the sacrificial layer 104) can be made shorter, and the sacrificial layer 104 can be removed within a shorter period of time. Here, the grooves 100 may have a planar pattern of any shape. Stated differently, the planar shape of the semiconductor crystal layer 106 that has been divided by the grooves 110 may be shaped like a strip, a quadrangle, a rectangle or any other shapes.

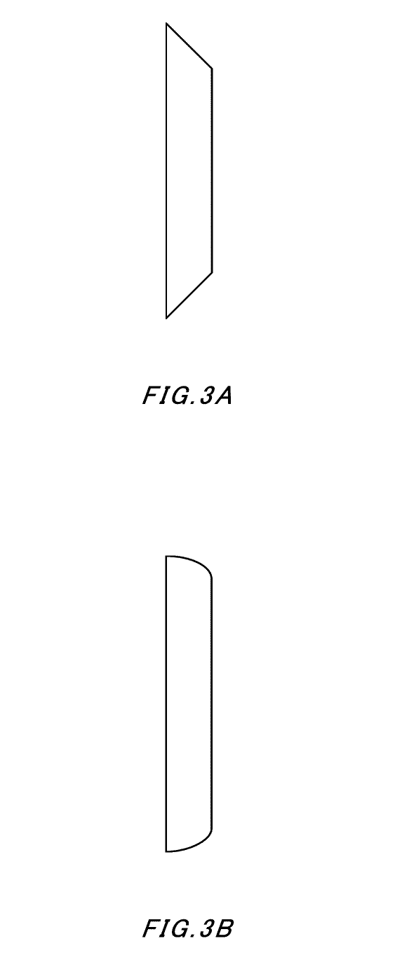

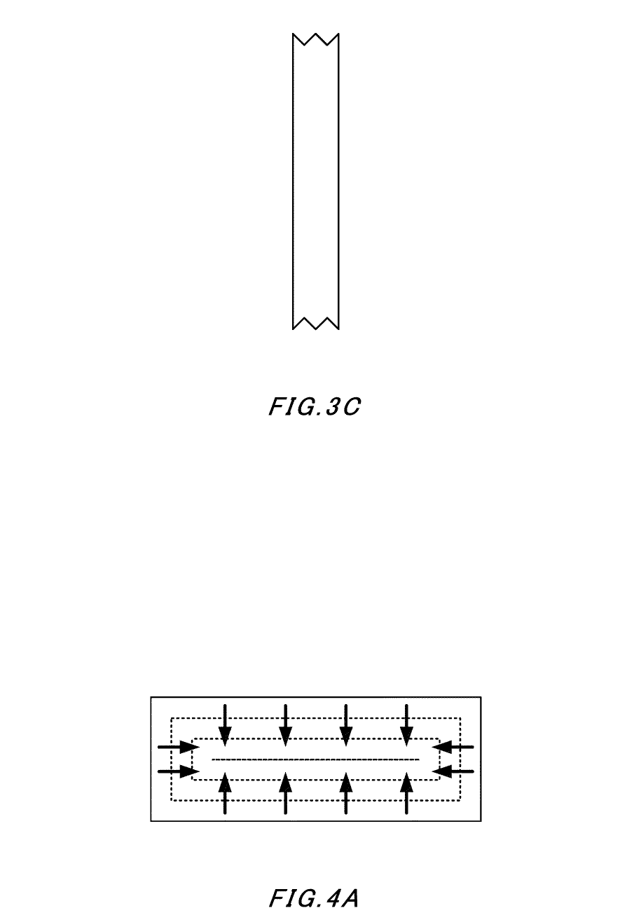

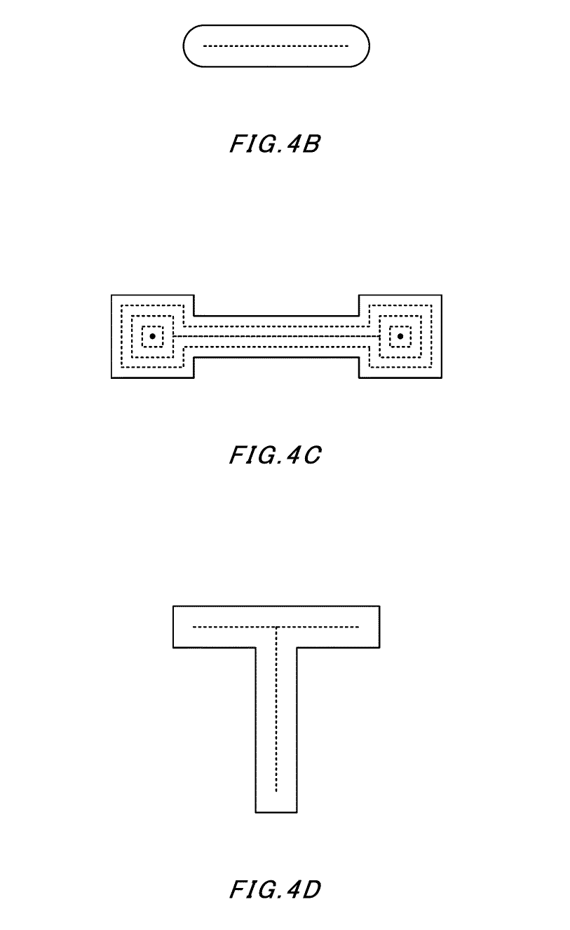

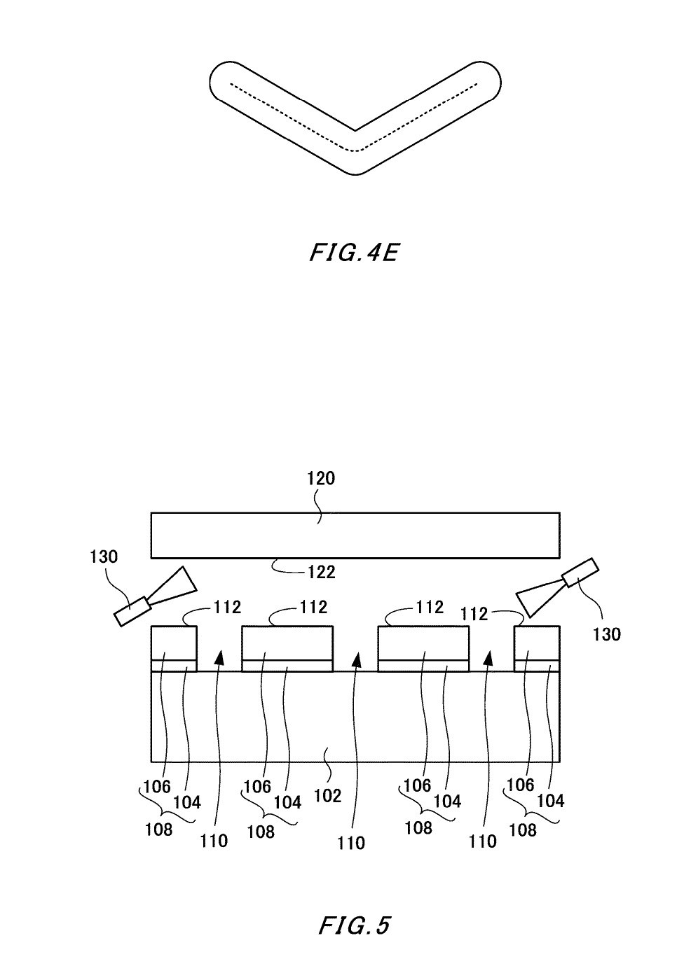

The planar shape (the planar shape of the divided pieces 108) of the semiconductor crystal layer 106 that has been divided by the grooves 110 is preferably such a planar shape that, when the planar shape is assumed to shrink and disappear at equal rates from each point on the edges of the divided piece 108 in a normal direction at the point, a shape observed immediately before the disappearance due to the shrinkage is not a single point but a single line, a plurality of lines or a plurality of points. Under this assumption, the shrinkage of the planar shape starts simultaneously at each point. Here, the edge indicates the line defining the perimeter of the planar shape, and the planar shape indicates the shape of the plane that is perpendicular to the stacking direction of the layers. The planar shape is assumed to shrink and disappear in the above, but the semiconductor crystal layer 106 does not actually shrink and disappear and the planar shape is hypothetically manipulated to shrink and disappear in order to define the planar shape. In the present example, the planar shape before the shrinkage (in other words, the actual planar shape of the semiconductor crystal layer 106) is defined based on the shape that is observed immediately before the disappearance due to the hypothetical manipulation. The planar shape of the divided pieces 108 can preferably be a planar shape enclosed by two parallel line segments and two lines that connect the ends of the two line segments. Note that, however, the planar shape of the semiconductor crystal layer 106 is a shape other than a precise circle and a regular polygon having n vertices (n is an integer equal to or more than 3). For example, at least one of the four line segments may be different in length from the others. The longest one of the edges defining the planar shape of the semiconductor crystal layer 106 may be twice, four times, ten times or more as large as the shortest one of the edges. The lines connecting the ends can be linear lines, curved lines or polylines. FIG. 3A shows an exemplary planar shape in which linear lines connect the ends of two parallel line segments. FIG. 3B shows an exemplary planar shape in which curved lines connect the ends of two parallel line segments. FIG. 3C shows an exemplary planar shape in which polylines connect the ends of two parallel line segments. When the two lines connecting the ends are both linear and also perpendicular to the two parallel line segments, the planar shape is a rectangle. In the case of a rectangular planar shape, when the planar shape of the divided piece shrinks at equal rates as shown by the arrows in FIG. 4A, the divided piece that has shrunk have a planar shape indicated by a dotted line, specifically speaking, a linear line immediately before the disappearance. Furthermore, when the divided pieces 108 shaped like long and narrow lines are arranged adjacent to each other so that a line-and-space pattern is formed and when the divided pieces 108 have a planar shape of a rounded rectangle as shown in FIG. 4B, the planar shape of the divided piece immediately before the disappearance is a linear line similarly to the rectangle shown in FIG. 4A. When the divided pieces 108 have a planar shape of “I” as shown in FIG. 4C, the planar shape immediately before the disappearance is represented by two points. When the divided pieces 108 have a planar shape of “T” as shown in FIG. 4D or the gull wing as shown in FIG. 4E, the planar shape immediate before the disappearance is a group of linear lines or a curved line.

During the etching step of the sacrificial layer 104, the gaseous product is believed to apply a force to the semiconductor crystal layer 106 in a direction away from the semiconductor crystal layer forming wafer 102. When the remaining sacrificial layer 104 concentrates on a single point immediately before the sacrificial layer 104 is entirely dissolved away, the force concentrates on the single point at which the sacrificial layer 104 remains. In this case, a relatively strong force is believed to be exerted to separate the semiconductor crystal layer 106 from the semiconductor crystal layer forming wafer 102. The impact resulting from the separation damages the semiconductor crystal layer 106. This is speculated to cause holes or concave portions to be created in the vicinity of the center of the pattern of the transferred semiconductor crystal layer 106. If the divided pieces 108 have the planar shapes shown in FIGS. 3A to 3C and FIGS. 4A to 4E, the sacrificial layer 104 does not remain in a single point but in a plurality of points or in a linear line. This can alleviate the impact resulting from the separation of the semiconductor crystal layer 106 from the semiconductor crystal layer forming wafer 102. As a result, holes or concave portions can be prevented from being generated in the vicinity of the center of the pattern of the planar shape of the transferred semiconductor crystal layer 106, and transfer defects can be reduced.

After this, as shown in FIG. 5, an adhesiveness enhancement treatment is performed on the surface of the transfer target wafer 120 and the surface of the semiconductor crystal layer 106 in order to enhance the adhesiveness between the transfer target wafer 102 and the semiconductor crystal layer 106. Here, in the regions excluding the grooves 110, the surface of the semiconductor crystal layer 106, which is provided on the semiconductor crystal layer forming wafer 102, is one example of “a first surface 112,” which is the surface of the layer formed on the semiconductor crystal layer forming wafer 102. Furthermore, the surface of the transfer target wafer 120 is one example of “a second surface 122,” which is the surface of the transfer target wafer 120 or the surface of the layer formed on the transfer target wafer 120. The first surface 112 and the second surface 122 come into contact with each other when the transfer target wafer 120 is bonded to the semiconductor crystal layer forming wafer 102.

The adhesiveness enhancement treatment may be performed only on one of the surface of the transfer target wafer 120 (the second surface 122) and the surface of the semiconductor crystal layer 106 (the first surface 112). The adhesiveness enhancement treatment can be, for example, ion beam activation performed by an ion beam generator 130. The ions to be applied are, for example, argon ions. Alternatively, the adhesiveness enhancement treatment may be plasma activation. The plasma activation can be, for example, an oxygen plasma treatment. The adhesiveness enhancement treatment can contribute to enhance the adhesiveness between the transfer target wafer 120 and the semiconductor crystal layer 106. Note that the adhesiveness enhancement treatment is not essential. The adhesiveness enhancement treatment may be replaced with formation of an adhesiveness layer on the transfer target wafer 120 in advance.

The transfer target wafer 120 is a wafer to which the semiconductor crystal layer 106 is to be transferred. The transfer target wafer 120 can be a target wafer on which an electronic device that uses the semiconductor crystal layer 106 as an active layer is eventually formed, or a provisional wafer on which the semiconductor crystal layer 106 is temporarily placed until the semiconductor crystal layer 106 is transferred onto the target wafer. The transfer target wafer 120 is made of an inorganic matter. The transfer target wafer 120 can be, for example, a silicon wafer, a silicon on insulator (SOI) wafer, a glass wafer, a sapphire wafer, a SiC wafer, and an AlN wafer. Additionally, the transfer target wafer 120 may be an insulative wafer such as a ceramics wafer, or an electrically-conductive wafer made of a metal, for example. When the transfer target wafer 120 is a silicon wafer or SOI wafer, a production apparatus that is used for existing silicon processes can be used. The research, development and production can be conducted more efficiently utilizing the common knowledge known in the field of silicon processes.

When the transfer target wafer 120 is a hard wafer that does not easily bend, such as a silicon wafer, the semiconductor crystal layer 106 to be transferred is protected against mechanical vibration and the like and the high crystallinity of the semiconductor crystal layer 106 can be maintained.

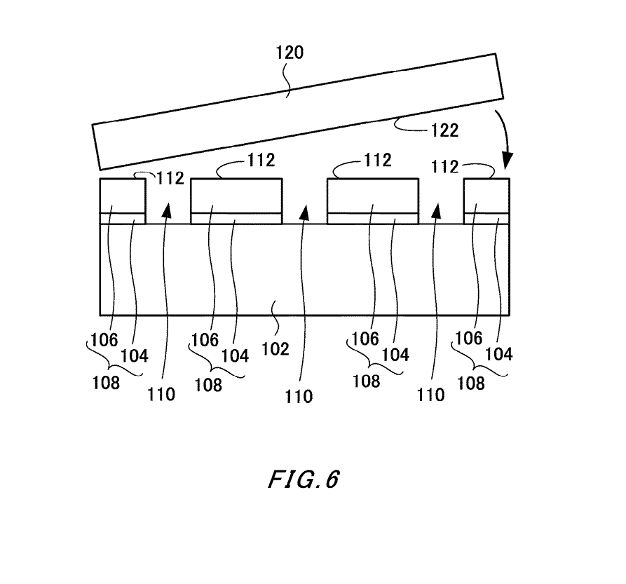

Subsequently, as shown in FIG. 6, the transfer target wafer 120 and the semiconductor crystal layer forming wafer 102 are bonded to each other in such a manner that the surface of the transfer target wafer 120 (the second surface 122) faces the surface of the semiconductor crystal layer 106 of the semiconductor crystal layer forming wafer 102 (the first surface 112). In the bonding step, the transfer target wafer 120 is bonded to the semiconductor crystal layer forming wafer 102 in such a manner that the surface of the semiconductor crystal layer 106, which is the first surface 112, is bonded to the surface of the transfer target wafer 120, which is the second surface 122. When the adhesiveness enhancement treatment is performed, the bonding step can be performed at room temperature.

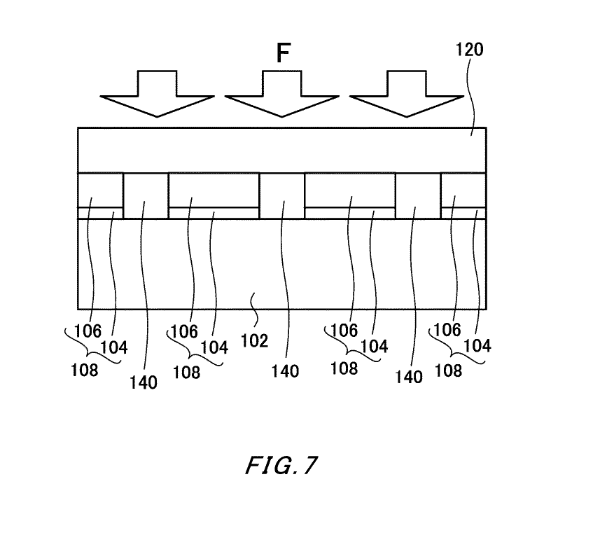

Subsequently, as shown in FIG. 7, a load F is applied onto the transfer target wafer 120 and the semiconductor crystal layer forming wafer 102, so that the transfer target wafer 120 is attached under pressure onto the semiconductor crystal layer forming wafer 102. This attaching step under pressure can improve the adhesiveness strength. During or after the attaching step under pressure, a thermal treatment may be performed. The temperature at which the thermal treatment takes place is preferably within the range of 50° C. to 600° C., more preferably within the range of 100° C. to 400° C. The load F can be selected as appropriate within the range of 0.01 MPa to 1 GPa. As a result of this attaching step under pressure, spaces 140 are formed between the inner wall of the grooves 110 and the surface of the transfer target wafer 120. Note that, when the transfer target wafer 120 is attached onto the semiconductor crystal layer forming wafer 102 using an adhesive layer, the attaching step under pressure is not necessary. Also, the attaching step under pressure is not essential even when the adhesive layer is not employed.

In the above description with reference to FIGS. 6 and 7, the bonding step was described as a separate step from the attaching step under pressure. However, the surface of the transfer target wafer 120 (the second surface 122) may be positioned so as to face the surface of the semiconductor crystal layer 106 on the semiconductor crystal layer forming wafer 102 (the first surface 112) and the transfer target wafer 120 and the semiconductor crystal layer forming wafer 120 may be bonded and attached under pressure within the range of 0.01 MPa to 1 GPa simultaneously. Strictly speaking, the period of time from when bonding is performed to when a predetermined pressure is reached cannot be actually reduced to zero. Therefore, “simultaneously” in the above indicates that the bonding step and the attaching step under pressure cannot be distinguished as two steps and can only be considered as a single step.

If the semiconductor crystal layer forming wafer 102 having the semiconductor crystal layer 106 formed thereon is bonded to the transfer target wafer 120 and they are subsequently attached to each other under pressure, or if the semiconductor crystal layer forming wafer 102 is positioned so as to face the transfer target wafer 120 and they are bonded to each other and attached to each other under pressure simultaneously, the semiconductor crystal layer 106 is generally attached to the transfer target wafer 120 excellently and the semiconductor crystal layer 106 is expected to be excellently transferred onto the transfer target wafer 120. On the other hand, if too much pressure is applied, an unnecessarily large load is applied onto the semiconductor crystal layer 106 and some disadvantages may occur, for example, the degraded crystallinity of the semiconductor crystal layer 106. If a hard wafer such as a silicon crystal wafer is used as the transfer target wafer 120 and the pressure is adjusted during the bonding step or attaching step under pressure, compressive strain or tensile strain can be generated in the semiconductor crystal layer 106 (the divided pieces 108). This allows the semiconductor crystal layer 106 to be used as an active layer of a strained device.

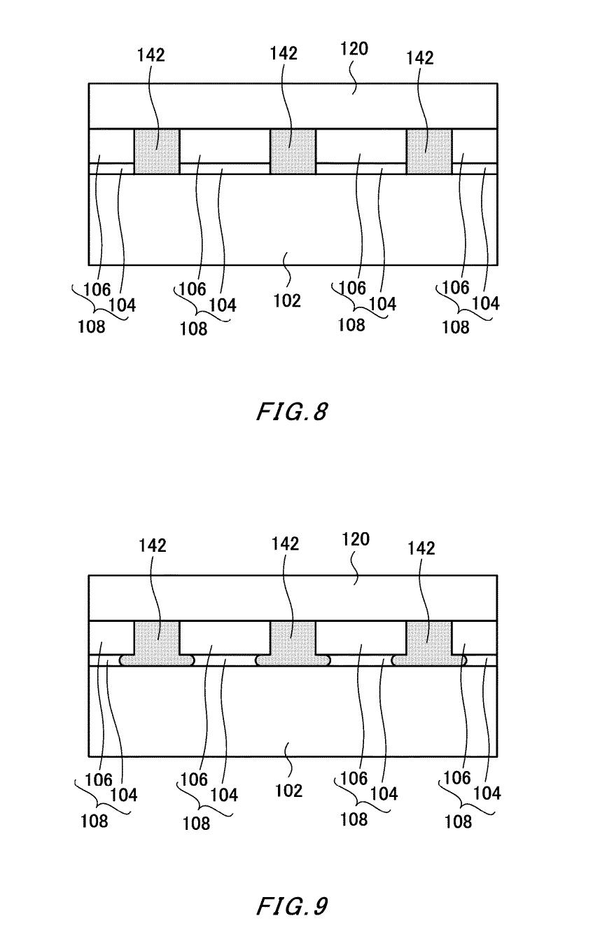

Subsequently, as shown in FIG. 8, the etching solution 142 is supplied to the spaces 140. The etching solution 142 can be supplied to the spaces 140 in any of the following methods. The etching solution 142 can be supplied into the spaces 140 using capillary action. The etching solution 142 can be forcibly supplied into the spaces 140 in such a manner that the ends of the spaces 140 on one side are immersed into the etching solution 142 and the etching solution 142 is suctioned from the ends on the other side. When the ends of the spaces 140 at one side are open and the ends at the other side are closed, the etching solution 142 can be forcibly supplied into the spaces 140 in such a manner that the transfer target wafer 120 and the semiconductor crystal layer forming wafer 102 are placed under reduced pressure and the open ends of the spaces 140 are immersed in the etching solution 142, after which the transfer target wafer 120 and the semiconductor crystal layer forming wafer 102 are placed under the atmospheric pressure.

A specific example of the method of supplying the etching solution 142 into the spaces 140 using capillary action is a method of allowing the etching solution 142 to drip onto the ends of the spaces 140 on one side. To supply the etching solution 142 into the spaces 140 using capillary action, the ends of the spaces 140 at the other end needs to be open. When the etching solution 142 is supplied into the spaces 140 by allowing the etching solution 142 to drip onto the ends of the spaces 140 at one end, the etching solution 142 can be supplied into the spaces 140 in a simple and reliable manner. The etching starts when the etching solution 142 drips onto the ends of the spaces 140 at one side. After the spaces 140 are filled with the etching solution 142, the transfer target wafer 120 and the semiconductor crystal layer forming wafer 102 can be entirely immersed into an etching bath that is filled with the etching solution 142 to cause the etching to proceed. Alternatively, the etching can be allowed to proceed by continuously supplying the etching solution 142 to the ends of the spaces 140 at one side. When the etching solution 142 continues to be supplied to the ends of the spaces 140 at one side by dripping, the etching uses only a small amount of the etching solution 142 and the necessary amount of the etching solution 142 can be reduced. Consequently, the production cost can be reduced and environmental damage resulting from the disposal of the etching solution 142 can be reduced.

Before the transfer target wafer 120 and the semiconductor crystal layer forming wafer 102 are bonded to each other, the inside of the grooves 110 can be made hydrophilic. If the inside of the grooves 110 are made hydrophilic, the etching solution can be smoothly supplied into the spaces 140. A method of making the inside of the grooves 110 hydrophilic can be, for example, a method of exposing the inside of the grooves 110 to a HCl gas, a method of injecting hydrophilic ions (for example, hydrogen ions) into the inside of the grooves 110, or the like.

Subsequently, as shown in FIG. 9, the etching solution 142 that has been supplied into the spaces 140 is used to etch the sacrificial layer 104. The sacrificial layer 104 can be selectively etched away. Here, the expression “to selectively etch away” means that the sacrificial layer 104 is “selectively” etched away substantially alone by selecting the etching solution and other conditions in such a manner that the sacrificial layer 104 and other constituents, for example, the semiconductor crystal layer 106, are similarly exposed to the etching solution and etched away but the etching rate of the sacrificial layer 104 is controlled to be higher than the etching rate of the other constituents. When the sacrificial layer 104 is an AlAs layer, the etching solution 142 can be, for example, HCl, HF, phosphoric acid, citric acid, hydroperoxide solution, ammonia, an aqueous solution of sodium hydroxide or water. During the etching, the temperature is preferably controlled to fall within the range of 10° C. and 90° C. The duration of the etching can be controlled as appropriate to fall within the range of 1 minute to 200 hours.

When the sacrificial layer 104 is made of AlₓGa₁₋ₓAs (0.9≦x≦1), the sacrificial layer 104 can be removed by etching using an HCl aqueous solution as the etchant. In this case, the concentration of the HCl aqueous solution is preferably no less than 5% by mass and no more than 25% by mass. If the etchant concentration of the etching solution used to etch the sacrificial layer is low, it takes long to complete the etching and is not preferable. On the other hand, if the etchant concentration is high, the etching produces a particular material at high speed and the etching-related problems may deteriorate.

The sacrificial layer 104 can be etched away with an ultrasonic wave being applied to the insides of the spaces 140 that are filled with the etching solution 142 while the sacrificial layer is being etched. The application of an ultrasonic wave can increase the etching rate. Furthermore, while the etching is being performed, an ultraviolet ray may be applied or the etching solution may be stirred. Here, the above describes an exemplary case where the sacrificial layer 104 is etched using the etching solution 142. However, the sacrificial layer 104 can be etched away using dry etching.

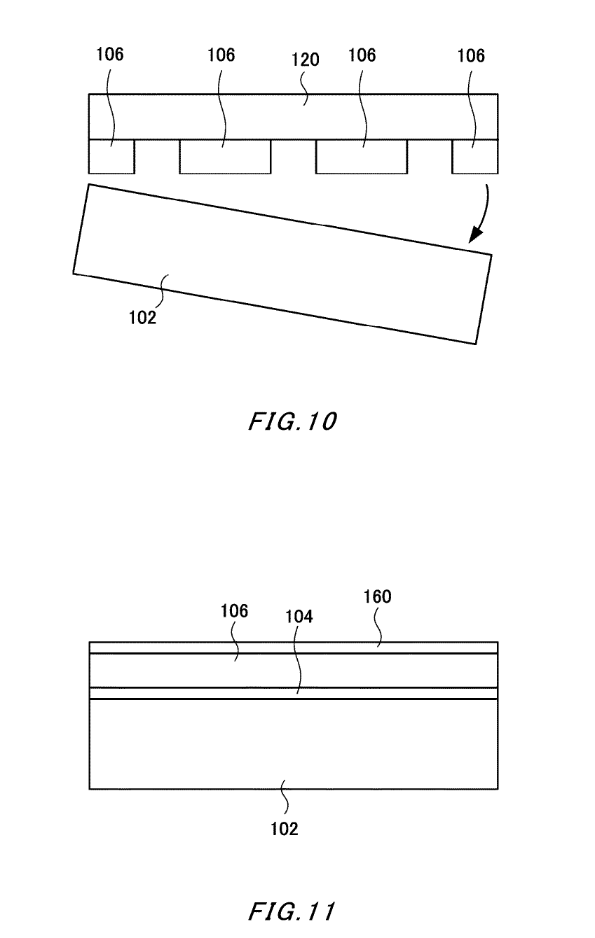

If the sacrificial layer 104 is removed by the etching in the above-described manner, the transfer target wafer 120 is separated from the semiconductor crystal layer forming wafer 102 with the semiconductor crystal layer 106 being left on the transfer target wafer 120 as shown in FIG. 10. Thus, the semiconductor crystal layer 106 is transferred onto the transfer target wafer 120 and a composite wafer in which the semiconductor crystal layer 106 is provided on the transfer target wafer 120 is produced.

According to the method of producing a composite wafer relating to the first embodiment, the semiconductor crystal layer forming wafer 102 is attached to the transfer target wafer 120 under pressure after the adhesiveness enhancement treatment is performed. Therefore, the semiconductor crystal layer 106 can be reliably transferred onto the transfer target wafer 120. In addition, since the grooves 110 are formed, the spaces 140 are formed. The etching solution can be supplied through the spaces 140 to perform etching on the sacrificial layer 104. Therefore, the sacrificial layer 104 can be swiftly etched and removed even if the transfer target wafer 120 is a non-flexible hard wafer. Accordingly, the transfer target wafer 120 can be swiftly separated from the semiconductor crystal layer forming wafer 102, which can improve the production throughput.

### Second Embodiment

FIGS. 11 to 14 are cross-sectional views illustrating steps of a method of producing a composite wafer relating to a second embodiment in the performed order. In the second embodiment, an adhesive layer 160 is formed between the semiconductor crystal layer 106 and the transfer target wafer 120. Specifically speaking, the semiconductor crystal layer 106 is bonded to the transfer target wafer 120 after the adhesive layer 160 is formed on the surface of at least one of the semiconductor crystal layer 106 and the transfer target wafer 120. The production method relating to the second embodiment has many common features with the production method relating to the first embodiment. Therefore, the following mainly describes differences between the first embodiment and the second embodiment and does not describe the common features.

As shown in FIG. 11, after the sacrificial layer 104 and the semiconductor crystal layer 106 are formed, the adhesive layer 160 is formed on the semiconductor crystal layer 106. The adhesive layer 160 is designed to enhance the adhesiveness between the semiconductor crystal layer 106 and the transfer target wafer 120 and made of an inorganic material. Since the adhesive layer 160 is made of an inorganic material, the adhesive layer 160 is advantageously handled in a secure manner even if the subsequent steps include a high-temperature step that is performed at approximately several hundred degrees Celsius. Furthermore, since the adhesive layer 160 is made of an inorganic material, the adhesive layer 160 can be used to form an insulating layer and the like of a device to be formed later and contribute to simplify the production process.

The adhesive layer 160 can be, for example, a layer made of at least one of Al₂O₃, AlN, Ta₂O₅, ZrO₂, HfO₂, SiOₓ (for example, SiO₂), SiNₓ (for example, Si₃N₄), and SiOₓN_{y}, or a laminate obtained by stacking at least two layers respectively made of the above-listed materials. In this case, the adhesive layer 160 can be formed by ALD, thermal oxidation, evaporation, CVD or sputtering. The thickness of the adhesive layer 160 can be within the range of 0.1 nm to 100 μm.

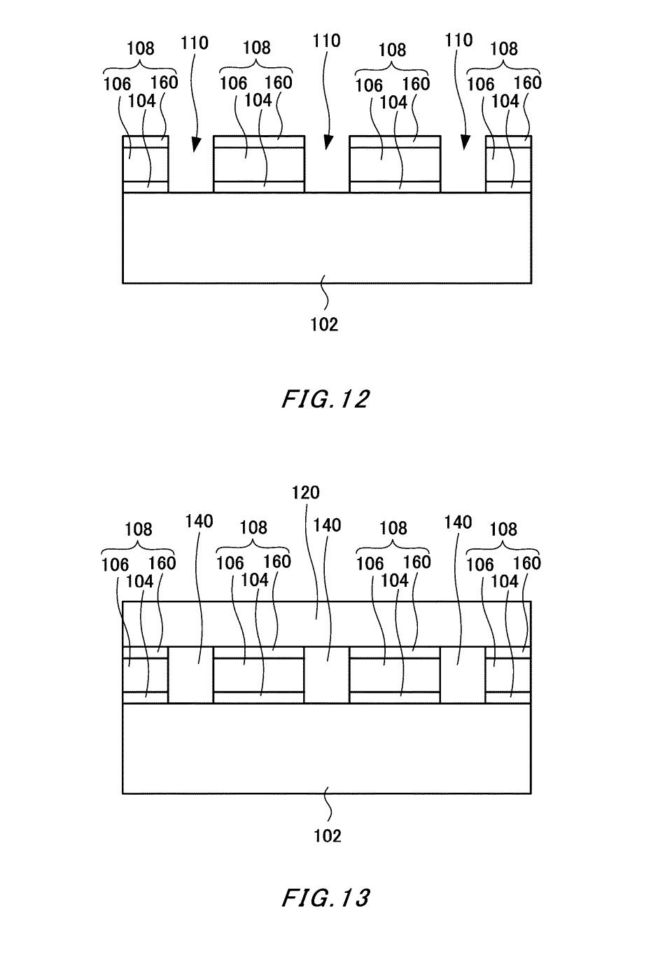

Subsequently, as shown in FIG. 12, the adhesive layer 160 and the semiconductor crystal layer 106 are etched to partially expose the sacrificial layer 104. In this way, the grooves 110 are formed. The grooves 110 are formed in the same manner as in the first embodiment. After this, as shown in FIG. 13, the transfer target wafer 120 and the semiconductor crystal layer forming wafer 102 are bonded to each other in such a manner that the surface of the transfer target wafer 120 is bonded onto the surface of the adhesive layer 160 in the regions excluding the grooves 110. Here, the surface of the adhesive layer 160 in the regions excluding the grooves 110 is one example of “the first surface 112,” which is the surface of the layer formed on the semiconductor crystal layer forming wafer 102 and to be bonded onto the transfer target wafer 120 or the layer formed on the transfer target wafer 120. The surface of the transfer target wafer 120 is one example of “the second surface 122,” which is the surface of the transfer target wafer 120 or the layer formed on the transfer target wafer 120 and to be bonded onto the first surface 112. In the bonding step, the transfer target wafer 120 and the semiconductor crystal layer forming wafer 102 are bonded to each other in such a manner that the surface of the adhesive layer 160, which is the first surface 112, is bonded onto the surface of the transfer target wafer 120, which is the second surface 122. The bonding step is performed in the same manner as in the first embodiment.

The second embodiment is the same as the first embodiment in that, after the grooves 110 are formed and before the transfer target wafer 120 and the semiconductor crystal layer forming wafer 102 are bonded to each other, the adhesiveness enhancement treatment to enhance the adhesiveness between the transfer target wafer 120 and the adhesive layer 160 is performed on one or more surfaces selected from the surface of the transfer target wafer 120 and the surface of the adhesive layer 160. Furthermore, the second embodiment is the same as the first embodiment also in that the transfer target wafer 120 and the semiconductor crystal layer forming wafer 102 can be attached to each other under pressure within the range of 0.01 MPa to 1 GPa in the bonding step.

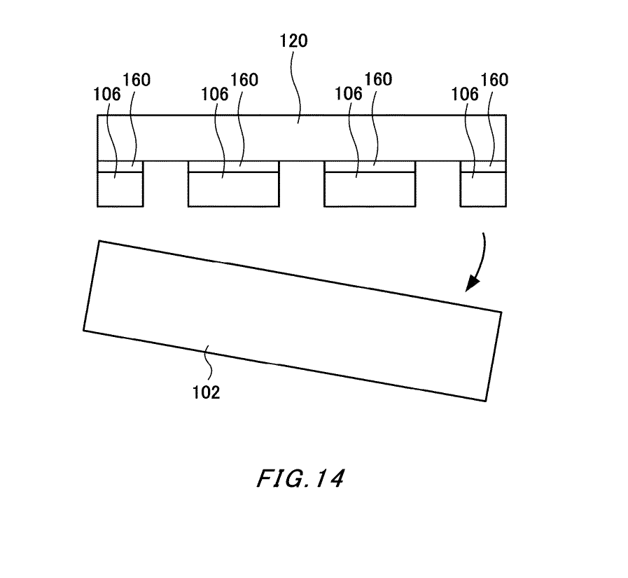

After this, the sacrificial layer 104 is etched away. In this manner, as shown in FIG. 14, the transfer target wafer 120 is separated from the semiconductor crystal layer forming wafer 102 with the adhesive layer 160 and the semiconductor crystal layer 106 being left on the transfer target wafer 120. The separation is performed in the same manner as in the first embodiment. Thus, the adhesive layer 160 and the semiconductor crystal layer 106 are transferred onto the transfer target wafer 120 and a composite wafer in which the adhesive layer 160 and the semiconductor crystal layer 106 are provided on the transfer target wafer 120 is produced. The second embodiment is the same as the first embodiment in that the sacrificial layer 104 may be etched away using dry etching.

According to the above-described method of producing a composite wafer relating to the second embodiment, the presence of the adhesive layer 160 increases the reliability of the attachment between the transfer target wafer 120 and the semiconductor crystal layer 106. Since the adhesive layer 160 is made of an inorganic material, the subsequent steps are advantageously not thermally limited.

Using the composite wafer relating to the first or second embodiment, the semiconductor crystal layer 106 on the transfer target wafer 120 may be further transferred onto a second transfer target wafer. In this case, the adhesive layer 160 can be used as a sacrificial layer for transferring the semiconductor crystal layer 106 onto the second transfer target wafer. In addition, an adhesive layer may be formed between the second transfer target wafer and the semiconductor crystal layer 106.

After the sacrificial layer 104 and the semiconductor crystal layer 106 are formed on the semiconductor crystal layer forming wafer 102 and before the semiconductor crystal layer forming wafer 102 and the transfer target wafer 120 are bonded to each other, an electronic device whose active region is constituted by a portion of the semiconductor crystal layer 106 may be formed on the semiconductor crystal layer 106. In this case, the semiconductor crystal layer 106 is transferred with the electronic device being formed thereon. Since the semiconductor crystal layer 106 is flipped each time it is transferred, this method enables electronic devices to be formed on both of the front and back planes of the semiconductor crystal layer 106.

When the planar shape of the semiconductor crystal layer 106 is characterized as shown in FIGS. 3A to 3C and FIGS. 4A to 4E, the present invention can be embodied as a composite wafer having the transferred semiconductor crystal layer 106. Specifically speaking, the present invention can be embodied as a composite wafer that includes the transfer target wafer 120 and the semiconductor crystal layer 106 that is formed on the transfer target wafer 120 by the transfer technique, wherein the semiconductor crystal layer 106 has the plurality of divided pieces 108 and the planar shape of one or more of the divided pieces 108 is configured such that, when the divided pieces 108 are assumed to shrink and disappear at equal rates from each point on the edges of the divided pieces 108 in a normal direction at the point, a shape observed immediately before the disappearance due to the shrinkage is not a single point but a single line, a plurality of lines or a plurality of points.

### Third Embodiment

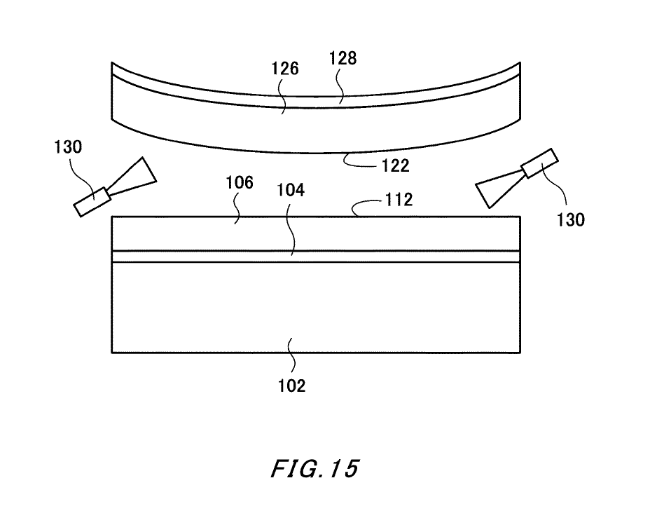

FIGS. 15 to 19 are cross-sectional or plan views that illustrate steps of a method of producing a composite wafer relating to a third embodiment in the performed order. According to the production method relating to the third embodiment, the sacrificial layer 104 and the semiconductor crystal layer 106 are formed on the semiconductor crystal layer forming wafer 102 in the order of the sacrificial layer 104 and the semiconductor crystal layer 106 as shown in FIG. 1, which describes the first embodiment. The third embodiment is the same as the first embodiment in terms of the semiconductor crystal layer forming wafer 102, the sacrificial layer 104 and the semiconductor crystal layer 106.

Subsequently, as shown in FIG. 15, the adhesiveness enhancement treatment is performed on the surface of a transfer target wafer 126 and the surface of the semiconductor crystal layer 106 to enhance the adhesiveness between the transfer target wafer 126 and the semiconductor crystal layer 106. Here, the surface of the semiconductor crystal layer 106 is one example of “the first surface 112,” which is the surface of the layer formed on the semiconductor crystal layer forming wafer 102 and is designed to come into contact with the transfer target wafer 126 or the layer formed on the transfer target wafer 126. The surface of the transfer target wafer 126 is one example of “the second surface 122,” which is the surface of the transfer target wafer 126 or the layer formed on the transfer target wafer 126 and designed to come into contact with the first surface 112. The adhesiveness enhancement treatment is the same as the adhesiveness enhancement treatment relating to the first embodiment.

The transfer target wafer 126 is a wafer to which the semiconductor crystal layer 106 is to be transferred. The transfer target wafer 126 may be a target wafer on which an electronic device that uses the semiconductor crystal layer 106 as its active layer is eventually arranged, or a provisional wafer on which the semiconductor crystal layer 106 is temporarily positioned until the semiconductor crystal layer 106 is transferred onto the target wafer. The transfer target wafer 126 is made of an inorganic material and a curved flexible wafer one of whose planes is a convex plane and the other plane is a concave plane in the free state. The transfer target wafer 126 can be made curved by forming a tensile strain film on the plane on the concave side or forming a compressive strain film on the plane on the convex side. In the present embodiment, the transfer target wafer 126 can be made curved by forming a tensile strain film 128 on the plane on the concave side. The plane of the transfer target wafer 126 on the convex side is the second surface 122.

The transfer target wafer 126 can be, for example, a silicon wafer, a silicon on insulator (SOI) wafer, a glass wafer, a sapphire wafer, a SiC wafer, or an AlN wafer. Additionally, the transfer target wafer 126 may be an insulative wafer such as a ceramics wafer, or an electrically-conductive wafer made of a metal, for example. When the transfer target wafer 126 is a silicon wafer or SOI wafer, a production apparatus that is used for an existing silicon process can be used. The research and development, and production can be conducted more efficiently utilizing the common knowledge already known in the field of silicon process.

When the transfer target wafer 126 is a silicon wafer or the like, the transfer target wafer 126 is flexible but does not bend easily. Therefore, the semiconductor crystal layer 106 to be transferred is protected against mechanical vibration and the like and the high crystallinity of the semiconductor crystal layer 106 can be maintained. At the same time, since the transfer target wafer 126 is curved due to the tensile strain film 128, the transfer target wafer 126 is bent in a direction away from the semiconductor crystal layer forming wafer 102 in the step of etching the sacrificial layer 104, described later. Accordingly, the etching solution is swiftly supplied to the bent portion and the transfer target wafer 126 is swiftly separated from the semiconductor crystal layer forming wafer 102.

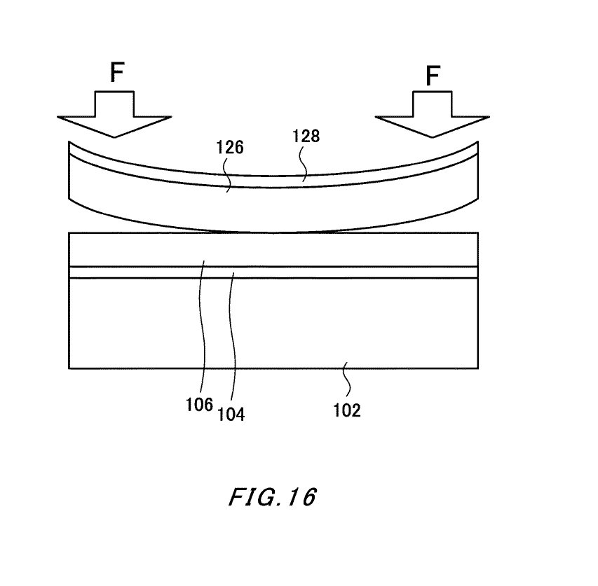

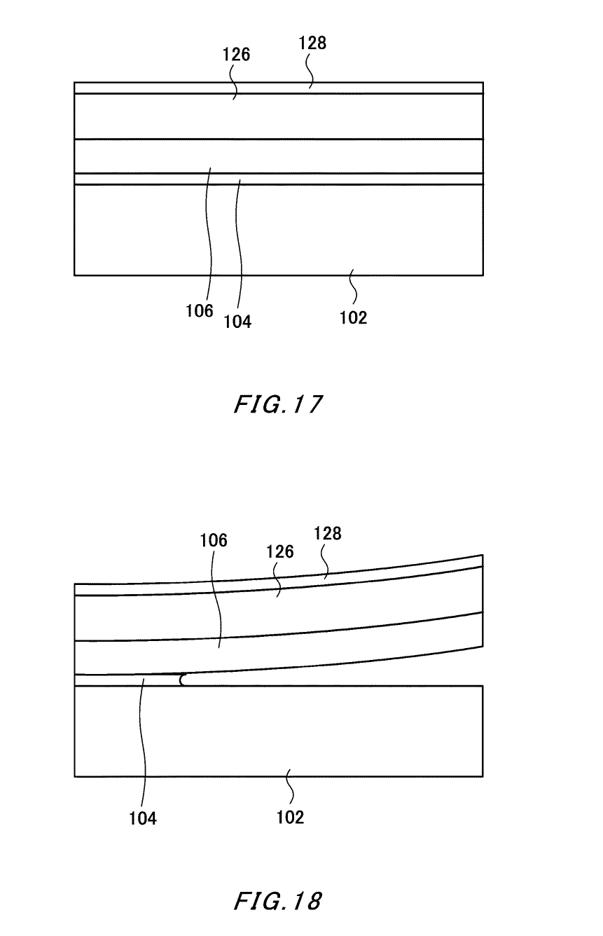

Subsequently, as shown in FIG. 16, the surface of the transfer target wafer 126 on the convex side (the second surface 122) is positioned so as to oppose the surface of the semiconductor crystal layer 106 on the semiconductor crystal layer forming wafer 102 (the first surface 112). In addition, as shown in FIG. 17, the transfer target wafer 126 and the semiconductor crystal layer forming wafer 102 are bonded to each other in such a manner that the surface of the semiconductor crystal layer 106, which is the first surface 112, is bonded to the surface of the transfer target wafer 126, which is the second surface 122. When the adhesiveness enhancement treatment is performed, the bonding step can be performed at room temperature.

In the bonding step, since the transfer target wafer 126 is curved, a load F that is high enough to press down the curved transfer target wafer 126 needs to be applied onto the transfer target wafer 126 and the semiconductor crystal layer forming wafer 102. A higher load may be applied to attach the transfer target wafer 126 to the semiconductor crystal layer forming wafer 102 under pressure. The step of attaching under pressure can improve the adhesiveness strength. A thermal treatment may be performed during or after the step of attaching under pressure. The temperature at which the thermal treatment takes place is preferably within the range of 50° C. to 600° C., more preferably within the range of 100° C. to 400° C. The load F can be selected as appropriate within the range of 0.01 MPa to 1 GPa. When the transfer target wafer 126 is attached to the semiconductor crystal layer forming wafer 102 using the adhesive layer, the step of attaching under pressure is not necessary. In addition, the step of attaching under pressure can be omitted even if the adhesive layer is not used.

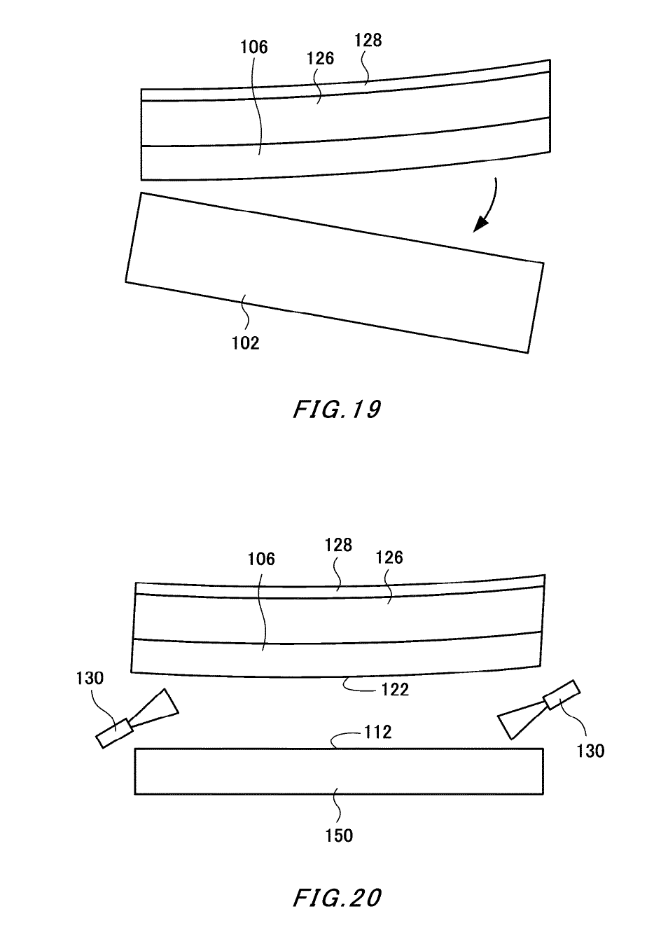

Subsequently, as shown in FIG. 18, the semiconductor crystal layer forming wafer 102 and the transfer target wafer 126 are entirely or partially (preferably, entirely) immersed into an etching solution to etch the sacrificial layer 104. If the sacrificial layer 104 is etched away, as shown in FIG. 19, the transfer target wafer 126 is separated from the semiconductor crystal layer forming wafer 102 with the semiconductor crystal layer 106 is left on the transfer target wafer 126.

In the step of separating the transfer target wafer 126 from the semiconductor crystal layer forming wafer 102, while the sacrificial layer 104 is etched, a portion of the transfer target wafer 126 that becomes disconnected from the semiconductor crystal layer forming wafer 102 is bent in the direction away from the semiconductor crystal layer forming wafer 102 due to the curve of the transfer target wafer 126. Thus, the etching solution can be supplied to the sacrificial layer 104 smoothly, and the transfer target wafer 126 can be separated from the semiconductor crystal layer forming wafer 102 swiftly.

The third embodiment is the same as the first embodiment in terms of the etching solution, the temperature during the etching, and the duration of the etching. Furthermore, the third embodiment is the same as the first embodiment in that the sacrificial layer 104 can be etched while an ultrasonic wave is applied to the etching solution, that an ultraviolet ray is applied during the etching, that the etching solution can be stirred, and the etching can be performed using dry etching.

If the sacrificial layer 104 is removed by etching in the above-described manner, the transfer target wafer 126 is separated from the semiconductor crystal layer forming wafer 102 with the semiconductor crystal layer 106 being left on the transfer target wafer 126 as shown in FIG. 19. Thus, the semiconductor crystal layer 106 is transferred onto the transfer target wafer 126 and a composite wafer in which the semiconductor crystal layer 106 is provided on the transfer target wafer 126 is produced.

According to the above-described method of producing a composite wafer relating to the third embodiment, while the sacrificial layer 104 is etched away, the portion of the transfer target wafer 126 that becomes disconnected from the semiconductor crystal layer forming wafer 102 is bent in the direction away from the semiconductor crystal layer forming wafer 102 using the curve of the transfer target wafer 126. Therefore, the etching solution is supplied to the sacrificial layer 104 smoothly and the transfer target wafer 126 can be swiftly separated from the semiconductor crystal layer forming wafer 102. This can improve the production throughput.

### Fourth Embodiment

FIGS. 20 to 24 are cross-sectional views illustrating the steps of a method of producing a composite wafer relating to a fourth embodiment in the performed order. In the fourth embodiment, using the composite wafer produced in the method relating to the third embodiment (the composite wafer in which the semiconductor crystal layer 106 is provided on the transfer target wafer 126), the semiconductor crystal layer 106 on the transfer target wafer 126 is further transferred onto a second transfer target wafer 150. In this manner, a composite wafer in which the semiconductor crystal layer 106 is provided on the second transfer target wafer 150 is produced.

As shown in FIG. 20, the adhesiveness enhancement treatment to enhance the adhesiveness between the second transfer target wafer 150 and the semiconductor crystal layer 106 is performed on the surface of the second transfer target wafer 150 and the surface of the semiconductor crystal layer 106. The adhesiveness enhancement treatment may be performed on one of the surface of the second transfer target wafer 150 and the surface of the semiconductor crystal layer 106. The adhesiveness enhancement treatment can be, for example, ion beam activation using the ion beam generator 130. The applied ions are, for example, argon ions. The adhesiveness enhancement treatment may be plasma activation. The adhesiveness enhancement treatment can contribute to enhance the adhesiveness between the second transfer target wafer 150 and the semiconductor crystal layer 106. Here, the adhesiveness enhancement treatment is not essential. The adhesiveness enhancement treatment may be replaced with a step of forming in advance an adhesive layer on the second transfer target wafer 150.

The second transfer target wafer 150 is a wafer to which the semiconductor crystal layer 106 is to be transferred, like the transfer target wafer 126. Like the transfer target wafer 126, the second transfer target wafer 150 may be the last target wafer or a provisional wafer. The materials and the like of the second transfer target wafer 150 are the same as those of the transfer target wafer 126 and thus not described.

Subsequently, as shown in FIG. 21, the transfer target wafer 126 and the second transfer target wafer 150 are bonded to each other in such a manner that the plane of the transfer target wafer 126 that includes the semiconductor crystal layer 106 is positioned so as to oppose the surface of the second transfer target wafer 150. In other words, the transfer target wafer 126 and the second transfer target wafer 150 are bonded to each other in such a manner that the surface of the semiconductor crystal layer 106 is bonded to the surface of the second transfer target wafer 150. When the adhesiveness enhancement treatment is performed, the bonding step can be performed at room temperature.

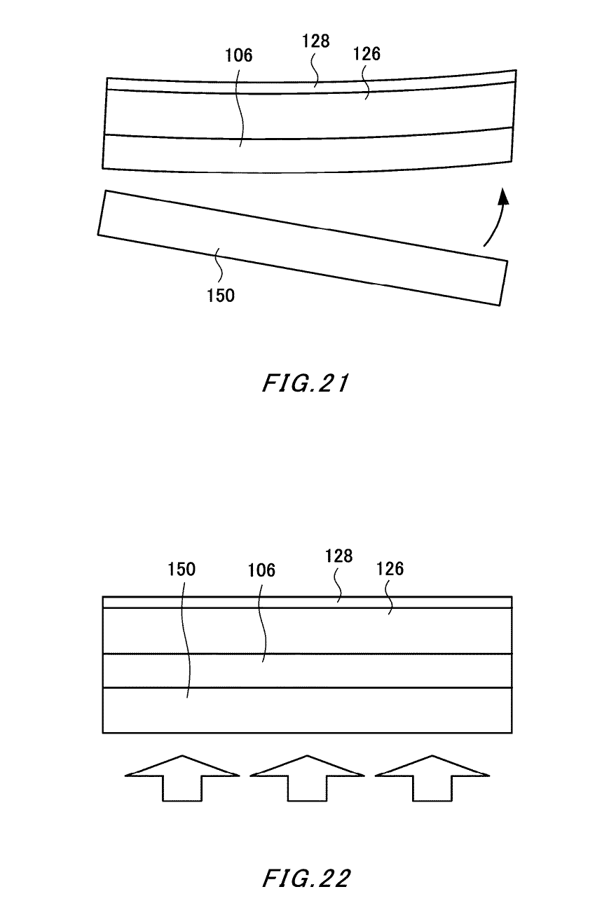

Subsequently, as shown in FIG. 22, a load F is applied to the second transfer target wafer 150 and the transfer target wafer 126 to attach the second transfer target wafer 150 to the transfer target wafer 126 under pressure. The load F can be selected as appropriate within the range of 0.01 MPa to 1 GPa. When the second transfer target wafer 150 and the transfer target wafer 126 are attached to each other using an adhesive layer, the step of attaching under pressure is not necessary. Furthermore, the step of attaching under pressure can be omitted even if the adhesive layer is not used.

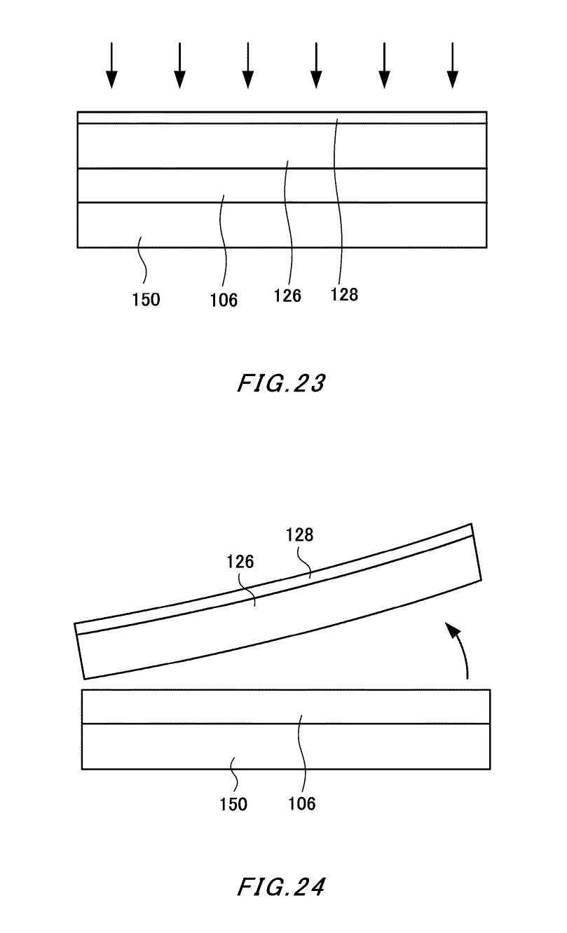

Furthermore, as shown in FIG. 23, the physical property of the interface that determines the adhesiveness between the transfer target wafer 126 and the semiconductor crystal layer 106 is changed. The physical property of the interface is changed by, for example, implanting hydrogen ions. By implanting hydrogen ions into the bonding interface between the transfer target wafer 126 and the semiconductor crystal layer 106, the adhesiveness of the interface can be reduced. Here, the ion implantation is performed with the acceleration voltage being adjusted in such a manner that the hydrogen ions stop at the interface.

If the adhesiveness of the bonding interface between the transfer target wafer 126 and the semiconductor crystal layer 106 is reduced as described above, the transfer target wafer 126 can be separated from the second transfer target wafer 150 with the semiconductor crystal layer 106 being left on the second transfer target wafer 150 as shown in FIG. 24. In this manner, the semiconductor crystal layer 106 is transferred onto the second transfer target wafer 150 and a composite wafer in which the semiconductor crystal layer 106 is provided on the second transfer target wafer 150 is produced.

According to the above-described method of producing a composite wafer relating to the fourth embodiment, the physical property of the interface between the transfer target wafer 126 and the semiconductor crystal layer 106 is changed to reduce the adhesiveness between the transfer target wafer 126 and the semiconductor crystal layer 106 after the transfer target wafer 126 is bonded to the second transfer target wafer 150. Therefore, the adhesiveness can be controlled depending on which of the transferring steps constituting a transfer phase is performed. Accordingly, the transfer phase including a plurality of transferring steps can be stably performed.

When there is an adhesive layer between the transfer target wafer 126 and the semiconductor crystal layer 106, the physical property of the adhesive layer can be changed. In the above-described embodiment, the physical property of the interface is changed in such a manner that the adhesiveness between the transfer target wafer 126 and the semiconductor crystal layer 106 is reduced. However, the physical property of the interface that determines the adhesiveness between the semiconductor crystal layer 106 and the second transfer target wafer 150, in other words, the physical property of the bonding interface between the semiconductor crystal layer 106 and the second transfer target wafer 150 may be changed in such a manner that the adhesiveness is enhanced. When there is an adhesive layer between the semiconductor crystal layer 106 and the second transfer target wafer 150, the physical property of the adhesive layer can be changed.

The physical property to be changed may be etching resistance in addition to the adhesiveness of the interface. For example, when there is a sacrificial layer between the transfer target wafer 126 and the semiconductor crystal layer 106 and there is an adhesive layer between the semiconductor crystal layer 106 and the second transfer target wafer 150, the adhesive layer has an amorphous phase that enables the adhesive layer to have superior adhesiveness during the step of attaching the semiconductor crystal layer 106 and the second transfer target wafer 150 and the phase of the adhesive layer may be changed from the amorphous phase to a polycrystalline phase (the physical property is changed) in order to obtain superior etching resistance when the transfer target wafer 126 is separated from the second transfer target wafer 150 by etching the sacrificial layer.

When the physical property is changed to change the etching resistance, in addition to the above-described method of changing the crystalline phase, heat, an ultraviolet ray or the like may be applied to an organic material to cure the organic material to increase the etching resistance of the organic material, ions or strains may be introduced into a crystal to increase crystal defects and thus to lower the etching resistance, or other methods are shown as an example. Alternatively, when the physical property is changed to increase the adhesiveness, the interface may be activated, for example. When the physical property is changed to lower the adhesiveness, an organic material may be swollen by an organic solvent, an organic material may be cured by heat or an ultraviolet ray, or other methods are shown as an example.

### Fifth Embodiment

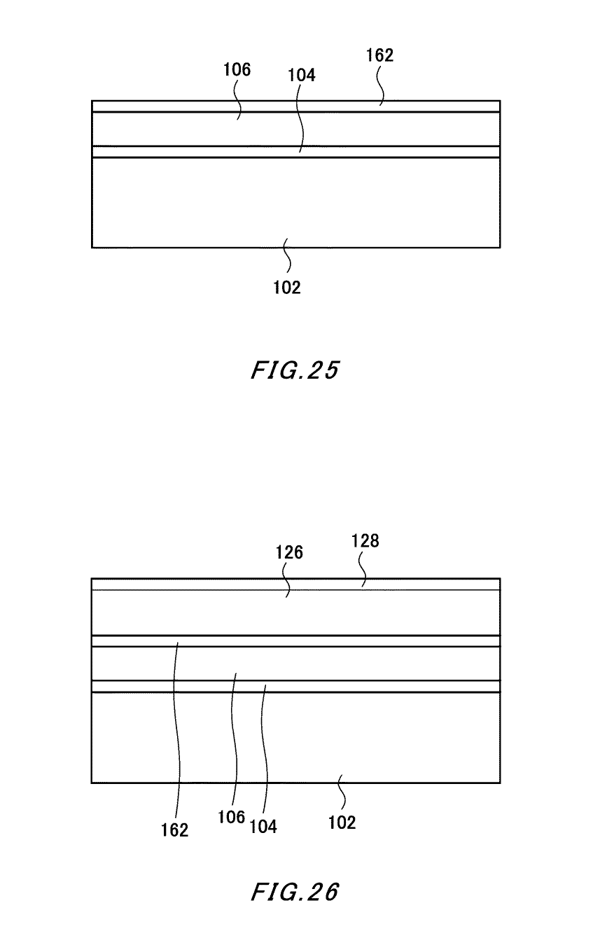

FIGS. 25 to 27 are cross-sectional views illustrating the steps of a method of producing a composite wafer relating to a fifth embodiment in the performed order. According to the fifth embodiment, an adhesive layer 162 is formed between the semiconductor crystal layer 106 and the transfer target wafer 126. The production method relating to the fifth embodiment has a lot of common features with the production method relating to the third embodiment, and the following thus mainly describes the differences between the third embodiment and the fifth embodiment and does not describe the common features.

As shown in FIG. 25, the adhesive layer 162 is formed on the semiconductor crystal layer 106 after the sacrificial layer 104 and the semiconductor crystal layer 106 are formed. The adhesive layer 162 is provided for the purposes of enhancing the adhesiveness between the semiconductor crystal layer 106 and the transfer target wafer 126. The adhesive layer 162 can be made of either an organic or inorganic matter, but preferably made of an inorganic matter considering the match between the materials since the transfer target wafer 126 is made of an inorganic matter. When the adhesive layer 162 is made of an organic matter, unevenness in the surface of the semiconductor crystal layer 106, if any, can be absorbed by the adhesive layer 162 to a certain extent, and the adhesive layer 162 can be excellently bonded to the transfer target wafer 126. Therefore, the semiconductor crystal layer 106 may only be required to have low surface flatness. On the other hand, when the adhesive layer 162 is made of an inorganic matter, the adhesive layer 162 can be advantageously handled stably even if the subsequent steps include a high-temperature step that is performed at approximately several hundred degrees Celsius. In addition, when the adhesive layer 162 is made of an inorganic matter, the adhesive layer 162 can be used to form an insulating layer or the like for a device that is eventually formed, which can simplify the production process. When the adhesive layer 162 is made of an inorganic matter, the average roughness of the adhesive layer 162 preferably does not exceed 2 nm in order to enhance the adhesiveness between the adhesive layer 162 and the transfer target wafer 126 that is made of an inorganic matter.

When the adhesive layer 162 is made of an organic matter, the adhesive layer 162 can be, for example, a polyimide film or a resist film. In this case, the adhesive layer 162 can be formed by various application techniques such as spin coating. When the adhesive layer 162 is made of an inorganic matter, the adhesive layer 162 can be, for example, a layer made of at least one of Al₂O₃, AlN, Ta₂O₅, ZrO₂, HfO₂, SiOₓ (for example, SiO₂), SiNₓ (for example, Si₃N₄), and SiOₓN_{y}, or a laminate obtained by stacking at least two layers respectively made of selected ones of the above-listed materials. In this case, the adhesive layer 162 can be formed by ALD, thermal oxidization, evaporation, CVD, or sputtering. The thickness of the adhesive layer 162 can be within the range of 0.1 nm and 100 μm.

Subsequently, as shown in FIG. 26, the transfer target wafer 126 and the semiconductor crystal layer forming wafer 102 are bonded to each other in such a manner that the surface of the transfer target wafer 126 is bonded to the surface of the adhesive layer 162. Here, the surface of the adhesive layer 162 is one example of “the first surface 112,” which is the surface of the layer formed on the semiconductor crystal layer forming wafer 102 and to come into contact with the transfer target wafer 126 or the layer formed on the transfer target wafer 126. The surface of the transfer target wafer 126 is one example of “the second surface 122,” which is the surface of the transfer target wafer 126 or of the layer formed on the transfer target wafer 126 and to come into contact with the first surface 112. In the bonding step, the transfer target wafer 126 and the semiconductor crystal layer forming wafer 120 are bonded to each other in such a manner that the surface of the adhesive layer 162, which is the first surface 112, is bonded onto the surface of the transfer target wafer 126, which is the second surface 122. The bonding step is performed in the same manner as in the third embodiment.

The fifth embodiment is the same as the third embodiment in that, before the transfer target wafer 126 and the semiconductor crystal layer forming wafer 102 are bonded to each other, the adhesiveness enhancement treatment to enhance the adhesiveness between the transfer target wafer 126 and the adhesive layer 162 may be performed on one or more surfaces selected from the surface of the transfer target wafer 126 and the surface of the adhesive layer 162. Furthermore, the fifth embodiment is the same as the third embodiment in that the transfer target wafer 126 and the semiconductor crystal layer forming wafer 102 can be attached to each other under pressure within the range of 0.01 MPa to 1 GPa in the bonding step.

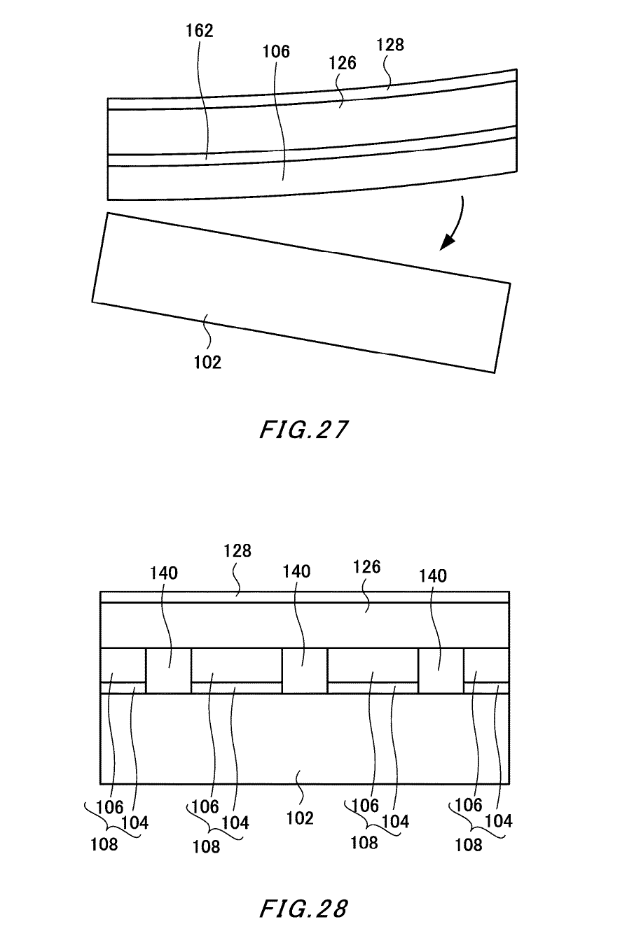

After this, the sacrificial layer 104 is etched away. In this manner, as shown in FIG. 27, the transfer target wafer 126 is separated from the semiconductor crystal layer forming wafer 102 with the adhesive layer 162 and the semiconductor crystal layer 106 being left on the transfer target wafer 126. The separation is performed in the same manner as in the third embodiment. In this way, the adhesive layer 162 and the semiconductor crystal layer 106 are transferred onto the transfer target wafer 126 and a composite wafer in which the adhesive layer 162 and the semiconductor crystal layer 106 are provided on the transfer target wafer 126 is produced. The fifth embodiment is the same as the third embodiment in that the sacrificial layer 104 may be etched away using dry etching.

According to the above-described method of producing a composite wafer relating to the fifth embodiment, the presence of the adhesive layer 162 increases the reliability of the attachment between the transfer target wafer 126 and the semiconductor crystal layer 106. When the adhesive layer 162 is made of an organic matter, the adhesive layer 162 can absorb the unevenness of the surface of the semiconductor crystal layer 106 and the semiconductor crystal layer 106 is thus required to have a less strict level of flatness. On the other hand, when the adhesive layer 162 is made of an inorganic material, the subsequent steps are advantageously subject to no thermal limitations.

The fifth embodiment is the same as the fourth embodiment in that the composite wafer relating to the fifth embodiment can be used to transfer the semiconductor crystal layer 106 on the transfer target wafer 126 onto the second transfer target wafer. In this case, the adhesive layer 162 can be used as a sacrificial layer to transfer the semiconductor crystal layer 106 onto the second transfer target wafer. In addition, an adhesive layer may be formed between the second transfer target wafer and the semiconductor crystal layer 106.

After the sacrificial layer 104 and the semiconductor crystal layer 106 are formed on the semiconductor crystal layer forming wafer 102 and before the semiconductor crystal layer forming wafer 102 and the transfer target wafer 126 are bonded to each other, an electronic device whose active region is constituted by a portion of the semiconductor crystal layer 106 may be formed on the semiconductor crystal layer 106. In this case, the semiconductor crystal layer 106 is transferred with the electronic device being formed thereon. Since the semiconductor crystal layer 106 is flipped each time it is transferred, this method enables electronic devices to be formed on both of the front and back planes of the semiconductor crystal layer 106.

### Sixth Embodiment

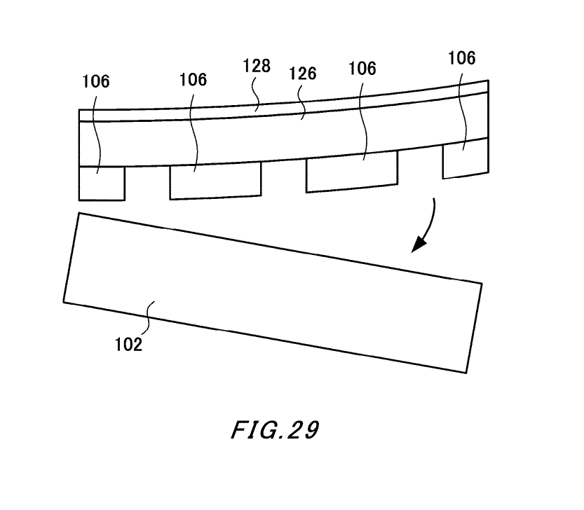

FIGS. 28 and 29 are cross-sectional views illustrating the steps of a method of producing a composite wafer relating to a sixth embodiment in the performed order. According to the production method relating to the sixth embodiment, the sacrificial layer 104 and the semiconductor crystal layer 106 are formed on the semiconductor crystal layer forming wafer 102 in the order of the sacrificial layer 104 and the semiconductor crystal layer 106 as shown in FIG. 1 described with reference to the first embodiment. The sixth embodiment is the same as the first embodiment in terms of the semiconductor crystal layer forming wafer 102, the sacrificial layer 104 and the semiconductor crystal layer 106.

Subsequently, as shown in FIG. 2 describing the first embodiment, the semiconductor crystal layer 106 is etched so as to partially expose the sacrificial layer 104. Thus, the semiconductor crystal layer 106 is divided into a plurality of divided pieces 108. The etching forms the grooves 110 between adjacent ones of the divided pieces 108.

After this, the adhesiveness enhancement treatment to enhance the adhesiveness between the transfer target wafer 126 and the semiconductor crystal layer 106 is performed on the surface of the transfer target wafer 126 and the surface of the semiconductor crystal layer 106. Subsequently, the surface of the transfer target wafer 126 on the convex side (the second surface 122) is positioned so as to face the surface of the semiconductor crystal layer 106 on the semiconductor crystal layer forming wafer 102 (the first surface 112). Following this, as shown in FIG. 28, the transfer target wafer 126 is bonded onto the semiconductor crystal layer forming wafer 102 in such a manner that the surface of the semiconductor crystal layer 106, which is the first surface 112, is bonded onto the surface of the transfer target wafer 126, which is the second surface 122. As a result of this bonding, the inner walls of the grooves 110 and the surface of the transfer target wafer 126 form the spaces 140. The sixth embodiment is the same as the third embodiment in terms of how the adhesiveness enhancement treatment is performed, that the load is applied for the bonding step, and the like.

Subsequently, an etching solution is supplied to the spaces 140. The etching solution supplied into the spaces 140 etches the sacrificial layer 104. The etching solution can be supplied to the spaces 140 in any of the following methods. The etching solution can be supplied into the spaces 140 using capillary action. The etching solution can be forcibly supplied into the spaces 140 in such a manner that the ends of the spaces 140 on one side are immersed into the etching solution and the etching solution is suctioned from the ends on the other side. When the ends of the spaces 140 at one side are open and the ends at the other side are closed, the etching solution can be forcibly supplied into the spaces 140 in such a manner that the transfer target wafer 126 and the semiconductor crystal layer forming wafer 102 are placed under reduced pressure and the open ends of the spaces 140 are immersed in the etching solution, after which the transfer target wafer 126 and the semiconductor crystal layer forming wafer 102 are placed under the atmospheric pressure.

While the sacrificial layer 104 is etched, the sacrificial layer 104 can be etched with an ultrasound wave being applied into the spaces 140 filled with the etching solution. The application of the ultrasound wave can contribute to increase the etching rate. Furthermore, during the etching, an ultraviolet ray may be applied, or the etching solution may be stirred.

If the sacrificial layer 104 is removed by the etching as described above, the transfer target wafer 126 is separated from the semiconductor crystal layer forming wafer 102 with the semiconductor crystal layer 106 being left on the transfer target wafer 126 as shown in FIG. 29. As a result, the semiconductor crystal layer 106 is transferred onto the transfer target wafer 126, and a composite wafer in which the semiconductor crystal layer 106 is provided on the transfer target wafer 126 is produced.

According to the above-described method of producing a composite wafer relating to the sixth embodiment, the spaces 140 are formed due to the presence of the grooves 110. Therefore, during the etching of the sacrificial layer 104, the etching solution is supplied via the spaces 140, in addition to that the etching solution is supplied using the curve of the transfer target wafer 126. Therefore, the sacrificial layer 104 can be swiftly etched and removed. Consequently, the transfer target wafer 126 can be swiftly separated from the semiconductor crystal layer forming wafer 102 and the production throughput can be improved.

The sixth embodiment is the same as the fourth embodiment in that the composite wafer relating to the sixth embodiment is used to transfer the semiconductor crystal layer 106 on the transfer target wafer 126 further onto a second transfer target wafer. An adhesive layer may be formed between the second transfer target wafer and the semiconductor crystal layer 106. Furthermore, after the sacrificial layer 104 and the semiconductor crystal layer 106 are formed on the semiconductor crystal layer forming wafer 102 and before the semiconductor crystal layer forming wafer 102 is bonded onto the transfer target wafer 126, an electronic device whose active region is formed by a portion of the semiconductor crystal layer 106 may be formed on the semiconductor crystal layer 106.

### Seventh Embodiment

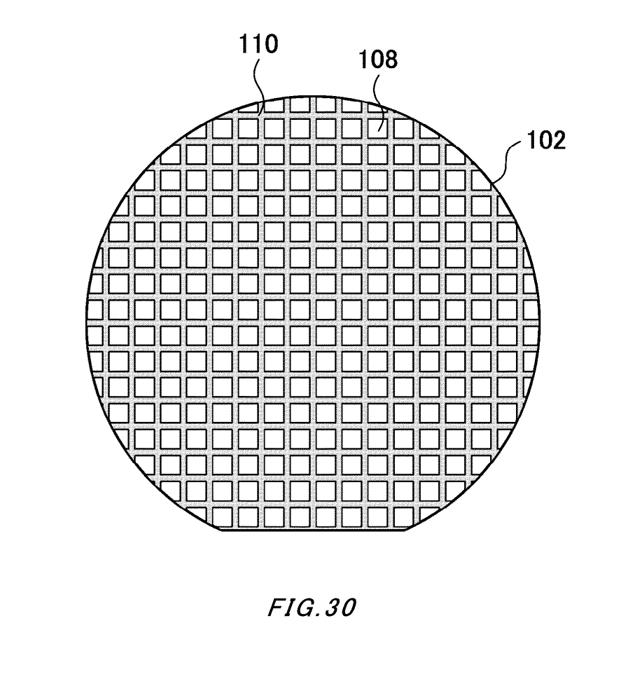

FIGS. 30 to 39 are cross-sectional or plan views illustrating the steps of a method of producing a composite wafer relating to a seventh embodiment in the performed order. According to the production method relating to the seventh embodiment, the sacrificial layer 104 and the semiconductor crystal layer 106 are formed on the semiconductor crystal layer forming wafer 102 in the order of the sacrificial layer 104 and the semiconductor crystal layer 106 as shown in FIG. 1 describing the first embodiment. The seventh embodiment is the same as the first embodiment in terms of the semiconductor crystal layer forming wafer 102, the sacrificial layer 104 and the semiconductor crystal layer 106.

As described in FIG. 2 describing the first embodiment, the semiconductor crystal layer 106 is etched so as to partially expose the sacrificial layer 104, as a result of which the semiconductor crystal layer 106 is divided into a plurality of divided pieces 108. The divided pieces 108 have a planar shape of a circle having a diameter of 30 mm or smaller. The etching forms the grooves 110 between adjacent ones of the divided pieces 108.

Due to the presence of the grooves 110, the etching solution is supplied via the grooves 110 during the etching of the sacrificial layer 104. If a large number of grooves 110 are formed, the distance in the sacrificial layer 104 which the etching solution needs to travel can be made shorter, and the sacrificial layer 104 can be removed within a shorter period of time. FIG. 30 is a plan view illustrating the semiconductor crystal layer forming wafer 102 from above and shows the pattern of the grooves 110. The pattern of the grooves 110 shown in FIG. 30 is a lattice pattern in which the linear grooves 110 are arranged parallel to each other to form a stripe pattern and two of such stripe patterns overlap each other orthogonally. The distance between adjacent ones of the grooves 110 is preferably as small as possible, for the purposes of shortening the period of time required to remove the sacrificial layer 104, provided that the size requirement for the semiconductor crystal layer 106 (the divided pieces 108) is satisfied. The width of the groove 110 is preferably no less than 100,000 times smaller than the distance to the adjacent groove 110 that is arranged in parallel and no more than the distance. It is not necessary to arrange the two stripe patterns of the grooves 110 so as to cross each other orthogonally and the two stripe patterns of the grooves 110 can be arranged so as to cross each other at any angle except for 0 and 180 degrees. In addition, the grooves 110 may be only partly arranged in the lattice pattern. Furthermore, the planar pattern of the grooves 110 may have any shape. In other words, the planar shape of the semiconductor crystal layer 106 that has been divided by the grooves 110 may be any shape and not limited to the strip-like, quadrangular, square and other shapes.

Subsequently, the adhesiveness enhancement treatment to enhance the adhesiveness between the transfer target wafer 120 and the semiconductor crystal layer 106 is performed on the surface of the transfer target wafer 120 and the surface of the semiconductor crystal layer 106 as described in FIG. 5 describing the first embodiment.

The transfer target wafer 120 relating to the seventh embodiment is a wafer to which the semiconductor crystal layer 106 is to be transferred. The transfer target wafer 120 relating to the seventh embodiment may be a target wafer on which an electronic device that uses the semiconductor crystal layer 106 as its active layer is eventually arranged, or a provisional wafer on which the semiconductor crystal layer 106 is temporarily positioned until the semiconductor crystal layer 106 is transferred onto the target wafer. According to the seventh embodiment, one or more constituents selected from the constituent constituting the first surface 112 and the constituent constituting the second surface 122, which are shown in FIG. 5 describing the first embodiment, may be made of an organic matter. The transfer target wafer 120 relating to the seventh embodiment may be entirely made of an organic material. In this case, the surface of the transfer target wafer 120 is the second surface 122. The transfer target wafer 120 relating to the seventh embodiment may have a non-flexible wafer and an organic layer. In this case, the surface of the organic layer is the second surface 122. When the transfer target wafer 120 relating to the seventh embodiment has a non-flexible wafer and an organic layer, the non-flexible wafer may be made of either an organic or inorganic matter. The non-flexible wafer can be, for example, a silicon wafer, a silicon on insulator (SOI) wafer, a glass wafer, a sapphire wafer, an SiC wafer, or an AlN wafer. In addition, the non-flexible wafer may be an insulative wafer such as a ceramics wafer and a plastic wafer, or an electrically conductive wafer such as a metal wafer. When the non-flexible wafer is a silicon wafer or a SOI wafer, an existing production apparatus that is used for a silicon process can be used. The research and development and production can be conducted more efficiently utilizing the common knowledge in the field of silicon process.

When the transfer target wafer 120 relating to the seventh embodiment includes a non-flexible wafer and thus is a hard wafer such as a silicon wafer that does not bend easily, the semiconductor crystal layer 106 to be transferred is protected against mechanical vibration or the like and can maintain high crystallinity. When the transfer target wafer 120 relating to the seventh embodiment is a flexible wafer, the flexible wafer can be bent in a direction away from the semiconductor crystal layer forming wafer 102 in the step of etching the sacrificial layer 104 (described later). In this manner, an etching solution can be swiftly supplied to the sacrificial layer 104, and the transfer target wafer 120 can be swiftly separated from the semiconductor crystal layer forming wafer 102.

Subsequently, the transfer target wafer 120 is bonded to the semiconductor crystal layer forming wafer 102 in such a manner that the surface of the transfer target wafer 120 (the second surface 122) is positioned so as to face the surface of the semiconductor crystal layer 106 on the semiconductor crystal layer forming wafer 102 (the first surface 112) as shown in FIG. 6 describing the first embodiment. In this bonding step, the transfer target wafer 120 is bonded to the semiconductor crystal layer forming wafer 102 in such a manner that the surface of the semiconductor crystal layer 106, which is the first surface 112, is bonded to the surface of the transfer target wafer 120, which is the second surface 122. When the adhesiveness enhancement treatment is performed, the bonding step can be performed at room temperature.

Subsequently, as shown in FIG. 7 describing the first embodiment, the transfer target wafer 120 may be attached onto the semiconductor crystal layer forming wafer 102 under pressure by applying a load F to the transfer target wafer 120 and the semiconductor crystal layer forming wafer 102. The step of attaching under pressure can contribute to improve the adhesiveness strength. During or after the step of attaching under pressure, a thermal treatment may be performed. The temperature at which the thermal treatment takes place is preferably within the range of 50° C. to 600° C., more preferably within the range of 100° C. and 400° C. As a result of the step of attaching under pressure, the spaces 140 are formed by the inner walls of the grooves 110 and the surface of the transfer target wafer 120. When the transfer target wafer 120 is made of an organic matter, or when the transfer target wafer 120 has a non-flexible wafer and an organic layer and the organic layer serves as an adhesive layer, the step of attaching under pressure does not require a large load. Also, when an adhesive layer is used to attach the transfer target wafer 120 and the semiconductor crystal layer forming wafer 102 to each other, the step of attaching under pressure does not require a large load.

Subsequently, as shown in FIG. 8 describing the first embodiment, the etching solution 142 is supplied to the spaces 140. The etching solution 142 can be supplied to the spaces 140 in any of the following methods. The etching solution 142 can be supplied into the spaces 140 using capillary action. The etching solution 142 can be forcibly supplied into the spaces 140 in such a manner that the ends of the spaces 140 on one side are immersed into the etching solution 142 and the etching solution 142 is suctioned from the ends on the other side. When the ends of the spaces 140 at one side are open and the ends at the other side are closed, the etching solution 142 can be forcibly supplied into the spaces 140 in such a manner that the transfer target wafer 120 and the semiconductor crystal layer forming wafer 102 are placed under reduced pressure and the open ends of the spaces 140 are immersed in the etching solution 142, after which the transfer target wafer 120 and the semiconductor crystal layer forming wafer 102 are placed under the atmospheric pressure.

Before the transfer target wafer 120 and the semiconductor crystal layer forming wafer 102 are bonded to each other, the inside of the grooves 110 can be made hydrophilic. If the inside of the grooves 110 is made hydrophilic, the etching solution can be smoothly supplied into the spaces 140. A method of making the inside of the grooves 110 hydrophilic can be, for example, a method of exposing the inside of the grooves 110 to a HCl gas, a method of injecting hydrophilic ions (for example, hydrogen ions) into the inside of the grooves 110, or the like.

Subsequently, as shown in FIG. 9 describing the first embodiment, the etching solution 142 that has been supplied into the spaces 140 is used to etch the sacrificial layer 104. The sacrificial layer 104 can be selectively etched away. The sacrificial layer 104 can be etched away with an ultrasonic wave being applied to the inside of the spaces 140 that are filled with the etching solution 142 while the sacrificial layer 104 is being etched. The application of an ultrasonic wave can increase the etching rate. Furthermore, while the etching is being performed, an ultraviolet ray may be applied or the etching solution may be stirred.

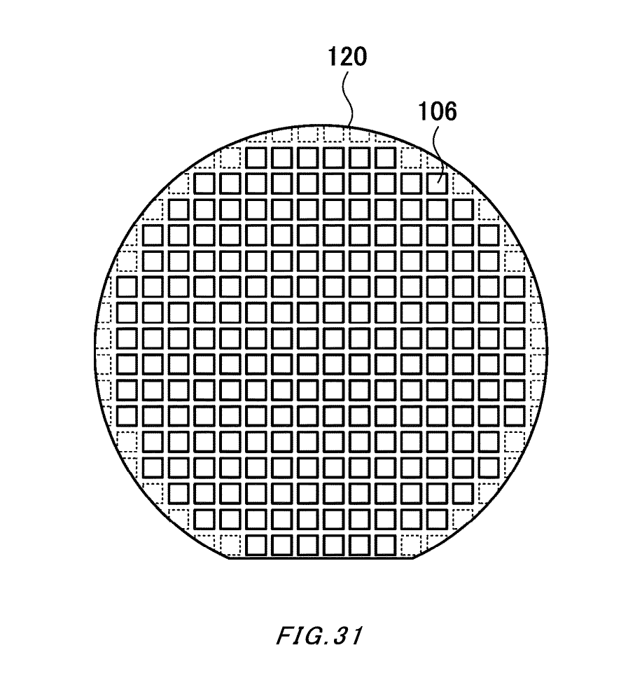

If the sacrificial layer 104 is removed by the etching, the transfer target wafer 102 is separated from the semiconductor crystal layer forming wafer 102 with the semiconductor crystal layer 106 being left on the transfer target wafer 120 as shown in FIG. 10 describing the first embodiment. In this manner, the semiconductor crystal layer 106 is transferred onto the transfer target wafer 120 and a composite wafer in which the semiconductor crystal layer 106 is provided on the transfer target wafer 120 is produced. The semiconductor crystal layer 106 on the transfer target wafer 120 is formed as a plurality of divided pieces as shown in FIG. 31. Here, the semiconductor crystal layer forming wafer 102 has substantially the same size as the transfer target wafer 120, for example.

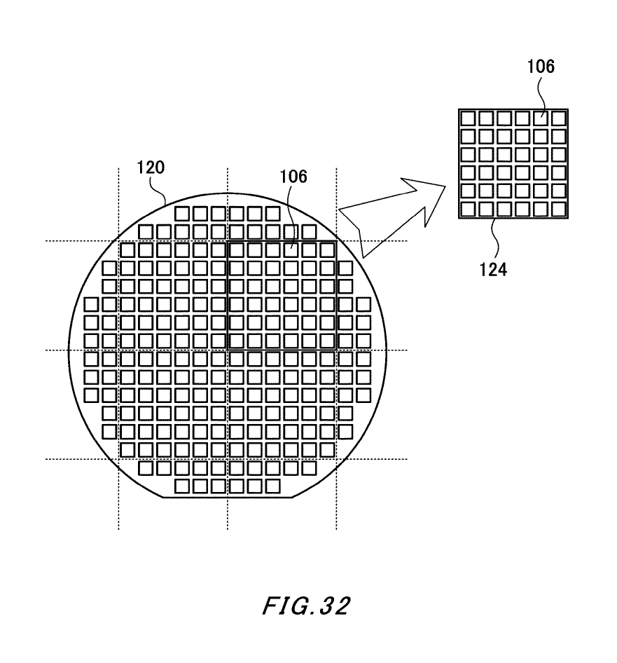

As shown in FIG. 32, the transfer target wafer 120 is shaped to have a size suitable for the transfer. In other words, the transfer target wafer 120 is divided into a plurality of division wafers 124 each of which has a shape suitable for the transfer. The following describes an exemplary cause where a single transfer target wafer 120 is divided into four division wafers 124. Since the division wafers 124 have a size suitable for the transfer and are shaped like a square, the semiconductor crystal layers 106 can be transferred densely without allowing dead spaces to be formed in the wafer to which the semiconductor crystal layers 106 are transferred. Since each of the division wafers 124 has a large number of semiconductor crystal layers 106 and the semiconductor crystal layers 106 on the division wafer 124 can be handled at once, the productivity can be improved.

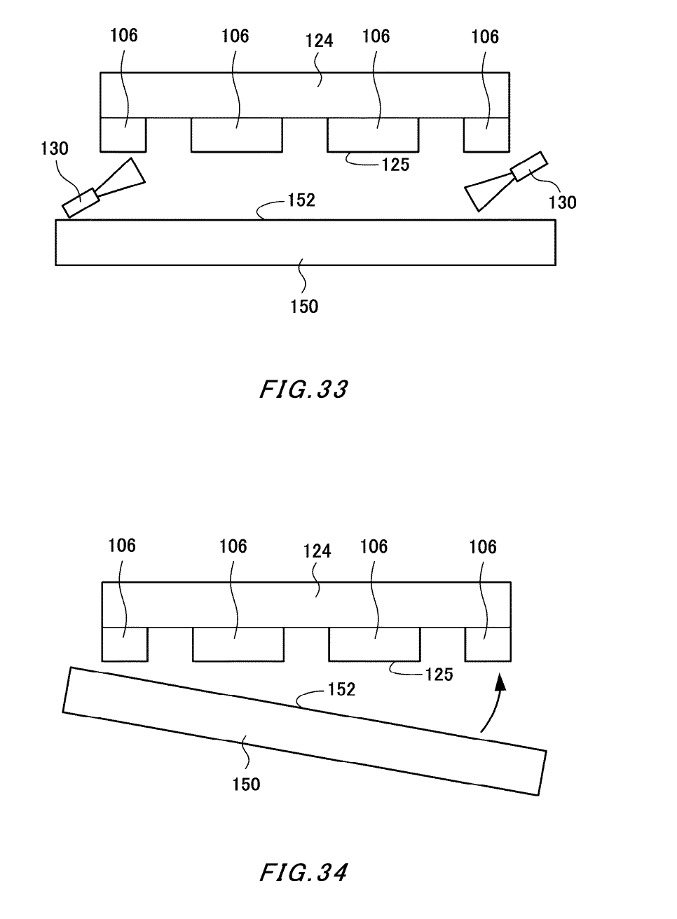

Subsequently, a second transfer target wafer 150 is provided, and the second transfer target wafer 150 is positioned so as to oppose the division wafer 124 as shown in FIG. 33. After this, the adhesiveness enhancement treatment to enhance the adhesiveness between the second transfer target wafer 150 and the semiconductor crystal layer 106 is performed on the surface of the second transfer target wafer 150 and the surface of the semiconductor crystal layer 106. Here, the surface of the semiconductor crystal layer 106 is one example of “a third surface 125,” which is the surface of a layer formed on the division wafer 124 and to be brought into contact with the second transfer target wafer 150 or the layer formed on the second transfer target wafer 150. The surface of the second transfer target wafer 150 is one example of “a fourth surface 152,” which is the surface of the second transfer target wafer 150 or the surface of the layer formed on the second transfer target wafer 150 and to be brought into contact with the third surface 125.

The adhesiveness enhancement treatment may be performed only on one of the surface of the second transfer target wafer 150 and the surface of the semiconductor crystal layer 106. The adhesiveness enhancement treatment can be, for example, ion beam activation using the ion beam generator 130. The applied ions are, for example, argon ions. The adhesiveness enhancement treatment may be plasma activation. The adhesiveness enhancement treatment can enhance the adhesiveness between the second transfer target wafer 150 and the semiconductor crystal layer 106. Note that the adhesiveness enhancement treatment is not essential. The adhesiveness enhancement treatment may be replaced with the step of forming in advance an adhesive layer on the second transfer target wafer 150.

The second transfer target wafer 150 is a wafer to which the semiconductor crystal layer 106 is to be transferred, like the transfer target wafer 120. The second transfer target wafer 150 may be the last target wafer or a provisional wafer, like the transfer target wafer 120. However, the second transfer target wafer 150 is generally assumed to be the last target wafer. The second transfer target wafer 150 is the same as the transfer target wafer 120 in terms of the material and the like and thus not described here. The second transfer target wafer 150 has a planar shape that is a circle having a diameter of 200 mm or larger. The second transfer target wafer 150 can be, for example, a silicon wafer having a diameter of 10 inches or more. If a silicon wafer having a large diameter is employed as the second transfer target wafer 150, the common knowledge and existing production apparatuses in the field of silicon wafer processes can be used, which can significantly reduce the production cost. The second transfer target wafer 150 (the entire wafer or a portion that is positioned so as to face the semiconductor crystal layer 106) can be amorphous, polycrystalline or monocrystalline, in which case the second transfer target wafer 150 has a single-crystal structure that does not lattice-match or pseudo-lattice-match the single-crystal structure of the semiconductor crystal layer 106. Since the semiconductor crystal layer 106 is formed on the second transfer target wafer 150 by means of the bonding technique, the second transfer target wafer 150 does not need to be made of a material that lattice-matches or pseudo-lattice-matches the semiconductor crystal layer 106. This can give flexibility for the selection of the material.

As shown in FIG. 34, the division wafer 124 is bonded to the second transfer target wafer 150 in such a manner that the surface of the division wafer 124 that has the semiconductor crystal layer 106 thereon faces the surface of the second transfer target wafer 150. In other words, the division wafer 124 is bonded to the second transfer target wafer 150 in such a manner that the surface of the semiconductor crystal layer 106 (the third surface 125) is bonded to the surface of the second transfer target wafer 150 (the fourth surface 152). When the adhesiveness enhancement treatment is performed, the bonding step can be performed at room temperature.

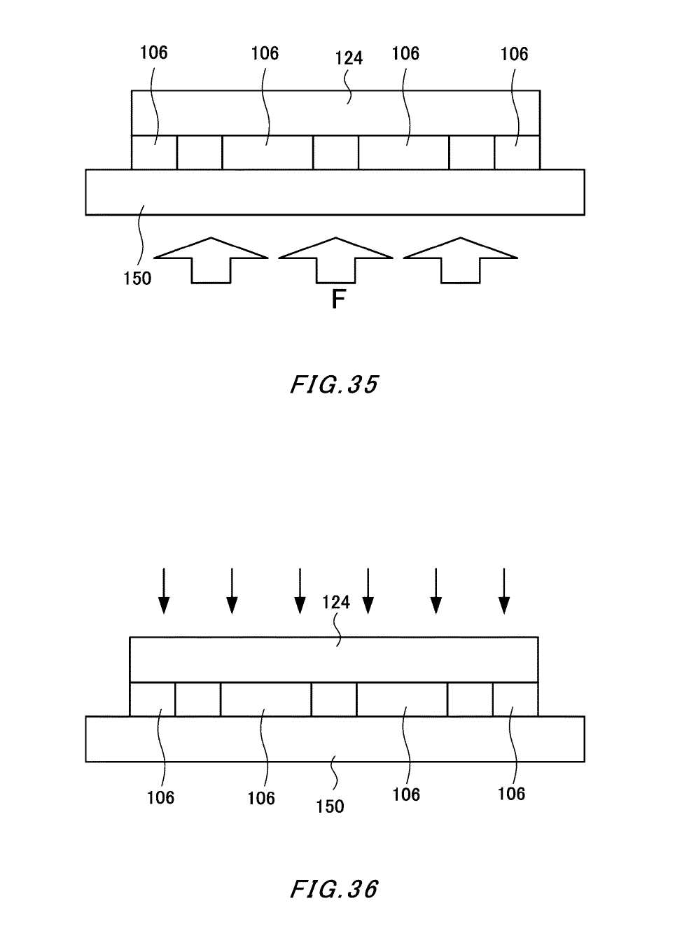

Subsequently, as shown in FIG. 35, a load F is applied to the second transfer target wafer 150 and the division wafer 124 to attach the second transfer target wafer 150 to the division wafer 124 under pressure. When the second transfer target wafer 150 and the division wafer 124 are attached to each other using an adhesive layer, the step of attaching under pressure does not need a large load.

As shown in FIG. 36, the physical property of the interface or layer that determines the adhesiveness between the division wafer 124 and the semiconductor crystal layer 106 is changed. The physical property of the interface is changed by, for example, implanting hydrogen ions. By implanting hydrogen ions into the adhesive interface between the division wafer 124 and the semiconductor crystal layer 106, the adhesiveness of the interface can be reduced. Here, the ion implantation is performed with the acceleration voltage being adjusted in such a manner that the hydrogen ions stop at the interface. Alternatively, a layer that has hydrogen ions implanted is formed in advance before the first bonding step. In this way, in the separating step, heat is applied to generate microscopic cracks in the hydrogen-ion-implanted layer to make it easy to separate the semiconductor crystal layer 106 from the interface. The physical property of an organic layer is changed by, for example, swelling or dissolving the organic layer using an organic solvent or aqueous solution. If the organic layer is swollen or dissolved, the adhesiveness between the division wafer 124 and the semiconductor crystal layer 106 can be lowered. Alternatively, when a ultraviolet-induced or heat-induced peelable dicing film is used, the viscosity can be lowered by applying an ultraviolet ray or heat to the layer.

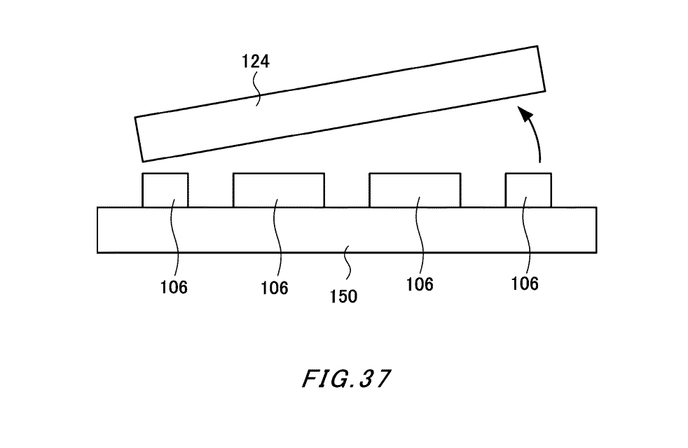

If the adhesiveness of the adhesive interface between the division wafer 124 and the semiconductor crystal layer 106 is lowered in the above-described manner, the division wafer 124 can be separated from the second transfer target wafer 150 with the semiconductor crystal layer 106 being left on the second transfer target wafer 150 as shown in FIG. 37. In this manner, the semiconductor crystal layer 106 is transferred onto the second transfer target wafer 150, and a composite wafer in which the semiconductor crystal layer 106 is provided on the second transfer target wafer 150 is produced.

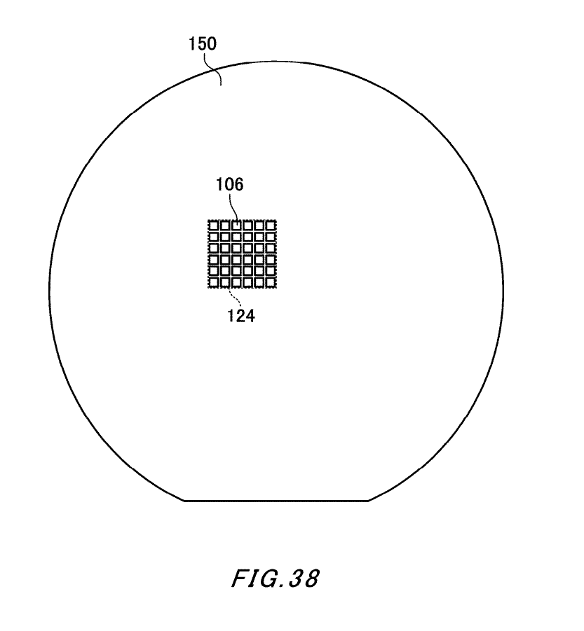

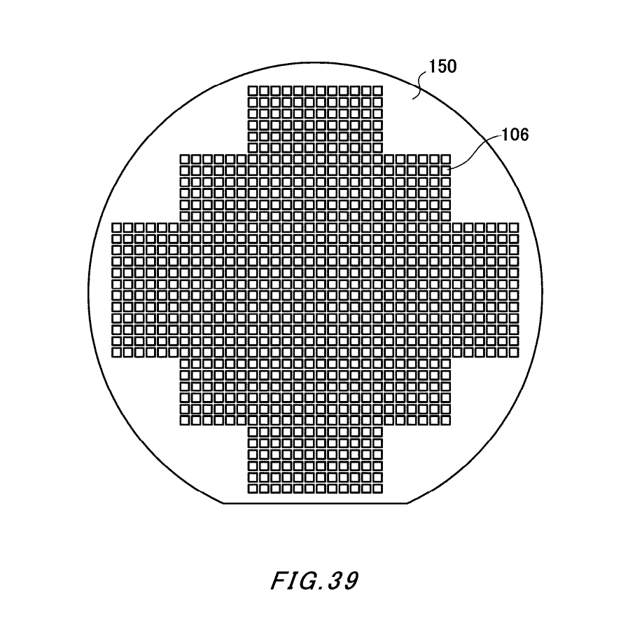

FIG. 38 is a plan view showing the second transfer target wafer 150 from above in the state shown in FIG. 37. FIG. 38 shows the second transfer target wafer 150 after the first transfer of the semiconductor crystal layer 106 from the division wafer 124 to the second transfer target wafer 150. FIG. 38 shows that a single transfer technique from the division wafer 124 to the second transfer target wafer 150 can transfer a large number of semiconductor crystal layers 106. Thus, the transfer procedure can be highly efficient. FIG. 39 is a plan view illustrating the second transfer target wafer 150 seen from above after the steps shown in FIGS. 33 to 37 are repeatedly performed multiple times. The semiconductor crystal layers 106 that are obtained by the dividing step are arranged two-dimensionally orderly on the second transfer target wafer 150. Since the division wafers 124 are shaped like a square, the semiconductor crystal layers 106 can be formed densely in a given transfer procedure adjacently to the semiconductor crystal layers 106 that have been formed in the previous transfer procedure. In this manner, the area of the second transfer target wafer 150 can be efficiently used.

When an adhesive layer is provided between the division wafer 124 and the semiconductor crystal layer 106, the physical property of the adhesive layer can be changed. In the above-described embodiment, the physical property of the interface is changed in such a manner that the adhesiveness between the division wafer 124 and the semiconductor crystal layer 106 is decreased, but the physical property of the interface that determines the adhesiveness between the semiconductor crystal layer 106 and the second transfer target wafer 150, in other words, the physical property of the bonding interface between the semiconductor crystal layer 106 and the second transfer target wafer 150 may be alternatively changed in such a manner that the adhesiveness is increased. When an adhesive layer is provided between the semiconductor crystal layer 106 and the second transfer target wafer 150, the physical property of the adhesive layer may be changed. The physical property to be changed may be the adhesiveness of the interface.

An exemplary method of changing the physical property of an interface to increase the adhesiveness of the interface is activation of the interface, and an exemplary method of changing the physical property of an organic matter to decrease the adhesiveness of the organic matter is swelling the organic matter using an organic solvent, curing the organic matter by applying heat or an ultraviolet ray to the organic matter, or the like.

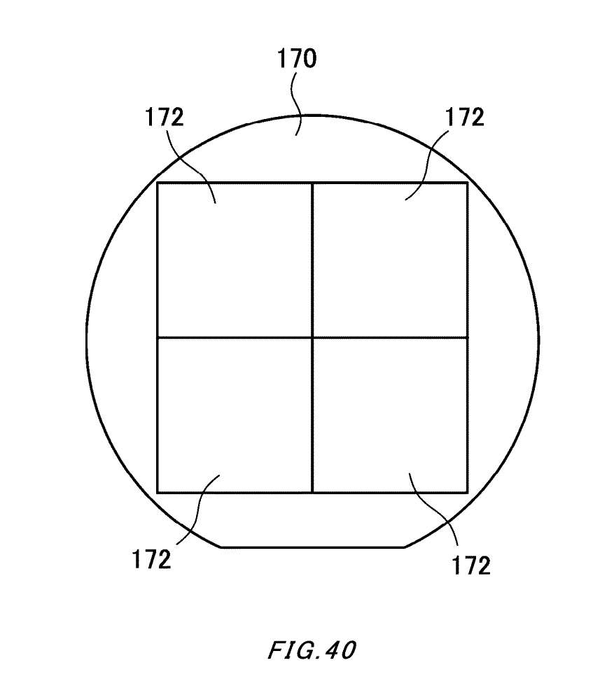

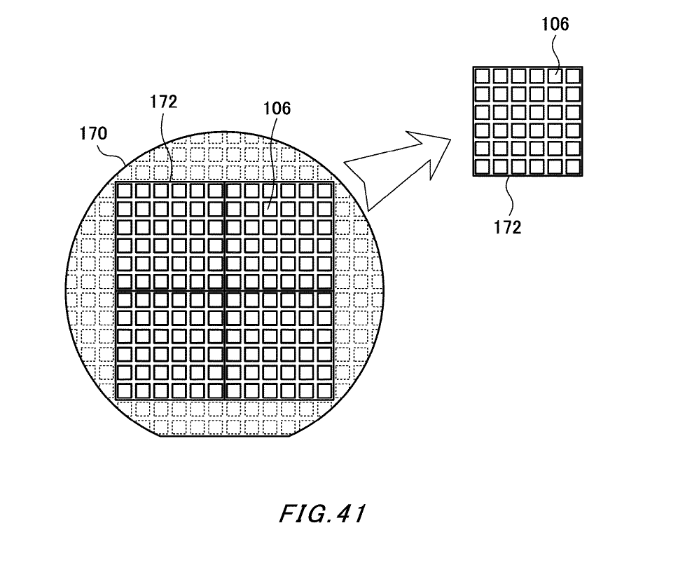

In the above-described seventh embodiment, the transfer target wafer 120 to which the semiconductor crystal layer 106 has been transferred is divided and shaped, for example. Alternatively, however, a plurality of intermediate wafers 172 that are shaped in advance are arranged and the semiconductor crystal layer 106 may be transferred onto the intermediate wafers 172. In other words, as shown in FIG. 40, four intermediate wafers 172 that have been shaped into, for example, squares are arranged and these four intermediate wafers 172 are supported by a support 170. By handling the support 170 in a similar manner to the transfer target wafer 120, the semiconductor crystal layer 106 can be transferred onto the intermediate wafers 172 that have been shaped in advance, as shown in FIG. 41. The intermediate wafers 172 that have been shaped in advance can be handled in a similar manner to the division wafers 124 shown in FIGS. 33 to 37.

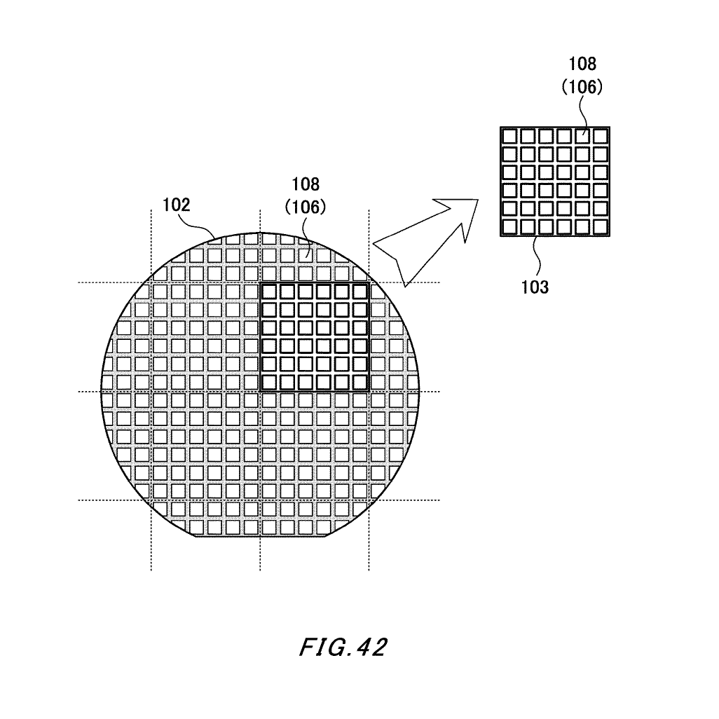

Furthermore, as shown in FIG. 42, the semiconductor crystal layer forming wafer 102 is divided into division wafers 103, and the division wafers 103 can be used in place of the semiconductor crystal layer forming wafer 102. In this case, it is preferable to use the second transfer target wafer 150, which is the final target wafer, in place of the transfer target wafer 120.

An intermediate layer may be formed between the semiconductor crystal layer 106 and one of the transfer target wafer 120 and the second transfer target wafer 150. The intermediate layer is preferably resistant against heat of 300° C. or more. The intermediate layer may also serve as an adhesive layer. The intermediate layer may be made of either an organic or inorganic matter. When made of an organic matter, the intermediate layer can be, for example, a polyimide film or a resist film. In this case, the intermediate layer can be formed by application techniques such as spin coating. When made of an inorganic matter, the intermediate layer can be, for example, a layer made of at least one of Al₂O₃, AlN, Ta₂O₅, ZrO₂, HfO₂, SiOₓ (for example, SiO₂), SiNₓ (for example, Si₃N₄), and SiOₓN_{y}, or a laminate obtained by stacking at least two layers respectively made of selected ones of the above-listed materials. In this case, the intermediate layer can be formed by ALD, thermal oxidization, evaporation, CVD, sputtering. The intermediate layer has a thickness within the range of 0.1 nm to 100 μm.

After the sacrificial layer 104 and the semiconductor crystal layer 106 are formed on the semiconductor crystal layer forming wafer 102 and before the semiconductor crystal layer forming wafer 102 is bonded to the transfer target wafer 120, an electronic device whose active region is constituted by a portion of the semiconductor crystal layer 106 may be formed on the semiconductor crystal layer 106. In this case, the semiconductor crystal layer 106 is transferred with the electronic device being formed thereon. Since the semiconductor crystal layer 106 is flipped each time it is transferred, this method enables electronic devices to be formed on both of the front and back planes of the semiconductor crystal layer 106.

According to the above description, the present invention can be embodied mainly as a production method. However, the present invention can also be embodied as a composite wafer that is produced by the above-described production method. In other words, the present invention can be embodied as a composite wafer including a second transfer target wafer 150 having a planar shape of a circle having a diameter of 200 mm or larger and a semiconductor crystal layer 106 positioned on the second transfer target wafer 150 and having a thickness of 1 μm or less. The semiconductor crystal layer 106 is divided into a plurality of divided pieces 108, each of which has a planar shape of a circle having a diameter of 30 mm or smaller. The entire portion of the second transfer target wafer 150 or a portion of the second transfer target wafer 150 that faces the divided pieces 108 is amorphous, polycrystalline, or monocrystalline. In the last case, the entire portion of the second transfer target wafer 150 or the portion of the second transfer target wafer 150 that faces the divided pieces 108 has a single-crystal structure that does not lattice-match or pseudo-lattice-match the single-crystal structure of the divided pieces 108. When the semiconductor crystal layer 106 is a monocrystalline Ge layer, the half-value width of the X-ray diffraction spectrum of the monocrystalline Ge layer may be characteristically 40 arcsec or less. When the semiconductor crystal layer 106 is made of monocrystalline In_{y}Ga_{1-y}As (0.3≦y≦1), the half-value width of the X-ray diffraction spectrum of the semiconductor crystal layer 106 may be characteristically 40 arcsec or less. The semiconductor crystal layer 106 preferably has a thickness of no less than 5 nm and no more than 100 nm. The semiconductor crystal layer 106 more preferably has a thickness of no less than 5 nm and no more than 20 nm. In addition, an electronic device whose active region is constituted by a portion of the semiconductor crystal layer 106 may be formed on the semiconductor crystal layer 106. The electronic device can be, for example, a Hall-effect device.

### First Embodiment Example

In a first embodiment example, a GaAs crystal layer sized to form a single die is formed on a Si wafer using the production method relating to the above-described second embodiment. The semiconductor crystal layer forming wafer 102 was a 4-inch GaAs wafer, the sacrificial layer 104 was an AlAs crystal layer, the semiconductor crystal layer 106 was a GaAs crystal layer, and the adhesive layer 160 was an Al₂O₃ layer. The transfer target wafer 120 was a 4-inch Si wafer.

The AlAs crystal layer and the GaAs crystal layer were formed in the stated order on the entire plane of the GaAs wafer using epitaxial growth based on reduced-pressure MOCVD. The thickness of the AlAs crystal layer was 150 nm and the thickness of the GaAs crystal layer was 1.0 μm. Furthermore, the Al₂O₃ layer was formed using ALD.

The Al₂O₃ layer and the GaAs crystal layer were etched away so as to partly expose the AlAs crystal layer, which is the sacrificial layer 104. As a result, the Al₂O₃ layer and the GaAs crystal layer were divided into a plurality of divided pieces 108. The size of the divided pieces 108 and the width of the grooves were selected from the four different selections shown in Table 1. The divided pieces 108 are formed in the following manner. Four mask patterns that are different in terms of the size of the divided pieces 108 and the width of the grooves as shown in Table 1 were used, and a positive resist was used to form a resist mask on the Al₂O₃ layer. This resist mask was used as a mask to etch the Al₂O₃ layer away using a 10% hydrofluoric acid solution. After this, water cleaning was performed, after which the GaAs crystal layer was etched away using a citric-acid-based etchant. In this manner, the Al₂O₃ layer and the GaAs crystal layer were formed into the divided pieces 108. The etching removed the GaAs crystal layer to expose the AlAs layer.

TABLE 1

| | SIZE OF DIVIDED PIECE 108 | GROOVE WIDTH |
|---|---|---|
| 1 | 300 μm × 300 μm | 120 μm |
| 2 | 370 μm × 370 μm | 50 μm |
| 3 | 450 μm × 450 μm | 150 μm |
| 4 | 550 μm × 550 μm | 50 μm |

Subsequently, the surface of the 4-inch GaAs wafer, which is the semiconductor crystal layer forming wafer 102, and the surface of the 4-inch Si wafer, which is the transfer target wafer 120, were activated by ion beams to perform adhesiveness enhancement treatment. The ion beam activation was performed by applying an Ar ion beam in a vacuum. Following this, the surface of the 4-inch GaAs wafer was bonded to the surface of the 4-inch Si wafer, and a load of 100000 N was applied to attach the surfaces to each other under pressure (with a pressure of 12.3 MPa). As a result, the wafers were bonded. The step of attaching under pressure was performed under room temperature. As a result of this bonding, the spaces 140 were formed by the inner walls of the grooves 110 that were formed by etching the Al₂O₃ layer and the GaAs crystal layer and the surface of the Si wafer, which is the transfer target wafer 120.

Subsequently, the AlAs crystal layer, which is the sacrificial layer 104, was etched away. Thus, the 4-inch Si wafer, which is the transfer target wafer 120, was separated from the 4-inch GaAs wafer with the GaAs crystal layer, which is the semiconductor crystal layer 106, being left on the 4-inch Si wafer. The AlAs crystal layer was etched away in such a manner that the lateral planes of the wafers that have been bonded together were immersed into an etching solution having an HCl concentration of 25% by mass (25% hydrogen chloride aqueous solution) at 23° C., the etching solution was supplied into the spaces 140 using capillary action, and this condition was kept as it was. This allowed the AlAs crystal layer, which is the sacrificial layer 104, to be etched away, and the 4-inch Si wafer was resultantly separated from the 4-inch GaAs wafer. In this manner, a composite wafer in which the GaAs crystal layer, which is the semiconductor crystal layer 106, was provided on the 4-inch Si wafer, which is the transfer target wafer 120, was produced.

The yield for the GaAs crystal layer (the semiconductor crystal layer 106) produced in the first embodiment example was “low” and the period of time required to complete the separation was “long.” Here, a low yield means that, when the crystal layer was examined using a microscope after the transfer, no defects were found within a unit region with a probability of no less than 10% and less than 30%, a medium yield means that the probability is no less than 30% and less than 90% and a high yield means that the probability is no less than 90%. Furthermore, a long period of time to complete the separation means that it takes more than three days, and a medium period of time to complete the separation indicates more than one day and no more than three days, and a short period of time to complete the separation means no more than 1 day. These definitions similarly apply to the following embodiment examples.

### Second Embodiment Example

A composite wafer was produced in the same manner as in the first embodiment example, except for that the load of 50000 N was applied to attach the wafers under pressure (the pressure of 6.17 MPa). In this case, a composite wafer was also produced without problems as in the first embodiment example. In the second embodiment example, the yield for the GaAs crystal layer (the semiconductor crystal layer 106) was “low” and the period of time required to complete the separation was “long.”

### Third Embodiment Example

A composite wafer was produced in the same manner as in the first Embodiment Example except for that the transfer target wafer was a 8-inch Si wafer (the load was 100000 N and the pressure was 12.3 MPa). In this case, a composite wafer could be also produced without problems as in the first embodiment example. The yield for the GaAs crystal layer (the semiconductor crystal layer 106) formed in the third embodiment example was “low” and the period of time required to complete the separation was “long.”

### Fourth Embodiment Example

In a fourth embodiment example, a GaAs crystal layer sized to form a single die is formed on a Si wafer using the production method of the above-described first embodiment. The semiconductor crystal layer forming wafer 102 was a 6-inch GaAs wafer, the sacrificial layer 104 was an AlAs crystal layer, and the semiconductor crystal layer 106 was a GaAs crystal layer. The transfer target wafer 120 was a 12-inch Si wafer.

An AlAs crystal layer and a GaAs crystal layer were formed in the stated order on the entire plane of the GaAs wafer using epitaxial growth based on reduced-pressure MOCVD. The thickness of the AlAs crystal layer was 150 nm and the thickness of the GaAs crystal layer was 1.0 μm.

The GaAs crystal layer was etched away to partially expose the AlAs crystal layer, which is the sacrificial layer 104. In this manner, the GaAs crystal layer was divided into a plurality of divided pieces 108. The size of the divided pieces 108 and the width of the grooves were shown in Table 2. The divided pieces 108 are formed in the following manner. A mask pattern that corresponds to the size of the divided pieces 108 and the width of the grooves shown in FIG. 2 was used, and a positive resist was used to form a resist mask on the GaAs crystal layer. The resist mask was used as a mask to etch the GaAs crystal layer using a phosphoric-acid-based etchant. In this manner, the GaAs crystal layer was formed into the divided pieces 108. The etching was performed until the 6-inch GaAs wafer, which is the semiconductor crystal layer forming wafer 102, was exposed.

TABLE 2

| | SIZE OF DIVIDED PIECE 108 | GROOVE WIDTH |
|---|---|---|
| 5 | 300 μm × 300 μm | 200 μm |

Subsequently, the surface of the 6-inch GaAs wafer, which is the semiconductor crystal layer forming wafer 102, and the surface of the 12-inch Si wafer, which is the transfer target wafer 120, were activated by ion beams in order to perform adhesiveness enhancement treatment. The ion beam activation was performed by applying an Ar ion beam in a vacuum. Following this, the surface of the 6-inch GaAs wafer was bonded to the surface of the 12-inch Si wafer, and a load of 200000 N was also applied to attach the surfaces to each other under pressure (with a pressure of 11.0 MPa). As a result, the wafers were bonded. The step of attaching under pressure was performed under room temperature. As a result of this bonding, the spaces 140 were formed by the inner walls of the grooves 110 that were formed by etching the GaAs crystal layer and the surface of the Si wafer, which is the transfer target wafer 120.

Subsequently, the AlAs crystal layer, which is the sacrificial layer 104, was etched away. Thus, the 12-inch Si wafer, which is the transfer target wafer 120, was separated from the 6-inch GaAs wafer with the GaAs crystal layer, which was the semiconductor crystal layer 106, being left on the 12-inch Si wafer. The AlAs crystal layer was etched away in such a manner that the lateral planes of the wafers that have been bonded together were immersed into an etching solution having an HCl concentration of 25% by mass (25% hydrogen chloride aqueous solution) at 23° C., the etching solution was supplied into the spaces 140 using capillary action, and this condition was kept as it was. This allowed the AlAs crystal layer, which is the sacrificial layer 104, to be etched away, and the 12-inch Si wafer was resultantly separated from the 6-inch GaAs wafer. In this manner, a composite wafer in which the GaAs crystal layer, which is the semiconductor crystal layer 106, was provided on the 12-inch Si wafer, which is the transfer target wafer 120, was produced. The yield for the GaAs crystal layer (the semiconductor crystal layer 106) produced in the fourth embodiment example was “low” and the period of time required to complete the separation was “long.”

### Fifth Embodiment Example

A composite wafer was produced in the same manner as in the fourth embodiment example except for that the semiconductor crystal layer forming wafer 102 was a 6-inch GaAs wafer, the transfer target wafer 120 was a 4-inch glass wafer, and the load applied to perform the step of attaching under pressure was 100000 N (the pressure was 12.3 MPa). In this case, a composite wafer could be also produced without problems as in the fourth embodiment example. The yield for the GaAs crystal layer (the semiconductor crystal layer 106) produced in the fifth embodiment example was “low,” and the period of time to complete the separation was “medium.”

### Sixth Embodiment Example

A composite wafer was produced in the same manner as in the fifth embodiment example except for that the transfer target wafer 120 was a 4-inch quartz wafer (the pressure was 12.3 MPa). In this case, a composite wafer could be also produced without problems as in the fifth embodiment example. The yield for the GaAs crystal layer (the semiconductor crystal layer 106) produced in the sixth embodiment example was “low,” and the period of time required to complete the separation was “medium.”

### Seventh Embodiment Example

A composite wafer was produced in the same manner as in the fourth embodiment example except for that the semiconductor crystal layer forming wafer 102 was a 6-inch GaAs wafer and the semiconductor crystal layer 106 was a Ge crystal layer (the load was 200000 N and the pressure was 11.0 MPa). In this case, a composite wafer could be also produced without problems as in the fourth embodiment example. The yield for the GaAs crystal layer (the semiconductor crystal layer 106) formed in the seventh embodiment example was “low,” and the period of time required to complete the separation was “long.”

### Eighth Embodiment Example

A composite wafer was produced in the same manner as in the first embodiment example except for that the HCl concentration was 10% by mass and the thickness of the AlAs layer, which is the sacrificial layer 104, was set at different values (the load was 100000 N and the pressure was 12.3 MPa). Composite wafers were produced with the thickness of the AlAs layer being set to 5 nm, 7 nm, 10 nm and 20 nm. Composite wafers could be produced without problems.

When the AlAs layer had a thickness of 5 nm, the yield for the GaAs crystal layer (the semiconductor crystal layer 106) was “medium,” and the period of time required to complete the separation was “medium.” When the AlAs layer had a thickness of 7 nm, the yield for the GaAs crystal layer (the semiconductor crystal layer 106) was “medium,” and the period of time required to complete the separation was “short.” When the AlAs layer had a thickness of 10 nm or 20 nm, the yield for the GaAs crystal layer (the semiconductor crystal layer 106) was “medium,” and the period of time required to complete the separation was “short.” There results show that the optimal value for the thickness of the AlAs layer is approximately 7 nm.

### Ninth Embodiment Example

A composite wafer was produced in the same manner as in the first embodiment example except for that the AlAs layer had a thickness of 20 nm and the HCl concentration was set at different values (the load was 100000 N and the pressure was 12.3 MPa). Composite wafers were produced while the HCl concentration was set to 5% by mass and 10% by mass. Composite wafers could be produced without problems.

When the HCl concentration was set to 5% by mass or 10% by mass, the yield for the GaAs crystal layer (the semiconductor crystal layer 106) was “medium,” and the period of time required to complete the separation was “short.” Considering the results of the first and ninth embodiment examples together, the appropriate values of the HCl concentration can be speculated to fall within the range of 5 to 10% by mass.

### Tenth Embodiment Example

A composite wafer was produced in the same manner as in the first embodiment example except for that the planar shape of the divided pieces 108 has a line-and-space pattern in which a line width of 300 μm and a groove width of 200 μm alternate (hereinafter, referred to as “300/200 μm LS pattern” by considering the width of the line and the width of the space (groove)) and the AlAs layer has a thickness of 7 nm (the load was 100000 N and the pressure was 12.3 MPa). Composite wafers could be produced without problems. The yield for the GaAs crystal layer (the semiconductor crystal layer 106) produced in the tenth embodiment example was “high,” and the period of time required to complete the separation was “short.” The results obtained in the tenth embodiment example are excellent compared to the results obtained in the other embodiment examples. It is assumed that such excellent results are attributed to the planar shape of the divided pieces 108.

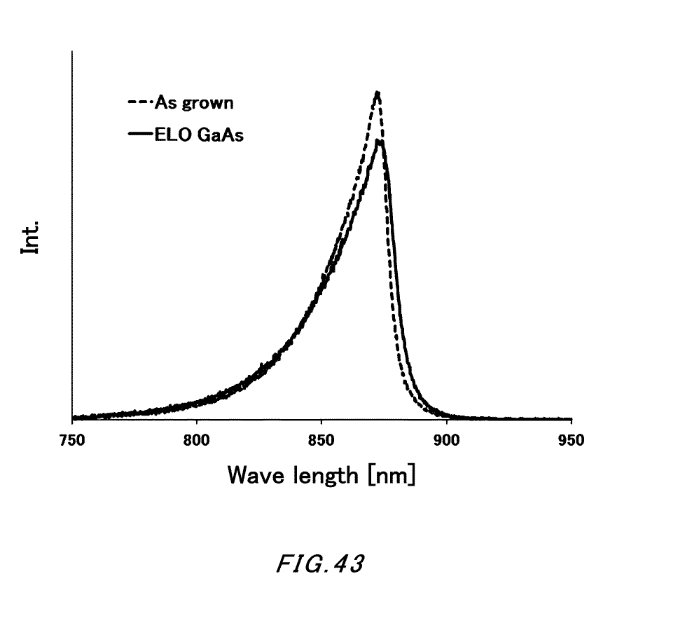

FIG. 43 is a graph showing the results obtained by performing photoluminescence spectroscopic analysis on the GaAs layer (ELO GaAs) after the transfer in the tenth embodiment example. For the comparison purpose, the results obtained by performing photoluminescence spectroscopic analysis on the GaAs layer before the transfer (as grown) is also shown. The graph indicates that the crystallinity, which is evaluated using PL spectroscopy, hardly changes before and after the transfer.

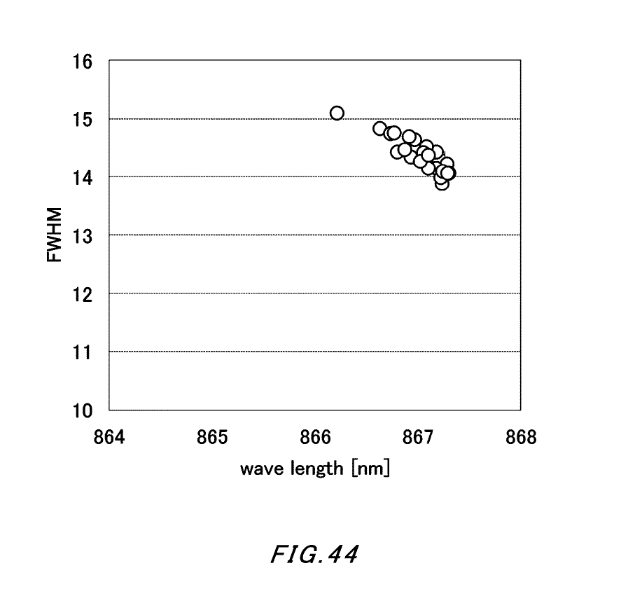

FIG. 44 shows the results obtained by performing PL spectroscopy on the GaAs layer after the transfer in the tenth embodiment example at a plurality of points (25 points). The crystallinity distribution was evaluated by referring to the dispersion distribution graph in which the center emission wavelength (wavelength) is plotted relative to the full width at half maximum (FWHM). As shown from FIG. 44, the crystallinity is hardly distributed.

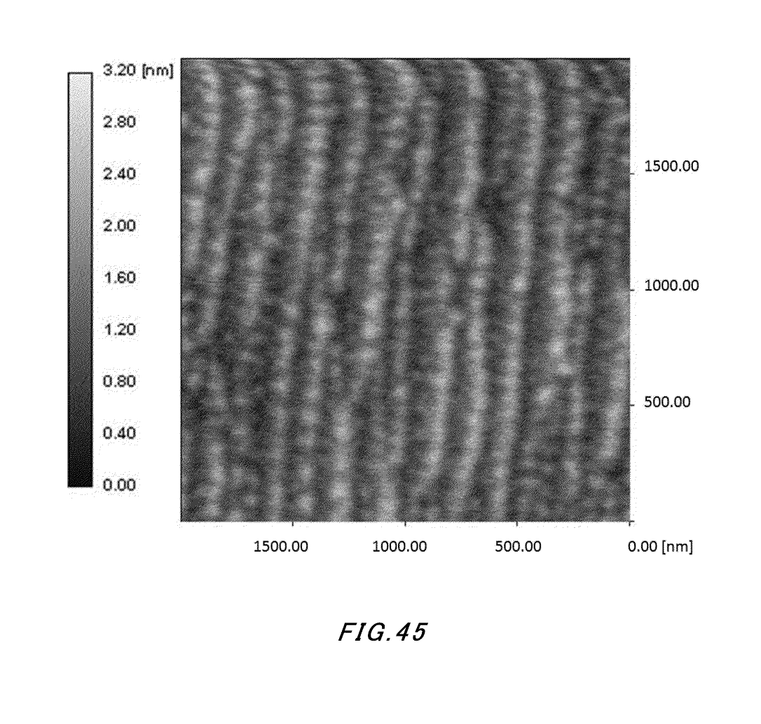

FIG. 45 shows the surface of the GaAs layer (ELO GaAs) after the transfer in the tenth embodiment example when observed using an atomic force microscope (AFM). FIG. 45 clearly shows the step caused by the off angle of the wafer. Even after the transfer, substantially the same condition is maintained for the surface as immediately after the growth. Thus, a surface having a sufficiently high quality for device formation is obtained.

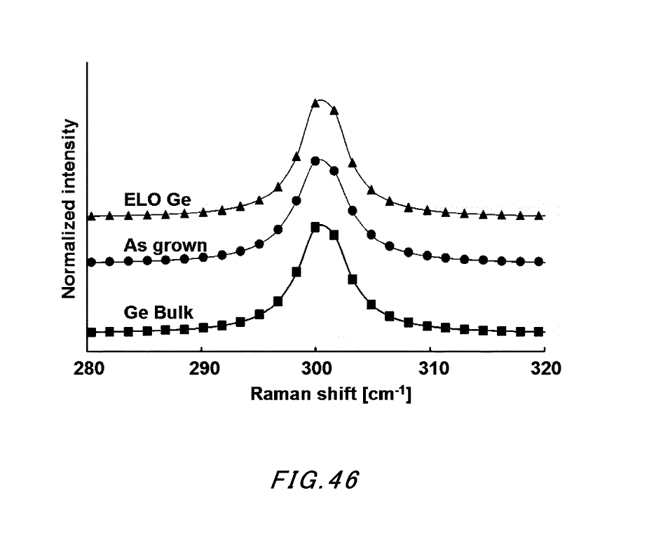

FIG. 46 shows the crystallinity evaluated by performing Raman spectroscopic analysis on a transferred Ge layer (ELO Ge), which is formed in the same manner as the above-described GaAs layer. For the comparison purpose, FIG. 46 also shows the crystallinity for the pre-transfer sample (As grown) and the crystallinity for bulk Ge (Ge Bulk). As shown in FIG. 46, the crystallinity of the transferred Ge layer is hardly different not only from the crystallinity of the Ge layer before the transfer but also from the crystallinity of the bulk crystal and thus excellent.

In the above description of the embodiment and embodiment examples, the final wafer to which the semiconductor crystal layer 106 is eventually transferred is not specifically mentioned. The final wafer may be a semiconductor wafer such as a silicon wafer, an SOI wafer or a wafer in which a semiconductor layer is formed on an insulative wafer. On the semiconductor wafer, SOI layer or the semiconductor layer, an electronic device such as a transistor may be formed in advance. In other words, the semiconductor crystal layer 106 can be formed by the transfer technique using the above-described methods on the wafer on which the electronic device has already been formed. Using this technique, semiconductor devices that are significantly different in composition, material or the like can be monolithically formed. In particular, if an electronic device is formed in advance on the semiconductor crystal layer 106 and the semiconductor crystal layer 106 is subsequently formed by the transfer technique on the above-described wafer on which an electronic device has already been formed, the electronic devices that are made of heterogeneous materials and produced using significantly different production processes can be easily monolithically formed.

### Eleventh Embodiment Example

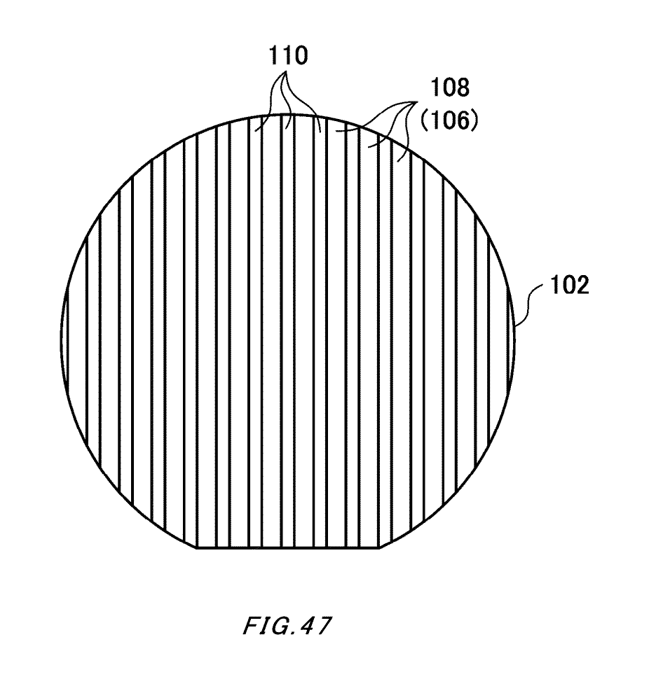

In an eleventh embodiment example, the above-described production method relating to the first embodiment was used, the semiconductor crystal layer forming wafer 102 was a 4-inch GaAs wafer, and the planar shape of the divided pieces 108 had the 300/200 μm LS pattern shown in FIG. 47. The sacrificial layer 104 was an AlAs crystal layer, and the semiconductor crystal layer 106 was a GaAs crystal layer. The transfer target wafer 120 was a 4-inch Si wafer.

An AlAs crystal layer and a GaAs crystal layer were formed in the stated order on the entire plane of the 4-inch GaAs wafer using epitaxial growth based on reduced-pressure MOCVD. The thickness of the AlAs crystal layer was 7 nm and the thickness of the GaAs crystal layer was 1.0 μm.

The GaAs crystal layer was subjected to etching so as to partly expose the AlAs crystal layer, which is the sacrificial layer 104, so that the GaAs crystal layer was divided into the divided pieces 108. The grooves 110 were formed between adjacent ones of the divided pieces 108. The planar shape of the divided pieces 108 was the 300/200 μm LS pattern. The divided pieces 108 were formed in the following manner. A mask pattern that corresponds to the size of the divided pieces 108 and the width of the grooves 110 (300/200 μm LS Pattern) was used, and a positive resist was used to form a resist mask on the GaAs crystal layer. Using the resist mask as a mask, the GaAs crystal layer was subjected to etching using a phosphoric-acid-based etchant so that the GaAs crystal layer was formed into the divided pieces 108. The etching reached the 4-inch GaAs wafer, which is the semiconductor crystal layer forming wafer 102.

After this, the surface of the 4-inch GaAs wafer, which is the semiconductor crystal layer forming wafer 102, and the surface of the 4-inch Si wafer, which is the transfer target wafer 120, were activated by ion beams in order to perform adhesiveness enhancement treatment. The ion beam activation was performed by applying an Ar ion beam in a vacuum. After this, the surface of the GaAs wafer was bonded to the surface of the 4-inch Si wafer, and a load of 100000 N was applied to attach the GaAs wafer and the 4-inch Si wafer under pressure (the pressure was 12.3 MPa). In this manner, the wafers were bonded to each other. The step of attaching under pressure was performed at room temperature. As a result of the bonding, the spaces 140 were formed by the inner walls of the grooves 110 formed by etching the GaAs crystal layer and the surface of the Si wafer, which is the transfer target wafer 120.

Subsequently, the AlAs crystal layer, which is the sacrificial layer 104, was etched away. Accordingly, the 4-inch Si wafer was separated from the 4-inch GaAs wafer with the GaAs crystal layer, which is the semiconductor crystal layer 106, being left on the 4-inch Si wafer, which is the transfer target wafer 120.

The AlAs crystal layer was etched away in such a manner that the lateral planes of the wafers that have been bonded together were immersed into an etching solution having an HCl concentration of 10% by mass (10% hydrogen chloride aqueous solution) at 23° C., the etching solution was supplied into the spaces 140 using capillary action, and this condition was kept as it was. This allowed the AlAs crystal layer, which is the sacrificial layer 104, to be etched away, and the 4-inch Si wafer was resultantly separated from the 4-inch GaAs wafer. In this manner, a composite wafer in which the GaAs crystal layer, which is the semiconductor crystal layer 106, was provided on the 4-inch Si wafer, which is the transfer target wafer 120, was produced.

The yield for the GaAs crystal layer (the semiconductor crystal layer 106) produced in the eleventh embodiment example was “high” and the period of time required to complete the separation was “short.”

### Twelfth Embodiment Example

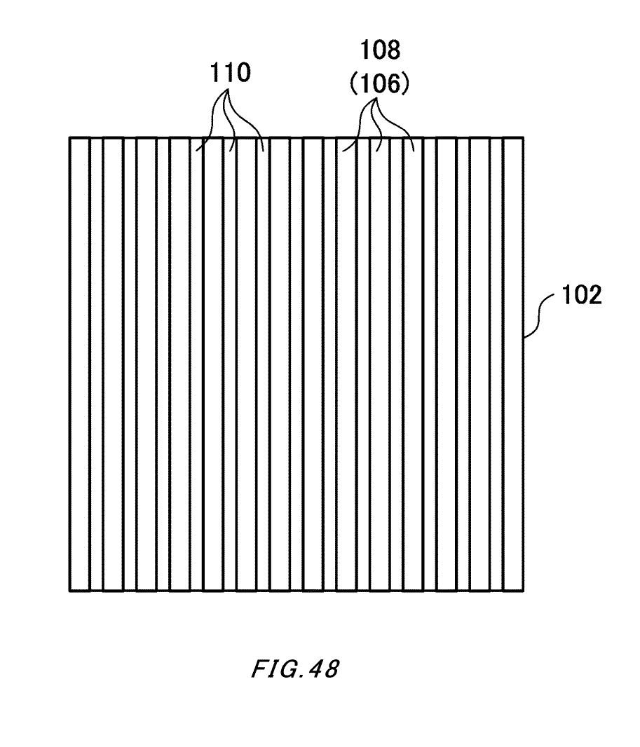

In a twelfth embodiment example, the semiconductor crystal layer forming wafer 102 was a 60-mm square GaAs wafer, and the planar shape of the divided pieces 108 was the 300/200 μm LS pattern shown in FIG. 48. The sacrificial layer 104 was an AlAs crystal layer and the semiconductor crystal layer 106 was a GaAs crystal layer. The transfer target wafer 120 was a 4-inch Si wafer.

An AlAs crystal layer and a GaAs crystal layer were formed in the stated order on the entire plane of the GaAs wafer using epitaxial growth based on reduced-pressure MOCVD. The thickness of the AlAs crystal layer was 7 nm and the thickness of the GaAs crystal layer was 1.0 μm.

The GaAs crystal layer was etched away so as to partly expose the AlAs crystal layer, which is the sacrificial layer 104, so that the GaAs crystal layer was divided into the divided pieces 108. The planar shape of the divided pieces 108 was the 300/200 μm LS pattern. The divided pieces 108 were formed in the following manner. A mask pattern that corresponds to the size of the divided pieces 108 and the width of the grooves (300/200 μm LS Pattern) was used, and a positive resist was used to form a resist mask on the GaAs crystal layer. Using the resist mask as a mask, the GaAs crystal layer was subjected to etching using a phosphoric-acid-based etchant so that the GaAs crystal layer was formed into the divided pieces 108. The etching reached the square GaAs wafer, which is the semiconductor crystal layer forming wafer 102.

After this, the surface of the square GaAs wafer, which is the semiconductor crystal layer forming wafer 102, and the surface of the 4-inch Si wafer, which is the transfer target wafer 120, were activated by ion beams in order to perform adhesiveness enhancement treatment. The ion beam activation was performed by applying an Ar ion beam in a vacuum. After this, the surface of the GaAs wafer was bonded to the surface of the 4-inch Si wafer, and a load of 100000 N was applied to attach the GaAs wafer and the 4-inch Si wafer under pressure (the pressure was 27.8 MPa). In this manner, the wafers were bonded to each other. The step of attaching under pressure was performed at room temperature. As a result of the bonding, the spaces 140 were formed by the inner walls of the grooves 110 formed by etching the GaAs crystal layer and the surface of the Si wafer, which is the transfer target wafer 120.

Subsequently, the AlAs crystal layer, which is the sacrificial layer 104, was etched away. Accordingly, the 4-inch Si wafer was separated from the square GaAs wafer with the GaAs crystal layer, which is the semiconductor crystal layer 106, being left on the 4-inch Si wafer, which is the transfer target wafer 120. The AlAs crystal layer was etched away in such a manner that the lateral planes of the wafers that have been bonded together were immersed into an etching solution having an HCl concentration of 10% by mass (10% hydrogen chloride aqueous solution) at 23° C., the etching solution was supplied into the spaces 140 using capillary action, and this condition was kept as it was. This allowed the AlAs crystal layer, which is the sacrificial layer 104, to be etched away, and the 4-inch Si wafer was resultantly separated from the square GaAs wafer. In this manner, a composite wafer in which the GaAs crystal layer, which is the semiconductor crystal layer 106, was provided on the 4-inch Si wafer, which is the transfer target wafer 120, was produced. The yield for the GaAs crystal layer (the semiconductor crystal layer 106) produced in the twelfth embodiment example was “high” and the period of time required to complete the separation was “short.”

### Thirteenth Embodiment Example

In a thirteenth embodiment example, a composite wafer was produced in the same manner as in the twelfth embodiment example except for that the semiconductor crystal layer forming wafer 102 was five 60-mm square GaAs wafers, the transfer target wafer 120 was a 12-inch Si wafer, and a load of 100000 N was applied for the attachment (the pressure was 5.56 MPa). The yield for the GaAs crystal layer (the semiconductor crystal layer 106) produced in the thirteenth embodiment example was “high” and the period of time required to complete the separation was “short.”

### Fourteenth Embodiment Example

In a fourteenth embodiment example, the semiconductor crystal layer forming wafer 102 was a 60-mm square GaAs wafer and the transfer target wafer 120 was a 4-inch quartz wafer. The sacrificial layer 104 was an AlAs crystal layer and the semiconductor crystal layer 106 was a GaAs crystal layer.

An AlAs crystal layer and a GaAs crystal layer were formed in the stated order on the entire plane of the 4-inch GaAs wafer using epitaxial growth based on reduced-pressure MOCVD. The thickness of the AlAs crystal layer was 7 nm and the thickness of the GaAs crystal layer was 1.0 μm.

The GaAs crystal layer was etched away so as to partly expose the AlAs crystal layer, which is the sacrificial layer 104, so that the GaAs crystal layer was divided into the divided pieces 108. The planar shape of the divided pieces 108 was the 300/200 μm LS pattern. The divided pieces 108 were formed in the following manner. A mask pattern that corresponds to the size of the divided pieces 108 and the width of the grooves 110 (the 300/200 μm LS pattern) was used, and a positive resist was used to form a resist mask on the GaAs crystal layer. Using the resist mask as a mask, the GaAs crystal layer was subjected to etching using a phosphoric-acid-based etchant so that the GaAs crystal layer was formed into the divided pieces 108. The etching reached the square GaAs wafer, which is the semiconductor crystal layer forming wafer 102.

Following this, after the etching was completed, without removing the resist as a mask, the above-described 4-inch wafer was cut using cleavage into 60-mm square GaAs wafers, each of which is the semiconductor crystal layer forming wafer 102.

After this, the surface of the square GaAs wafer, which is the semiconductor crystal layer forming wafer 102, and the surface of the 4-inch quartz wafer, which is the transfer target wafer 120, were activated by ion beams in order to perform the adhesiveness enhancement treatment. The ion beam activation was performed by applying an Ar ion beam in a vacuum. After this, the surface of the GaAs wafer was bonded to the surface of the 4-inch quartz wafer, and a load of 10000 N was applied to attach the GaAs wafer and the 4-inch quartz wafer under pressure (the pressure was 27.8 MPa). In this manner, the wafers were bonded to each other. The step of attaching under pressure was performed at room temperature. As a result of the bonding, the spaces 140 were formed by the inner walls of the grooves 110 formed by etching the GaAs crystal layer and the surface of the quartz wafer, which is the transfer target wafer 120.

Subsequently, the AlAs crystal layer, which is the sacrificial layer 104, was etched away. Accordingly, the 4-inch Si wafer was separated from the square GaAs wafer with the GaAs crystal layer, which is the semiconductor crystal layer 106, being left on the 4-inch quartz wafer, which is the transfer target wafer 120.

The AlAs crystal layer was etched away in such a manner that 10 μL of an etching solution having an HCl concentration of 10% by mass (10% hydrogen chloride aqueous solution) at 23° C. was attached to one point, where one groove opens (the opening of one space 140), at one lateral plane of the square GaAs wafer that has been bonded, and the etching solution was supplied into the spaces 140 using capillary action. The etching solution percolated into the entire lateral plane and accordingly into all of the spaces. After the etching solution was supplied to all of the spaces 140, the wafers that have been bonded were immersed in the etching solution and this state was kept as it was. This allowed the AlAs crystal layer, which is the sacrificial layer 104, to be etched away, and the 4-inch Si wafer was resultantly separated from the square GaAs wafer. In this manner, a composite wafer in which the GaAs crystal layer, which is the semiconductor crystal layer 106, was provided on the 4-inch Si wafer, which is the transfer target wafer 120, was produced.

The yield for the GaAs crystal layer (the semiconductor crystal layer 106) produced in the fourteenth embodiment example was “high” and the period of time required to complete the separation was “short.”

### Fifteenth Embodiment Example

A composite wafer was produced in the same manner as in the fourteenth embodiment example except for the method of supplying the etching solution. The etching solution was supplied in such a manner that 10 μL of an etching solution having an HCl concentration of 10% by mass (10% hydrogen chloride aqueous solution) at 23° C. was attached using a micropipetter to one point, where one groove opens (the opening of one space 140), at one lateral plane of the square GaAs wafer that has been bonded, and the etching solution was thus supplied into the spaces 140 using capillary action. The etching solution percolated into the entire lateral plane and accordingly into all of the spaces. After the etching solution was supplied into all of the spaces 140, the etching solution kept supplied using the micropipetter until the etching was completed. This allowed the AlAs crystal layer, which is the sacrificial layer 104, to be etched away, and the 4-inch Si wafer was resultantly separated from the square GaAs wafer. In this manner, a composite wafer in which the GaAs crystal layer, which is the semiconductor crystal layer 106, was provided on the 4-inch Si wafer, which is the transfer target wafer 120, was produced.

The yield for the GaAs crystal layer (the semiconductor crystal layer 106) produced in the fifteenth embodiment example was “high” and the period ofs time required to complete the separation was “short.”

### Sixteenth Embodiment Example

A composite wafer was produced in the same manner as in the fourteenth embodiment example except for the method of supplying the etching solution. The etching solution was supplied in such a manner that 10 μL of an etching solution having an HCl concentration of 10% by mass (10% hydrogen chloride aqueous solution) at 23° C. was attached using a micropipetter to one point, where one groove opens (the opening of one space 140), at one lateral plane of the square GaAs wafer that has been bonded, and the etching solution was thus supplied into the spaces 140 using capillary action. The etching solution percolated into the entire lateral plane and accordingly into all of the spaces. After the etching solution was supplied into all of the spaces 140, the spaces 140 were left as they were until they were dried. Until the etching was completed, the step of supplying the etching solution using the micropipetter and the step of drying the spaces 140 were repeatedly performed. This allowed the AlAs crystal layer, which is the sacrificial layer 104, to be etched away, and the 4-inch Si wafer was resultantly separated from the square GaAs wafer. In this manner, a composite wafer in which the GaAs crystal layer, which is the semiconductor crystal layer 106, was provided on the 4-inch Si wafer, which is the transfer target wafer 120, was produced.

The yield for the GaAs crystal layer (the semiconductor crystal layer 106) produced in the sixteenth embodiment example was “high” and the period of time required to complete the separation was “short.”

### Seventeenth Embodiment Example

A composite wafer was produced in the same manner as in the eleventh embodiment example except for that grease was provided at a portion of the lateral plane of the wafer that has been bonded, which is the semiconductor crystal layer forming wafer 102. By providing the grease at the lateral plane, the etching solution was prevented from percolating into the spaces 140 through the lateral plane. When it was attempted to fill the spaces 140 with the etching solution using capillary action, the capillary action may be blocked if the etching solution percolates through the lateral plane. Thus, the spaces 140 may not be filled sufficiently with the etching solution. In the seventeenth embodiment example, however, the etching solution was prevented from percolating through the lateral plane by providing the lateral plane of the wafer with grease. Therefore, the spaces 140 were reliably filled with the etching solution. In the above, grease was used as an example, but any other material than grease can be used as long as the material can block the etching solution from percolating through the lateral plane.

The yield for the GaAs crystal layer (the semiconductor crystal layer 106) was higher in the seventeenth embodiment example than in the eleventh embodiment example, and the period of time required to complete the separation was made shorter.

### Eighteenth Embodiment Example

A composite wafer was produced in the same manner as in the eleventh embodiment example except for that the semiconductor crystal layer was a Ge crystal layer having a thickness of 400 nm. The yield for the Ge crystal layer (the semiconductor crystal layer 106) produced in the eighteenth embodiment example was “high,” and the period of time required to complete the separation was “short.”

### Nineteenth Embodiment Example

A composite wafer was produced in the same manner as in the eleventh embodiment example except for that the semiconductor crystal layer was a GaAs crystal layer having a thickness of 10 nm. The yield for the GaAs crystal layer (the semiconductor crystal layer 106) produced in the nineteenth embodiment example was “high,” and the period of time required to complete the separation was “short.”

### Twentieth Embodiment Example

A composite wafer was produced in the same manner as in the eleventh embodiment example except for that a load of 8448 N (the pressure was 1.04 MPa) was applied during the under-pressure attaching step. The yield for the GaAs crystal layer (the semiconductor crystal layer 106) produced in the twentieth embodiment example was “high,” and the period of time required to complete the separation was “short.”

### Twenty-First Embodiment Example

A composite wafer was produced in the same manner as in the eleventh embodiment example except for that a load of 236 N (the pressure was 29.1 kPa) was applied during the under-pressure attaching step. The yield for the GaAs crystal layer (the semiconductor crystal layer 106) produced in the twenty-first embodiment example was “high,” and the period of time to complete the separation was “short.”

### Twenty-Second Embodiment Example

Two composite wafers were produced in the same manner as in the eighth embodiment example by setting the thickness of the AlAs layer to 7 nm. To produce one of these composite wafers, a silicon wafer was used as the transfer target wafer 120. To produce the other composite wafer, a Pyrex glass wafer was used. Both of the composite wafers were evaluated by examining the GaAs crystal layer (the semiconductor crystal layer 106) before and after the transfer using X-ray diffraction. When the transfer target wafer 120 was the Pyrex glass wafer, the lattice spacing d before the transfer was 5.65286 Å and the lattice spacing d after the transfer was 5.65283 Å. On the other hand, when the transfer target wafer 120 was a silicon wafer, the lattice spacing d before the transfer was 5.65286 Å and the lattice spacing d after the transfer was 5.65259 Å. When the transfer target wafer 120 was the Pyrex glass wafer, the lattice spacing hardly changed before and after the transfer. When the transfer target wafer 120 was the silicon wafer, however, the lattice constant of the GaAs crystal layer (the semiconductor crystal layer 106) in the thickness direction was found smaller after the transfer. This indicates that tensile strain was created in the plane direction. Such a change in lattice constant (whether strain is created in the plane direction) is speculated to be attributed to the hardness of the wafer. It is expected that strain can be controlled in the GaAs crystal layer (the semiconductor crystal layer 106) by using a hard wafer such as a silicon wafer and controlling the load applied to perform the bonding step. It is expected that this strain controlling technique enables the composite wafers relating to the present embodiment example to be used to produce a strained transistor and the like.

The above-described embodiments and embodiment examples can be embodied as the following inventions.

(1) A method of producing a composite wafer including a semiconductor crystal layer, the method including:

a step of forming a sacrificial layer and the semiconductor crystal layer on a semiconductor crystal layer forming wafer in the order of the sacrificial layer and the semiconductor crystal layer;

a step of bonding the semiconductor crystal layer forming wafer to a transfer target wafer in such a manner that a first surface faces and is in contact with a second surface, the first surface being a surface of a layer formed on the semiconductor crystal layer forming wafer and the second surface being the surface of the transfer target wafer or the surface of a layer formed on the transfer target wafer;

a step of etching the sacrificial layer away to separate the transfer target wafer from the semiconductor crystal layer forming wafer with the semiconductor crystal layer being left on the transfer target wafer;

a step of bonding the transfer target wafer to a second transfer target wafer in such a manner that the semiconductor crystal layer on the transfer target wafer faces the surface of the second transfer target wafer;

a step of changing one or more physical properties selected from (i) the physical property of a layer positioned between the transfer target wafer and the semiconductor crystal layer, (ii) the physical property of an interface that determines the adhesiveness between the transfer target wafer and the semiconductor crystal layer, (iii) the physical property of a layer positioned between the semiconductor crystal layer and the second transfer target wafer, and (iv) the physical property of an interface that determines the adhesiveness between the semiconductor crystal layer and the second transfer target wafer; and

a step of separating the transfer target wafer from the second transfer target wafer with the semiconductor crystal layer being left on the second transfer target wafer.

(2) The production method as set forth in (1), wherein

the transfer target wafer is made of an inorganic material and a curved flexible wafer having planes one of which is a convex plane and the other is a concave plane in a free state,

the second surface is on the side of the convex plane,

in the step of separating the transfer target wafer from the semiconductor crystal layer forming wafer, the sacrificial layer is etched while a portion of the transfer target wafer that is away from the semiconductor crystal layer forming wafer is bent in a direction away from the semiconductor crystal layer forming wafer due to the curve of the transfer target wafer.

(3) The production method as set forth in one of (1) and (2), further comprising

a step of forming an adhesive layer on the semiconductor crystal layer after the step of forming the sacrificial layer and the semiconductor crystal layer and before the step of bonding the semiconductor crystal layer forming wafer to the transfer target wafer.

(4) The production method as set forth in one of (1) and (3), further comprising

a step of performing an adhesiveness enhancement treatment to enhance the adhesiveness of a bonding interface between the first surface and the second surface on one or more surfaces selected from the first surface and the second surface, after the step of forming the sacrificial layer and the semiconductor crystal layer and before the step of bonding the semiconductor crystal layer forming wafer to the transfer target wafer.

(5) The production method as set forth in one of (1) to (4), further comprising

a step of attaching the transfer target wafer to the semiconductor crystal layer forming wafer under pressure of 0.01 MPa to 1 GPa after the step of bonding the semiconductor crystal layer forming wafer to the transfer target wafer and before the step of separating the transfer target wafer from the semiconductor crystal layer forming wafer.

(6) The production method as set forth in one of (1) to (5), comprising

a step of etching at least the semiconductor crystal layer so as to partly expose the sacrificial layer and to divide the semiconductor crystal layer into a plurality of divided pieces, after the step of forming the sacrificial layer and the semiconductor crystal layer and before the step of bonding the semiconductor crystal layer forming wafer to the transfer target wafer. (7) The production method as set forth in one of (1) to (6), further comprising a step of forming an electronic device whose active region is formed by a portion of the semiconductor crystal layer on the semiconductor crystal layer, after the step of forming the sacrificial layer and the semiconductor crystal layer and before the step of bonding the semiconductor crystal layer forming wafer to the transfer target wafer.

(8) The production method as set forth in one of (1) to (7), wherein

the etching of the sacrificial layer performed in the step of separating the transfer target wafer from the semiconductor crystal layer forming wafer is performed by immersing in an etching solution the entire or part of the semiconductor crystal layer forming wafer and the transfer target wafer.

(9) A composite wafer comprising:

a flexible wafer that is made of an inorganic material and that is curved in such a manner that one of the planes thereof is a convex plane and the other plane is a concave plane in a free state;

a single-crystal semiconductor crystal layer; and

a polycrystalline insulative layer that is positioned between the flexible wafer and the semiconductor crystal layer.

(10) The composite wafer as set forth in (9), wherein

the flexible wafer contains atoms that induce electric conductivity with a concentration of 1×10¹⁰ cm⁻³ to 1×10¹⁶ cm⁻³, and the insulative layer serves as a passivation layer for the atoms that induce electric conductivity.

(11) A composite wafer including:

a transfer target wafer that has a planar shape of a circle having a diameter of 200 mm or larger; and

a semiconductor crystal layer that is positioned on the transfer target wafer and has a thickness of 1 μm or less, wherein

the semiconductor crystal layer is divided into a plurality of divided pieces,

each of the divided pieces has a planar shape of a circle having a diameter of 30 mm or smaller, and

the entire portion of the transfer target wafer or a portion of the transfer target wafer that is positioned so as to face the divided pieces is amorphous, polycrystalline or a single-crystal structure that does not lattice-match or pseudo-lattice-match the single-crystal structure of the divided pieces.

(12) The composite wafer as set forth in (11), further comprising

an intermediate layer that is positioned between the transfer target wafer and the divided pieces, and

the intermediate layer is resistant against heat of 300° C. or more.

(13) The composite wafer as set forth in one of (11) and (12), wherein

the divided pieces are arranged one-dimensionally or two-dimensionally.

(14) The composite wafer as set forth in (13), wherein

the divided pieces are arranged in a two-dimensional array of n columns in the horizontal direction and m rows in the vertical direction, and

the number n of columns in the horizontal direction of the two-dimensional array is 10 or more and the number m of rows in the vertical direction of the two-dimensional array is 10 or more.

(15) The composite wafer as set forth in one of (11) to (14), wherein

each of the divided pieces is formed by a single-crystal Ge layer, and

the half-value width of the diffraction spectrum of the Ge layer obtained by X-ray diffraction is 40 arcsec or less.

(16) The composite wafer as set forth in one of (11) to (15), wherein

each of the divided pieces has a smoothness of 10 nm or less.

(17) A method of producing a composite wafer, comprising:

a step of forming a sacrificial layer and a semiconductor crystal layer having a thickness of 1 μm or less on a semiconductor crystal layer forming wafer that has a planar shape of a circle having a diameter of 200 mm or smaller, in the order of the semiconductor crystal layer forming wafer, the sacrificial layer and the semiconductor crystal layer;

a step of etching at least the semiconductor crystal layer so as to partly expose the sacrificial layer and to divide the semiconductor crystal layer into a plurality of divided pieces each of which has a planar shape of a circle having a diameter of 30 mm or smaller;

a step of shaping the semiconductor crystal layer forming wafer so as to have a size suitable for transfer;

a step of bonding the semiconductor crystal layer forming wafer to a transfer target wafer in such a manner that a first surface faces a second surface, the first surface being the surface of a layer formed on the shaped semiconductor crystal layer forming wafer and being to be brought into contact with the transfer target wafer or a layer formed on the transfer target wafer, the second surface being the surface of the transfer target wafer or the surface of a layer formed on the transfer target wafer and being to be brought into contact with the first surface; and

a step of etching the sacrificial layer and separating the transfer target wafer from the semiconductor crystal layer forming wafer with the semiconductor crystal layer being left on the transfer target wafer, wherein

the transfer target wafer has a planar shape of a circle having a diameter of 200 mm or larger.

(18) The production method as set forth in (17), wherein

the step of shaping is a step of dividing the semiconductor crystal layer forming wafer into a plurality of division wafers each of which is shaped suitably for transfer.

(19) A method of producing a composite wafer, comprising:

a step of forming a sacrificial layer and a semiconductor crystal layer having a thickness of 1 μm or less on a semiconductor crystal layer forming wafer having a planar shape of a circle having a diameter of 200 mm or smaller, in the order of the semiconductor crystal layer forming wafer, the sacrificial layer and the semiconductor crystal layer;

a step of etching at least the semiconductor crystal layer so as to partly expose the sacrificial layer and to divide the semiconductor crystal layer into a plurality of divided pieces having a planar shape of a circle having a diameter of 30 mm or smaller;

a step of bonding the semiconductor crystal layer forming wafer to an intermediate wafer in such a manner that a first surface faces a second surface, the first surface being the surface of a layer formed on the semiconductor crystal layer forming wafer and being to be brought into contact with the intermediate wafer or a layer formed on the intermediate wafer, the second surface being the surface of the intermediate wafer or the surface of a layer formed on the intermediate wafer and being to be brought into contact with the first surface;

a step of etching the sacrificial layer and separating the intermediate wafer from the semiconductor crystal layer forming wafer with the semiconductor crystal layer being left on the intermediate wafer;

a step of shaping the intermediate wafer so as to have a size suitable for transfer;

a step of bonding the intermediate wafer to a transfer target wafer in such a manner that a third surface faces a fourth surface, the third surface being the surface of a layer that is formed on the shaped intermediate wafer and being to be brought into contact with the transfer target wafer or a layer formed on the transfer target wafer, the fourth surface being the surface of the transfer target wafer or the surface of a layer formed on the transfer target wafer and being to be brought into contact with the third surface; and

a step of separating the transfer target wafer from the intermediate wafer with the semiconductor crystal layer being left on the transfer target wafer, wherein

the intermediate wafer is a non-flexible wafer and the transfer target wafer has a planar shape of a circle having a diameter of 200 mm or larger.

(20) The production method as set forth in (19), wherein

the step of shaping is a step of dividing the intermediate wafer into a plurality of division wafers each of which has a shape suitable for the transfer.

(21) A method of producing a composite wafer, comprising:

a step of forming a sacrificial layer and a semiconductor crystal layer having a thickness of 1 μm or less on a semiconductor crystal layer forming wafer having a planar shape of a circle having a diameter of 200 mm or smaller, in the order of the semiconductor crystal layer forming wafer, the sacrificial layer and the semiconductor crystal layer;

a step of etching at least the semiconductor crystal layer so as to partly expose the sacrificial layer and to divide the semiconductor crystal layer into a plurality of divided pieces having a planar shape of a circle having a diameter of 30 mm or smaller;

a step of bonding the semiconductor crystal layer forming wafer to an intermediate wafer in such a manner that a first surface faces a second surface, the first surface being the surface of a layer formed on the semiconductor crystal layer forming wafer and being to be brought into contact with the intermediate wafer or a layer formed on the intermediate wafer, the second surface being the surface of the intermediate wafer or the surface of a layer formed on the intermediate wafer and being to be brought into contact with the first surface;

a step of etching the sacrificial layer and separating the intermediate wafer from the semiconductor crystal layer forming wafer with the semiconductor crystal layer being left on the intermediate wafer;

a step of bonding the intermediate wafer to the transfer target wafer in such a manner that a third surface faces a fourth surface, the third surface being the surface of a layer that is formed on the intermediate wafer and being to be brought into contact with a transfer target wafer or a layer formed on the transfer target wafer, the fourth surface being the surface of the transfer target wafer or the surface of a layer formed on the transfer target wafer and being to be brought into contact with the third surface; and

a step of separating the transfer target wafer from the intermediate wafer with the semiconductor crystal layer being left on the transfer target wafer, wherein

the intermediate wafer is a non-flexible wafer that has been shaped so as to have a size suitable for the transfer,

the transfer target wafer has a planar shape of a circle having a diameter of 200 mm or larger,

in the step of bonding the semiconductor crystal layer forming wafer to the intermediate wafer and in the step of separating the intermediate wafer from the semiconductor crystal layer forming wafer, a plurality of the intermediate wafers are supported by a single support,

the plurality of intermediate wafers supported by the single support are collectively handled, and

in the step of bonding the intermediate wafer to the transfer target wafer and in the step of separating the transfer target wafer from the intermediate wafer, the intermediate wafers that have been separated from the support are individually handled.

(22) The production method as set forth in one of (19) to (21), further comprising

after the step of bonding the intermediate wafer to the transfer target wafer and before the step of separating the transfer target wafer from the intermediate wafer, a step of changing one or more physical properties selected from (i) the physical property of a layer positioned between the intermediate wafer and the semiconductor crystal layer, (ii) the physical property of an interface that determines the adhesiveness between the intermediate wafer and the semiconductor crystal layer, (iii) the physical property of a layer positioned between the semiconductor crystal layer and the transfer target wafer, and (iv) the physical property of an interface that determines the adhesiveness between the semiconductor crystal layer and the transfer target wafer. (23) The production method as set forth in one of (17) to (22), further comprising

after the step of forming the sacrificial layer and the semiconductor crystal layer and before the step of dividing, a step of forming a first adhesive layer on the semiconductor crystal layer.

(24) The production method as set forth in one of (17) to (23), further comprising

a step of forming a second adhesive layer on the intermediate wafer, wherein

the surface of the second adhesive layer is the second surface.

(25) The production method as set forth in one of (17) to (24), further comprising

before the first surface is bonded to the second surface, a step of performing an adhesiveness enhancement treatment to enhance the adhesiveness of a bonding interface between the first surface and the second surface on one or more surfaces selected from the first surface and the second surface.

(26) The production method as set forth in (25), further comprising

a step of applying a pressure of 0.01 MPa to 1 GPa to the wafers so that the first surface is attached to the second surface with the bonding interface being placed therebetween under pressure.

(27) The production method as set forth in one of (19) to (26), further comprising

before the third surface is bonded to the fourth surface, a step of performing an adhesiveness enhancement treatment to enhance the adhesiveness of a bonding interface between the third surface and the fourth surface on one or more surfaces selected from the third surface and the fourth surface.

(28) The production method as set forth in (27), further comprising

a step of applying a pressure of 0.01 MPa to 1 GPa to the wafers so that the third surface is attached to the fourth surface with the bonding interface being placed therebetween under pressure.

(29) The production method as set forth in one of (17) to (28), further comprising

after the step of forming the sacrificial layer and the semiconductor crystal layer and before the step of bonding the semiconductor crystal layer forming wafer to the intermediate wafer, a step of forming an electronic device whose active region is formed by a portion of the semiconductor crystal layer on the semiconductor crystal layer.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A method of producing a composite wafer including a semiconductor crystal layer, comprising:
forming a sacrificial layer and the semiconductor crystal layer above a semiconductor crystal layer forming wafer in the order of the sacrificial layer and the semiconductor crystal layer;
etching the semiconductor crystal layer so as to partially expose the sacrificial layer and dividing the semiconductor crystal layer into a plurality of divided pieces;
bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, the first surface being a surface of a layer formed on the semiconductor crystal layer forming wafer, and the second surface being a surface of the transfer target wafer or a surface of a layer formed on the transfer target wafer; and
etching the sacrificial layer to separate the transfer target wafer and the semiconductor crystal layer forming wafer from each other with the semiconductor crystal layer being left on the transfer target wafer.

2. A method of producing a composite wafer including a semiconductor crystal layer, comprising:
forming a sacrificial layer made of AlₓGa₁₋ₓAs (0.9≦x≦1) above a semiconductor crystal layer forming wafer to a thickness of no less than 5 nm and no more than 100 nm and further forming the semiconductor crystal layer;
etching the semiconductor crystal layer so as to partially expose the sacrificial layer and dividing the semiconductor crystal layer into a plurality of divided pieces;
bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, the first surface being a surface of a layer formed on the semiconductor crystal layer forming wafer, and the second surface being a surface of the transfer target wafer or a surface of a layer formed on the transfer target wafer; and
removing the sacrificial layer by means of etching that uses an HCl aqueous solution as an etchant to separate the transfer target wafer and the semiconductor crystal layer forming wafer from each other with the semiconductor crystal layer being left on the transfer target wafer.

3. A method of producing a composite wafer including a semiconductor crystal layer, comprising:
forming a sacrificial layer made of AlₓGa₁₋ₓAs (0.9≦x≦1) above a semiconductor crystal layer forming wafer and further forming the semiconductor crystal layer;
etching the semiconductor crystal layer so as to partially expose the sacrificial layer and dividing the semiconductor crystal layer into a plurality of divided pieces;
bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, the first surface being a surface of a layer formed on the semiconductor crystal layer forming wafer, and the second surface being a surface of the transfer target wafer or a surface of a layer formed on the transfer target wafer; and
removing the sacrificial layer by means of etching that uses an HCl aqueous solution as an etchant to separate the transfer target wafer and the semiconductor crystal layer forming wafer from each other with the semiconductor crystal layer being left on the transfer target wafer, wherein
the HCl aqueous solution has a concentration of no less than 5 mass % and no more than 25 mass %.

4. A method of producing a composite wafer including a semiconductor crystal layer, comprising:
forming a sacrificial layer and the semiconductor crystal layer above a semiconductor crystal layer forming wafer in the order of the sacrificial layer and the semiconductor crystal layer;
etching the semiconductor crystal layer so as to partially expose the sacrificial layer and dividing the semiconductor crystal layer into a plurality of divided pieces;
bonding the semiconductor crystal layer forming wafer and a transfer target wafer made of an inorganic material in such a manner that a first surface of the semiconductor crystal layer forming wafer faces a second surface of the transfer target wafer and the first surface comes into contact with the second surface, the first surface being a surface of a layer formed on the semiconductor crystal layer forming wafer, and the second surface being a surface of the transfer target wafer or a surface of a layer formed on the transfer target wafer; and
etching the sacrificial layer to separate the transfer target wafer and the semiconductor crystal layer forming wafer from each other with the semiconductor crystal layer being left on the transfer target wafer, wherein
one or more of the plurality of divided pieces have such a planar shape that, when the divided pieces are assumed to shrink and disappear at equal rates from each point on edges that define the external shape of the planar shape of the divided pieces in a normal direction at the point, a shape observed immediately before the disappearance due to the shrinkage is not a single point but a single line, a plurality of lines or a plurality of points.

5. The method as set forth in claim 4 of producing a composite wafer, wherein
the planar shape of the divided pieces is a planar shape defined by two parallel line segments and two lines connecting the ends of the two parallel line segments, and the lines connecting the ends are straight, curved or polygonal lines.

6. The method as set forth in claim 5 of producing a composite wafer, wherein
the planar shape of the divided pieces is rectangular.

7. The method as set forth in claim 1 of producing a composite wafer, further comprising
after the bonding, attaching the semiconductor crystal layer forming wafer and the transfer target wafer to each other under a pressure within a range of 0.01 MPa to 1 GPa.

8. A method of producing a composite wafer including a semiconductor crystal layer, comprising:
forming a sacrificial layer and the semiconductor crystal layer above a semiconductor crystal layer forming wafer in the order of the sacrificial layer and the semiconductor crystal layer;
etching the semiconductor crystal layer so as to partially expose the sacrificial layer and dividing the semiconductor crystal layer into a plurality of divided pieces;
arranging the semiconductor crystal layer forming wafer and a transfer target wafer made of an inorganic material in such a manner that a first surface of the semiconductor crystal layer forming wafer faces a second surface of the transfer target wafer and attaching the semiconductor crystal layer forming wafer and the transfer target wafer to each other in such a manner that the first surface comes into contact with the second surface under a pressure within a range of 0.01 MPa to 1 GPa, the first surface being a surface of a layer formed on the semiconductor crystal layer forming wafer, and the second surface being a surface of the transfer target wafer or a surface of a layer formed on the transfer target wafer; and
etching the sacrificial layer to separate the transfer target wafer and the semiconductor crystal layer forming wafer from each other with the semiconductor crystal layer being left on the transfer target wafer.

9. The method as set forth in claim 1 of producing a composite wafer, further comprising
after the formation of the sacrificial layer and the semiconductor crystal layer, and before the division of the semiconductor crystal layer into the plurality of divided pieces, forming an adhesive layer made of an inorganic material above the semiconductor crystal layer, wherein
during the division of the semiconductor crystal layer into the plurality of divided pieces, the adhesive layer and the semiconductor crystal layer are etched so as to partially expose the sacrificial layer and the adhesive layer and the semiconductor crystal layer are divided into the plurality of pieces.

10. The method as set forth in claim 1 of producing a composite wafer, further comprising
after the division and before the bonding of the semiconductor crystal layer forming wafer and the transfer target wafer, performing adhesiveness enhancement treatment to enhance adhesiveness at the bonding interface between the first surface and the second surface on a one or more surfaces selected from the first surface and the second surface.

11. The method as set forth in claim 1 of producing a composite wafer, wherein
the etching of the sacrificial layer during the separation of the transfer target wafer and the semiconductor crystal layer forming wafer is performed by immersing partially or entirely the semiconductor crystal layer forming wafer and the transfer target wafer in an etching solution.

12. The method as set forth in claim 1 of producing a composite wafer, wherein
the bonding or the attachment under the pressure of the transfer target wafer and the semiconductor crystal layer forming wafer forms a space between the surface of the transfer target wafer and an internal wall of a groove formed between adjacent ones of the divided pieces, and
the etching of the sacrificial layer for the separation of the transfer target wafer and the semiconductor crystal layer forming wafer from each other is started by dropping an etching solution onto one end of the space.

13. The method as set forth in claim 12 of producing a composite wafer, wherein
after the inside of the space is filled with the etching solution, the transfer target wafer and the semiconductor crystal layer forming wafer are entirely immerse into the etching solution to allow the etching to proceed.

14. The method as set forth in claim 12 of producing a composite wafer, wherein
the etching solution is continuously supplied to the end of the space to allow the etching to proceed.

15. The method as set forth in claim 14 of producing a composite wafer, wherein
during the etching, the inside of the space is partially or entirely dried one or more times.

16. A composite wafer comprising a transfer target wafer and a semiconductor crystal layer that is formed on the transfer target wafer by a transfer technique, wherein
the semiconductor crystal layer has a plurality of divided pieces, and
one or more of the plurality of divided pieces have such a planar shape that, when the divided pieces are assumed to shrink and disappear at equal rates from each point on edges that define the external shape of the planar shape of the divided pieces in a normal direction at the point, a shape observed immediately before the disappearance due to the shrinkage is not a single point but a single line, a plurality of lines or a plurality of points.

17. A composite wafer comprising a transfer target wafer and a semiconductor crystal layer that is formed on the transfer target wafer by a transfer technique, wherein
the semiconductor crystal layer has a plurality of divided pieces, and
one or more of the plurality of divided pieces have compressive or tensile strain.

18. The composite wafer as set forth in claim 16, wherein
the planar shape of the divided pieces are rectangular.
